(19) United States
(12) Patent Application Publication
(10) Pub. No.: US 2018/0188428 A1
(43) Pub. Date: Jul. 5, 2018

(54) NEAR-INFRARED CUT FILTER, METHOD FOR PRODUCING NEAR-INFRARED CUT FILTER, AND SOLID-STATE IMAGING ELEMENT

(71) Applicant: FUJIFILM Corporation, Tokyo (JP)

(72) Inventors: Keisuke ARIMURA, Haibara-gun (JP); Kazuto SHIMADA, Haibara-gun (JP); Takahiro OKAWARA, Haibara-gun (JP); Takashi KAWASHIMA, Haibara-gun (JP); Hidenori TAKAHASHI, Haibara-gun (JP)

(73) Assignee: FUJIFILM Corporation, Tokyo (JP)

(21) Appl. No.: 15/899,850

(22) Filed: Feb. 20, 2018

Related U.S. Application Data
(63) Continuation of application No. PCT/JP2016/074877, filed on Aug. 25, 2016.

(30) Foreign Application Priority Data
Sep. 28, 2015 (JP) 2015-189500

(51) Int. Cl. G02B 5/20

(52) U.S. Cl. CPC G02B 5/208

(57) ABSTRACT

A near-infrared cut filter has a first infrared absorbing layer including an infrared absorber A, a second infrared absorbing layer including an infrared absorber C, and a resin layer disposed between the first infrared absorbing layer and the second infrared absorbing layer.

### CROSS-REFERENCE TO RELATED APPLICATIONS

This application is a Continuation of PCT International Application No. PCT/JP2016/74877, filed on Aug. 25, 2016, which claims priority under 35 U.S.C. § 119(a) to Japanese Patent Application No. 2015-189500, filed on Sep. 28, 2015. Each of the above application(s) is hereby expressly incorporated by reference, in its entirety, into the present application.

### BACKGROUND OF THE INVENTION

### 1. Field of the Invention

The present invention relates to a near-infrared cut filter, a method for producing a near-infrared cut filter, and a solid-state imaging element having a near-infrared cut filter.

### 2. Description of the Related Art

Video cameras, digital still cameras, camera-equipped cellular phones, and the like include CCDs (charge-coupled devices) and CMOSs (complementary metal-oxide semiconductors), which are solid-state imaging elements for color images. Such a solid-state imaging element employs, in its light receiving section, silicon photodiodes sensitive to infrared radiation, which requires visibility correction. Thus, the solid-state imaging element often employs a near-infrared cut filter.

WO2014/168189A discloses a near-infrared cut filter in which a near-infrared absorbing layer including a transparent resin and an organic dye is formed on the surface of a transparent substrate. It is described in paragraph 0108 in WO2014/168189A that a coating liquid including a polyester resin and a squarylium dye is applied onto one main surface of a glass substrate to form an infrared absorbing layer, and a coating liquid including a polyester resin and a diimmonium compound is applied onto the infrared absorbing layer to form an infrared absorbing layer, thereby producing a near-infrared cut filter.

### SUMMARY OF THE INVENTION

However, as a result of studies conducted by the present inventors on the near-infrared cut filter described in WO2014/168189A, the haze has been found to be high.

Accordingly, it is an object of the present invention to provide a near-infrared cut filter with low haze, a method for producing the near-infrared cut filter, and a solid-state imaging element.

As a result of thorough studies conducted by the present inventors on the cause of generation of haze on the near-infrared cut filter in which two or more infrared absorbing layers including an infrared absorber are laminated, they have found that the infrared absorber included in the infrared absorbing layers undergoes interlayer mixing at an interface between the infrared absorbing layers. The present inventors have thought that the haze can be decreased if the interlayer mixing of the infrared absorbers at the interface is suppressed. Thus, the present invention has been completed. The present invention is provided as follows.

<1> A near-infrared cut filter has a first infrared absorbing layer including an infrared absorber A, a second infrared absorbing layer including an infrared absorber C, and a resin layer disposed between the first infrared absorbing layer and the second infrared absorbing layer.
<2> In the near-infrared cut filter according to <1>, at least one of the infrared absorber A or the infrared absorber C includes a copper compound.
<3> In the near-infrared cut filter according to <1> or <2>, at least one of the infrared absorber A or the infrared absorber C includes at least one compound selected from the group consisting of a pyrrolopyrrole compound, a squarylium compound, a cyanine compound, a phthalocyanine compound, and a naphthalocyanine compound.
<4> In the near-infrared cut filter according to <1>, one of the infrared absorber A and the infrared absorber C includes a copper compound and the other includes at least one compound selected from the group consisting of a pyrrolopyrrole compound, a squarylium compound, a cyanine compound, a phthalocyanine compound, and a naphthalocyanine compound.
<5> In the near-infrared cut filter according to any one of <1> to <4>, at least one of the first infrared absorbing layer or the second infrared absorbing layer is a layer obtained by curing an infrared absorbing composition that contains a compound having a crosslinking group and an infrared absorber.
<6> In the near-infrared cut filter according to any one of <1> to <5>, at least one of the first infrared absorbing layer or the second infrared absorbing layer is a layer obtained by curing an infrared absorbing composition that contains a compound having a crosslinking group and a copper compound, and the compound having a crosslinking group is a compound having a partial structure represented by M-X. Herein, M represents an atom selected from the group consisting of Si, Ti, Zr, and Al; X represents one group selected from the group consisting of a hydroxy group, an alkoxy group, an acyloxy group, a phosphoryloxy group, a sulfonyloxy group, an amino group, an oxime group, and O═C(R^{a})(R^{b}); R^{a} and R^{b} each independently represent a monovalent organic group; and when X represents O═C(R^{a})(R^{b}), X bonds to M through an unshared electron pair of an oxygen atom in a carbonyl group.
<7> In the near-infrared cut filter according to <5> or <6>, a content of the compound having a crosslinking group is 15 mass % or more based on a total solid content of the infrared absorbing composition.
<8> In the near-infrared cut filter according to any one of <1> to <7>, the resin layer has a glass transition temperature of 0° C. to 200° C.
<9> In the near-infrared cut filter according to any one of <1> to <8>, the resin layer has a thickness of 0.005 mm or more.
<10> In the near-infrared cut filter according to any one of <1> to <9>, at least one of the first infrared absorbing layer or the second infrared absorbing layer includes a resin, and an absolute value of a difference between an SP value that is a solubility parameter of the resin included in the at least one of the first infrared absorbing layer or the second infrared absorbing layer and an SP value that is a solubility parameter of a resin included in the resin layer is 0.5 to 5.0 (MPa)^{1/2}.
<11> In the near-infrared cut filter according to any one of <1> to <10>, the first infrared absorbing layer is in contact with the resin layer, and the second infrared absorbing layer is in contact with the resin layer.
<12> A method for producing a near-infrared cut filter includes a step of forming a first infrared absorbing layer on a support using an infrared absorbing composition A including an infrared absorber A, a step of forming a resin layer on the first infrared absorbing layer using a resin composition B including a resin B, and a step of forming a second infrared absorbing layer on the resin layer using an infrared absorbing composition C including an infrared absorber C.
<13> In the method for producing a near-infrared cut filter according to <12>, the infrared absorbing composition A includes the infrared absorber A and a resin A, and an absolute value of a difference between an SP value that is a solubility parameter of the resin A and an SP value that is a solubility parameter of the resin B is 0.5 to 5.0 (MPa)^{1/2}.
<14> In the method for producing a near-infrared cut filter according to <12> or <13>, the infrared absorbing composition C includes the infrared absorber C and a resin C, and an absolute value of a difference between an SP value that is a solubility parameter of the resin C and an SP value that is a solubility parameter of the resin B is 0.5 to 5.0 (MPa)^{1/2}.
<15> A solid-state imaging element has the near-infrared cut filter according to any one of <1> to <11>.

According to the present invention, there can be provided a near-infrared cut filter with low haze. Furthermore, there can be provided a method for producing the near-infrared cut filter and a solid-state imaging element.

### BRIEF DESCRIPTION OF THE DRAWINGS

FIG. 1 schematically illustrates a near-infrared cut filter according to an embodiment of the present invention.

### DESCRIPTION OF THE PREFERRED EMBODIMENTS

Hereafter, the present invention will be described in detail.

In this specification, numerical values before and after “to” inclusively indicate a lower limit and an upper limit.

In this specification, when substitution or no substitution is not specified for groups (atomic groups), both groups (atomic groups) that do not have a substituent and groups (atomic groups) that have a substituent are included. For example, an “alkyl group” includes not only an alkyl group that does not have a substituent (unsubstituted alkyl group) but also an alkyl group that has a substituent (substituted alkyl group).

In this specification, “(meth)acrylate” refers to acrylate and methacrylate, “(meth)acrylic” refers to acrylic and methacrylic, and “(meth)acryloyl” refers to acryloyl and methacryloyl.

The weight-average molecular weight and the number-average molecular weight of compounds used in the present invention can be determined by gel permeation chromatography (GPC) in terms of polystyrene.

Near-infrared radiation refers to light (electromagnetic waves) having a maximum absorption wavelength range of 700 to 2500 nm.

In this specification, the “total solid content” refers to the total mass of all components other than solvents in a composition. The solid content in the present invention is a solid content at 25° C.

### Near-Infrared Cut Filter

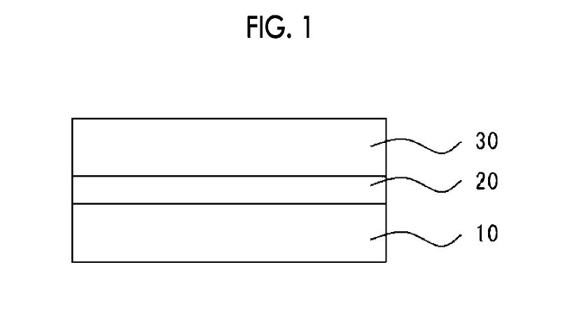

FIG. 1 illustrates a near-infrared cut filter according to an embodiment of the present invention. The near-infrared cut filter has a first infrared absorbing layer 10 including an infrared absorber A, a resin layer 20, and a second infrared absorbing layer 30 including an infrared absorber C. The resin layer 20 is disposed between the first infrared absorbing layer 10 and the second infrared absorbing layer 30. This structure can provide a near-infrared cut filter with low haze. That is, since the near-infrared cut filter has the resin layer 20 disposed between the first infrared absorbing layer 10 and the second infrared absorbing layer 30, the resin layer 20 can suppress interlayer mixing of the infrared absorber A included in the first infrared absorbing layer 10 and the infrared absorber C included in the second infrared absorbing layer 30. Thus, a near-infrared cut filter with low haze can be provided.

In the near-infrared cut filter, the first infrared absorbing layer 10 may be directly formed on the surface of the resin layer 20. That is, the first infrared absorbing layer 10 may be in contact with the resin layer 20. Alternatively, another layer may be interposed between the first infrared absorbing layer 10 and the resin layer 20. The second infrared absorbing layer 30 may be directly formed on the surface of the resin layer 20. That is, the second infrared absorbing layer 30 may be in contact with the resin layer 20. Alternatively, another layer may be interposed between the second infrared absorbing layer 30 and the resin layer 20. The first infrared absorbing layer 10 and the second infrared absorbing layer 30 are preferably in contact with the resin layer 20.

In the near-infrared cut filter, the first infrared absorbing layer 10, the resin layer 20, and the second infrared absorbing layer 30 may be formed on a support. The support is made of any material such as glass, crystal, or resin as long as the material transmits at least light in a visible wavelength range. Examples of the glass include soda-lime glass, borosilicate glass, alkali-free glass, and quartz glass. Examples of the crystal include rock crystal, lithium niobate, and sapphire. Examples of the resin include polyester resins such as polyethylene terephthalate and polybutylene terephthalate; polyolefin resins such as polyethylene, polypropylene, and ethylene-vinyl acetate copolymers; norbornene resins; acrylic resins such as polyacrylate and poly(methyl methacrylate); urethane resins; vinyl chloride resins; fluorocarbon resins; polycarbonate resins; polyvinyl butyral resins; and polyvinyl alcohol resins.

The near-infrared cut filter according to the present invention may have three or more infrared absorbing layers. When the near-infrared cut filter has three or more infrared absorbing layers, other infrared absorbing layers may be directly laminated on the surfaces of the first infrared absorbing layer 10 and/or the second infrared absorbing layer 30. Alternatively, other infrared absorbing layers may be laminated on resin layers disposed on the surfaces of the first infrared absorbing layer 10 and/or the second infrared absorbing layer 30. In the case where the near-infrared cut filter has the first infrared absorbing layer 10, the resin layer 20, and the second infrared absorbing layer 30 formed on the support, other infrared absorbing layers may be formed on a surface of the support opposite to the surface on which a laminate of the first infrared absorbing layer 10, the resin layer 20, and the second infrared absorbing layer 30 has been formed.

The near-infrared cut filter according to the present invention may further have a dielectric multilayer film. When the near-infrared cut filter has a dielectric multilayer film, the near-infrared cut filter tends to have a large view angle and good infrared shielding properties. The dielectric multilayer film may be disposed on the first infrared absorbing layer 10 and/or the second infrared absorbing layer 30. In the case where the near-infrared cut filter has the first infrared absorbing layer 10, the resin layer 20, and the second infrared absorbing layer 30 formed on the support, the dielectric multilayer film may be formed on a surface of the support opposite to the surface on which a laminate of the first infrared absorbing layer 10, the resin layer 20, and the second infrared absorbing layer 30 has been formed.

In the present invention, the dielectric multilayer film is a film for shielding near-infrared radiation using the effect of light interference. That is, the dielectric multilayer film refers to a film capable of reflecting near-infrared radiation. Specifically, the dielectric multilayer film is a film obtained by alternately laminating two or more dielectric layers having different refractive indices (high-refractive-index material layers and low-refractive-index material layers).

The dielectric multilayer film is made of a material such as ceramic. To produce a near-infrared cut filter that uses the effect of light interference, two or more ceramics having different refractive indices are preferably used. Specifically, the dielectric multilayer film suitably has a structure in which high-refractive-index material layers and low-refractive-index material layers are alternately laminated.

The material for the high-refractive-index material layers is a material having a refractive index of 1.7 or more, and the refractive index is normally in the range of 1.7 to 2.5. The material is, for example, a material that contains titanium oxide, zirconium oxide, tantalum pentoxide, niobium pentoxide, lanthanum oxide, yttrium oxide, zinc oxide, zinc sulfide, or indium oxide as a main component and that also contains a small amount of titanium oxide, tin oxide, cerium oxide, and/or the like.

The material for the low-refractive-index material layers is a material having a refractive index of 1.6 or less, and the refractive index is normally in the range of 1.2 to 1.6. Examples of the material include silica, alumina, lanthanum fluoride, magnesium fluoride, and sodium hexafluoroaluminate.

The thickness of each of the high-refractive-index material layers and the low-refractive-index material layers is preferably 0.1λ to 0.5λ, where λ represents a wavelength (nm) of infrared radiation to be shielded. When the thickness is in the above range, the shielding and transmission of infrared radiation having a particular wavelength are easily controlled. The number of layers laminated in the dielectric multilayer film is preferably 2 to 100, more preferably 2 to 60, and further preferably 2 to 40. If warping occurs on the substrate during vapor deposition of the dielectric multilayer film, the following method can be employed to prevent warping. That is, for example, the dielectric multilayer film is deposited on both surfaces of the substrate or the surface of the substrate on which the dielectric multilayer film is deposited is irradiated with radiation such as ultraviolet radiation. When radiation is applied, the radiation may be applied during deposition of the dielectric multilayer film or may be separately applied after the deposition.

The near-infrared cut filter according to the present invention may further have an ultraviolet absorbing layer. When the near-infrared cut filter has an ultraviolet absorbing layer, the near-infrared cut filter has good ultraviolet shielding properties. For the ultraviolet absorbing layer, for example, an absorbing layer described in paragraphs 0040 to 0070 and 0119 to 0145 in WO2015/099060A can be taken into consideration, the contents of which are incorporated herein.

Hereafter, the near-infrared cut filter according to the present invention will be described in detail.

### Resin Layer 20

The near-infrared cut filter has a resin layer 20 between a first infrared absorbing layer 10 and a second infrared absorbing layer 30. Any layer including a resin is preferred as the resin layer 20. A layer including a transparent resin is further preferred. The resin content in the resin layer 20 is preferably 50 to 100 mass % based on the mass of the resin layer. The lower limit of the resin content is preferably 70 mass % or more and more preferably 90 mass % or more. The upper limit of the resin content may be, for example, 99 mass % or less or 95 mass % or less.

The thickness of the resin layer 20 is preferably 0.0005 mm or more and more preferably 0.01 mm or more. The upper limit of the thickness is preferably 0.05 mm or less and more preferably 0.02 mm or less. When the resin layer has a thickness of 0.0005 mm or more, haze can be effectively suppressed.

The resin layer 20 preferably has a glass transition temperature of 0° C. to 200° C. The lower limit of the glass transition temperature is preferably 10° C. or higher and more preferably 30° C. or higher. The upper limit of the glass transition temperature is preferably 100° C. or lower and more preferably 70° C. or lower. When the glass transition temperature of the resin layer is within the above range, peeling or the like at an interface with the adjacent layer can be suppressed. In the present invention, the glass transition temperature of the resin layer is measured by differential scanning calorimetry (DSC). In the present invention, if the resin layer has two or more glass transition temperatures, a lower glass transition temperature is employed as the glass transition temperature in the present invention.

The resin layer 20 sometimes contains a trace amount of infrared absorber as a result of the movement of the infrared absorber from the first infrared absorbing layer 10 and the second infrared absorbing layer 30. However, the resin layer 20 in the present invention is a layer that substantially does not exhibit infrared absorbing properties and that is different from the infrared absorbing layers. The content of the infrared absorber in the resin layer 20 is preferably 20 mass % or less and more preferably 15 mass % or less based on the mass of the resin layer. The lower limit of the content may be, for example, 0 mass % or more.

The resin layer 20 can be formed using a resin composition including a resin. For example, the resin layer 20 can be formed by applying a resin composition onto the first infrared absorbing layer 10, the second infrared absorbing layer 30, or the like. Examples of the method for applying the resin composition include a dropping method (drop casting), coating with a spin coater, coating with a slit spin coater, coating with a slit coater, screen printing, and coating with an applicator. Hereafter, the resin composition will be described.

### Resin Composition

### Resin

The resin composition may contain any resin. A resin that transmits at least near-infrared radiation (preferably light having a wavelength of 700 to 1200 nm) can be preferably used. The resin preferably transmits visible light and near-infrared radiation. Examples of the resin include (meth)acrylic resins, styrene resins, epoxy resins, enethiol resins, polycarbonate resins, polyether resins, polyarylate resins, polysulfone resins, polyethersulfone resins, poly(p-phenylene) resins, poly(arylene ether phosphine oxide) resins, polyimide resins, polyamide resins, polyamide-imide resins, polyolefin resins, cyclic olefin resins, polyester resins, maleimide resins, acrylonitrile resins, polyvinyl acetal resins, poly(N-vinyl acetamide) resins, polyvinylpyrrolidone resins, fluorene polycarbonate resins, fluorene polyester resins, polyethylene naphthalate resins, fluorinated aromatic polymer resins, allyl ester resins, and silsesquioxane resins. These resins may be used alone or in combination of two or more as a mixture. For the above resins, the description in paragraphs 0056 to 0060 in JP2014-218597A and the description in paragraphs 0074 to 0156 in JP2013-218312A can be taken into consideration, the contents of which are incorporated herein.

The resin preferably has a weight-average molecular weight (Mw) of 2,000 to 2,000,000. The upper limit of the weight-average molecular weight (Mw) is preferably 1,000,000 or less and more preferably 500,000 or less. The lower limit of the weight-average molecular weight (Mw) is preferably 3,000 or more and more preferably 5,000 or more.

In the case of epoxy resins, the weight-average molecular weight (Mw) is preferably 100 or more and more preferably 200 to 2,000,000. The upper limit of the weight-average molecular weight (Mw) is preferably 1,000,000 or less and more preferably 500,000 or less.

The temperature at which 5% of the mass of the resin is reduced when the resin is heated from 25° C. at 20° C./min is preferably 200° C. or higher and more preferably 260° C. or higher.

An example of the (meth)acrylic resin is a polymer including a structural unit derived from (meth)acrylic acid and/or (meth)acrylic acid esters. Specifically, the polymer is obtained by polymerizing at least one selected from the group consisting of (meth)acrylic acid, (meth)acrylic acid esters, (meth)acrylamide, and (meth)acrylonitrile. Examples of commercially available polymers include Cyclomer P ACA230AA and Cyclomer P ACA21013 (manufactured by Daicel Corporation), BGM-601 (manufactured by Osaka Organic Chemical Industry Ltd.), and Acrycure RD-F8 (manufactured by Nippon Shokubai Co., Ltd.).

Examples of the polyester resin include polymers obtained through reaction of a polyol (e.g., ethylene glycol, propylene glycol, glycerol, and trimethylolpropane) and a polybasic acid (e.g., an aromatic dicarboxylic acid such as terephthalic acid, isophthalic acid, or naphthalenedicarboxylic acid; an aromatic dicarboxylic acid obtained by substituting a hydrogen atom of the aromatic nucleus of the foregoing with a methyl group, an ethyl group, a phenyl group, or the like; an aliphatic dicarboxylic acid having 2 to 20 carbon atoms, such as adipic acid, sebacic acid, or dodecanedicarboxylic acid; and an alicyclic dicarboxylic acid such as cyclohexanedicarboxylic acid) and polymers (e.g., polycaprolactone) obtained through ring-opening polymerization of a cyclic ester compound such as a caprolactone monomer.

Examples of the epoxy resin include bisphenol A epoxy resins, bisphenol F epoxy resins, phenol novolac epoxy resins, cresol novolac epoxy resins, and aliphatic epoxy resins. For example, commercially available epoxy resins are as follows.

Examples of the bisphenol A epoxy resins include JER 827, JER 828, JER 834, JER 1001, JER 1002, JER 1003, JER 1055, JER 1007, JER 1009, and JER 1010 (all manufactured by Mitsubishi Chemical Corporation); and EPICLON 860, EPICLON 1050, EPICLON 1051, and EPICLON 1055 (all manufactured by DIC Corporation).

Examples of the bisphenol F epoxy resins include JER 806, JER 807, JER 4004, JER 4005, JER 4007, and JER 4010 (all manufactured by Mitsubishi Chemical Corporation); EPICLON 830 and EPICLON 835 (all manufactured by DIC Corporation); and LCE-21 and RE-602S (all manufactured by Nippon Kayaku Co., Ltd.).

Examples of the phenol novolac epoxy resins include JER 152, JER 154, JER 157S70, and JER 157S65 (all manufactured by Mitsubishi Chemical Corporation); and EPICLON N-740, EPICLON N-740, EPICLON N-770, and EPICLON N-775 (all manufactured by DIC Corporation).

Examples of the cresol novolac epoxy resins include EPICLON N-660, EPICLON N-665, EPICLON N-670, EPICLON N-673, EPICLON N-680, EPICLON N-690, and EPICLON N-695 (all manufactured by DIC Corporation); and EOCN-1020 (manufactured by Nippon Kayaku Co., Ltd.).

Examples of the aliphatic epoxy resins include ADEKA RESIN EP-4080S, ADEKA RESIN EP-4085S, and ADEKA RESIN EP-4088S (all manufactured by ADEKA Corporation); Celloxide 2021P, Celloxide 2081, Celloxide 2083, Celloxide 2085, EHPE3150, EPOLEAD PB3600, and EPOLEAD PB4700 (all manufactured by Daicel Corporation); and Denacol EX-212L, EX-214L, EX-216L, EX-321L, and EX-850L (all manufactured by Nagase ChemteX Corporation).

Other examples include ADEKA RESIN EP-4000S, ADEKA RESIN EP-4003S, ADEKA RESIN EP-4010S, and ADEKA RESIN EP-4011S (all manufactured by ADEKA Corporation); NC-2000, NC-3000, NC-7300, XD-1000, EPPN-501, and EPPN-502 (all manufactured by ADEKA Corporation); JER 1031S (manufactured by Mitsubishi Chemical Corporation); and Ripoxy SPCF-9X (manufactured by Showa Denko K.K.).

The resin may have an acid group. Examples of the acid group include a carboxy group, a phosphate group, a sulfonate group, and a phenolic hydroxy group. The resin may have only one acid group or two or more acid groups. For the resin having an acid group, an alkali-soluble resin described in paragraphs 0180 to 0202 in JP2015-043063A is exemplified, the contents of which are incorporated herein. The acid value of the resin having an acid group is preferably 30 to 200 mgKOH/g. The lower limit of the acid value is preferably 50 mgKOH/g or more and more preferably 70 mgKOH/g or more. The upper limit of the acid value is preferably 150 mgKOH/g or less and more preferably 120 mgKOH/g or less.

The resin may have a crosslinking group. Examples of the crosslinking group include groups having an ethylenically unsaturated bond, cyclic ether groups, methylol groups, and groups represented by -M-(X²)ₙ described below. The resin having a crosslinking group is, for example, a resin including a structural unit having a crosslinking group or the above-described epoxy resin. Examples of the structural unit having a crosslinking group include structural units represented by formulae (A2-1) to (A2-4) below.

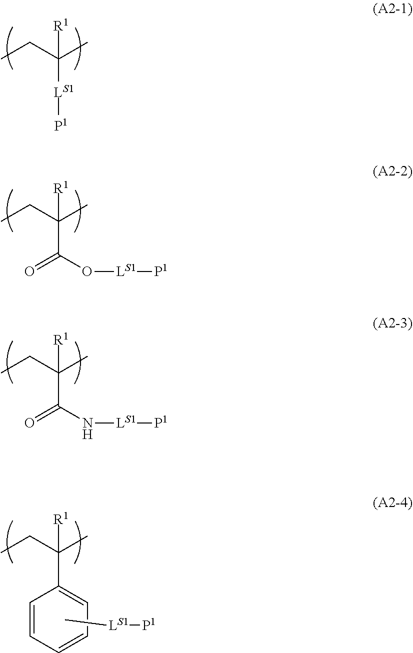

R¹ represents a hydrogen atom or an alkyl group. The number of carbon atoms in the alkyl group is preferably 1 to 5, more preferably 1 to 3, and particularly preferably 1. R¹ preferably represents a hydrogen atom or a methyl group.

L⁵¹ represents a single bond or a divalent linking group. Examples of the divalent linking group include alkylene groups, arylene groups, —O—, —S—, —CO—, —COO—, —OCO—, —SO₂—, —NR¹⁰— (R¹⁰ represents a hydrogen atom or an alkyl group and preferably represents a hydrogen atom), or groups obtained by combining the foregoing groups. Preferred examples of the divalent linking group include alkylene groups and groups obtained by combining at least one of arylene groups or alkylene groups and —O—. The number of carbon atoms in the alkylene group is preferably 1 to 30, more preferably 1 to 15, and further preferably 1 to 10. The alkylene group may have a substituent, but is preferably unsubstituted. The alkylene group is a linear, branched, or cyclic alkylene group. The cyclic alkylene group is a monocyclic or polycyclic alkylene group. The number of carbon atoms in the arylene group is preferably 6 to 18, more preferably 6 to 14, and further preferably 6 to 10.

P¹ represents a crosslinking group. Examples of the crosslinking group include groups having an ethylenically unsaturated bond, cyclic ether groups, methylol groups, and groups represented by -M-(X²)ₙ. In the groups represented by -M-(X²)ₙ, M represents an atom selected from the group consisting of Si, Ti, Zr, and Al; X² represents a substituent or a ligand; at least one of nX² represents one group selected from the group consisting of a hydroxy group, an alkoxy group, an acyloxy group, a phosphoryloxy group, a sulfonyloxy group, an amino group, an oxime group, and O═C(R^{a})(R^{b}); X² may bond to each other to form a ring; and n represents the number of bonding arms of M with X².

The group having an ethylenically unsaturated is, for example, a vinyl group, a styryl group, a (meth)allyl group, or a (meth)acryloyl group and preferably a (meth)allyl group or a (meth)acryloyl group. The cyclic ether group is, for example, an epoxy group or an oxetanyl group and preferably an epoxy group.

In the groups represented by M-(X²)ₙ, M represents an atom selected from the group consisting of Si, Ti, Zr, and Al. M preferably represents Si, Ti, or Zr and more preferably represents Si.

X² represents a substituent or a ligand; at least one of nX² represents one group selected from the group consisting of a hydroxy group, an alkoxy group, an acyloxy group, a phosphoryloxy group, a sulfonyloxy group, an amino group, an oxime group, and O═C(R^{a})(R^{b}); and X² may bond to each other to form a ring. At least one of nX² preferably represents one group selected from the group consisting of an alkoxy group, an acyloxy group, and an oxime group. At least one of nX² more preferably represents an alkoxy group and all X² more preferably represent an alkoxy group. When X² represents O═C(R^{a})(R^{b}), X² bonds to M through an unshared electron pair of an oxygen atom in the carbonyl group (—CO—). R^{a} and R^{b} each independently represent a monovalent organic group.

The number of carbon atoms in the alkoxy group represented by X² is preferably 1 to 20, more preferably 1 to 10, further preferably 1 to 5, and particularly preferably 1 or 2. The alkoxy group is a linear, branched, or cyclic alkoxy group, and is preferably a linear or branched alkoxy group and more preferably a linear alkoxy group. The alkoxy group may be unsubstituted or may have a substituent, but is preferably unsubstituted. Examples of the substituent include halogen atoms (preferably a fluorine atom), a vinyl group, a (meth)acryloyl group, a styryl group, an epoxy group, an oxetanyl group, an amino group, an isocyanate group, an isocyanurate group, a ureido group, a mercapto group, a sulfide group, a sulfo group, a carboxy group, and a hydroxy group.

Examples of the acyloxy group represented by X² include substituted or unsubstituted alkylcarbonyloxy groups having 2 to 30 carbon atoms and substituted or unsubstituted arylcarbonyloxy groups having 6 to 30 carbon atoms. Examples of the substituent include the above-described substituents.

The number of carbon atoms in the oxime group represented by X² is preferably 1 to 20, more preferably 1 to 10, and further preferably 1 to 5. The oxime group is, for example, an ethyl methyl ketoxime group.

Examples of the amino group represented by X² include an amino group, substituted or unsubstituted alkylamino groups having 1 to 30 carbon atoms, substituted or unsubstituted arylamino groups having 6 to 30 carbon atoms, and heterocyclic amino groups having 0 to 30 carbon atoms. Examples of the substituent include the above-described substituents.

When X² represents O═C(R^{a})(R^{b}), examples of the monovalent organic group represented by R^{a} and R^{b} include alkyl groups, aryl groups, and groups represented by —R¹⁰¹—COR¹⁰². The number of carbon atoms in the alkyl group is preferably 1 to 20 and more preferably 1 to 10. The alkyl group is a linear, branched, or cyclic alkyl group. The alkyl group may be unsubstituted or may have any of the above-described substituents. The number of carbon atoms in the aryl group is preferably 6 to 20 and more preferably 6 to 12. The aryl group may be unsubstituted or may have any of the above-described substituents. In the group represented by —R¹⁰¹—COR¹⁰², R¹⁰¹ represents an arylene group and R¹⁰² represents an alkyl group or an aryl group. The number of carbon atoms in the arylene group represented by R¹⁰¹ is preferably 1 to 20 and more preferably 1 to 10. The arylene group is a linear, branched, or cyclic arylene group. The arylene group may be unsubstituted or may have any of the above-described substituents. The alkyl group and the aryl group represented by R¹⁰² are the same as those described in R^{a} and R^{b}, and the preferred ranges thereof are also the same.

Among the substituents and ligands represented by X², substituents other than a hydroxy group, an alkoxy group, an acyloxy group, a phosphoryloxy group, a sulfonyloxy group, an amino group, and an oxime group are preferably hydrocarbon groups. Examples of the hydrocarbon groups include alkyl groups, alkenyl groups, and aryl groups. The alkyl group is a linear, branched, or cyclic alkyl group. The number of carbon atoms in the linear alkyl group is preferably 1 to 20, more preferably 1 to 12, and further preferably 1 to 8. The number of carbon atoms in the branched alkyl group is preferably 3 to 20, more preferably 3 to 12, and further preferably 3 to 8. The cyclic alkyl group is a monocyclic or polycyclic alkyl group. The number of carbon atoms in the cyclic alkyl group is preferably 3 to 20, more preferably 4 to 10, and further preferably 6 to 10. The number of carbon atoms in the alkenyl group is preferably 2 to 10, more preferably 2 to 8, and further preferably 2 to 4. The number of carbon atoms in the aryl group is preferably 6 to 18, more preferably 6 to 14, and further preferably 6 to 10. The hydrocarbon group may have a substituent. Examples of the substituent include alkyl groups, halogen atoms (preferably a fluorine atom), a vinyl group, a (meth)acryloyl group, a styryl group, an epoxy group, an oxetanyl group, an amino group, an isocyanate group, an isocyanurate group, a ureido group, a mercapto group, a sulfide group, a sulfo group, a carboxy group, a hydroxy group, and alkoxy groups.

When the resin includes a structural unit having a crosslinking group, the content of the structural unit having a crosslinking group is preferably 5 to 100 mol % based on all structural units constituting the polymer. The lower limit of the content is more preferably 10 mol % or more and further preferably 15 mol % or more. The upper limit of the content is more preferably 90 mol % or less, further preferably 80 mol % or less, and particularly preferably 70 mol % or less.

Examples of the resin having a crosslinking group include Dianal NR series (manufactured by Mitsubishi Rayon Co., Ltd.), Photomer 6173 (COOH-containing polyurethane acrylic oligomer, manufactured by Diamond Shamrock Co., Ltd.), Viscoat R-264 and KS Resist 106 (both manufactured by Osaka Organic Chemical Industry Ltd.), Cyclomer P series (e.g., ACA230AA) and Placcel CF200 series (both manufactured by Daicel Corporation), Ebecryl 3800 (manufactured by Daicel-UCB Company, Ltd.), and Acrycure RD-F8 (manufactured by Nippon Shokubai Co., Ltd.). The above-described epoxy resin is also exemplified. The following resins can also be used.

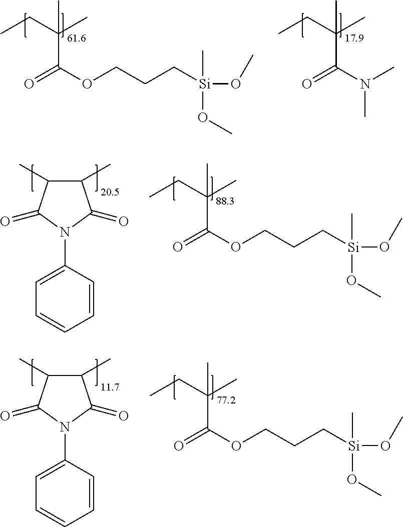

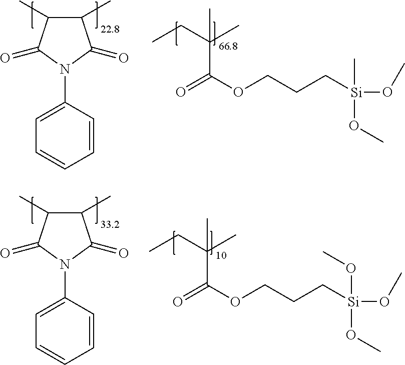

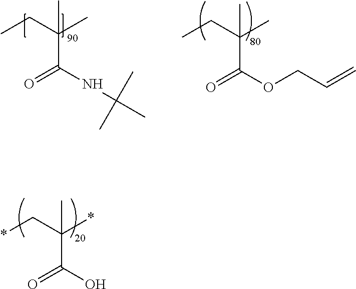

In the present invention, the resin also preferably has structural units represented by formulae (A3-1) to (A3-6) below.

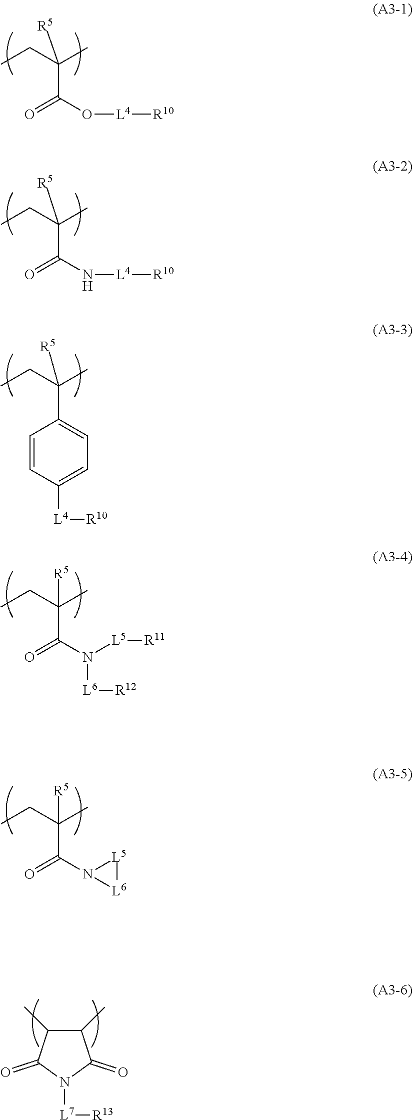

In the formulae, R⁵ represents a hydrogen atom or an alkyl group, L⁴ to L⁷ each independently represent a single bond or a divalent linking group, and R¹⁰ to R¹³ each independently represent an alkyl group or an aryl group.

R⁵ has the same meaning as R¹ in the formulae (A2-1) to (A2-4), and the preferred range thereof is also the same.

L⁴ to L⁷ have the same meaning as L¹ in the formulae (A2-1) to (A2-4), and the preferred ranges thereof are also the same.

The alkyl group represented by R¹⁰ is a linear, branched, or cyclic alkyl group and preferably a cyclic alkyl group. The alkyl group may have any of the above-described substituents or may be unsubstituted. The number of carbon atoms in the alkyl group is preferably 1 to 30, more preferably 1 to 20, and further preferably 1 to 10. The number of carbon atoms in the aryl group represented by R¹⁰ is preferably 6 to 18, more preferably 6 to 12, and further preferably 6. R¹⁰ preferably represents a cyclic alkyl group or an aryl group.

The alkyl group represented by R¹¹ and R¹² is a linear, branched, or cyclic alkyl group and is preferably a linear or branched alkyl group. The alkyl group may have any of the above-described substituents or may be unsubstituted. The number of carbon atoms in the alkyl group is preferably 1 to 12, more preferably 1 to 6, and further preferably 1 to 4. The number of carbon atoms in the aryl group represented by R¹¹ and R¹² is preferably 6 to 18, more preferably 6 to 12, and further preferably 6. R¹¹ and R¹² preferably represent a linear or branched alkyl group.

The alkyl group represented by R¹³ is a linear, branched, or cyclic alkyl group and preferably a linear or branched alkyl group. The alkyl group may have any of the above-described substituents or may be unsubstituted. The number of carbon atoms in the alkyl group is preferably 1 to 12, more preferably 1 to 6, and further preferably 1 to 4. The number of carbon atoms in the aryl group represented by R¹³ is preferably 6 to 18, more preferably 6 to 12, and further preferably 6. R¹³ preferably represents a linear or branched alkyl group or an aryl group.

In the present invention, the resin may be a resin having at least one of the structural units represented by the formulae (A2-1) to (A2-4) and at least one of the structural units represented by the formulae (A3-1) to (A3-6). In this case, the molar ratio of the total content of the structural units represented by the formulae (A2-1) to (A2-4) and the total content of the structural units represented by the formulae (A3-1) to (A3-6) is preferably 95:5 to 20:80 and more preferably 90:10 to 40:60.

The content of the resin in the resin composition is preferably 50 to 100 mass % based on the total solid content of the resin composition. The lower limit of the content is preferably 60 mass % or more and more preferably 70 mass % or more. The upper limit of the content may be, for example, 95 mass % or less or 90 mass % or less.

### Solvent

The resin composition may contain a solvent. The solvent is not particularly limited and can be appropriately selected in accordance with the purpose as long as each component in the resin composition can be homogeneously dissolved or dispersed in the solvent. The solvent is, for example, water or an organic solvent and is preferably an organic solvent.

Examples of the organic solvent include alcohols (e.g., methanol), ketones, esters, aromatic hydrocarbons, halogenated hydrocarbons, dimethylformamide, dimethylacetamide, dimethyl sulfoxide, and sulfolane. The alcohols, the aromatic hydrocarbons, and the halogenated hydrocarbons are specifically listed in paragraph 0136 in JP2012-194534A, the contents of which are incorporated herein. The esters, the ketones, and the ethers are specifically listed in paragraph 0497 in JP2012-208494A (paragraph 0609 in corresponding US2012/0235099A).

Examples of the esters include ethyl acetate, n-butyl acetate, isobutyl acetate, cyclohexyl acetate, amyl formate, isoamyl acetate, isobutyl acetate, butyl propionate, isopropyl butyrate, ethyl butyrate, butyl butyrate, methyl lactate, ethyl lactate, alkyl oxyacetates (e.g., methyl oxyacetate, ethyl oxyacetate, and butyl oxyacetate (for example, methyl methoxyacetate, ethyl methoxyacetate, butyl methoxyacetate, methyl ethoxyacetate, and ethyl ethoxyacetate)), alkyl 3-oxypropionates (e.g., methyl 3-oxypropionate and ethyl 3-oxypropionate (for example, methyl 3-methoxypropionate, ethyl 3-methoxypropionate, methyl 3-ethoxypropionate, and ethyl 3-ethoxypropionate)), alkyl 2-oxypropionates (e.g., methyl 2-oxypropionate, ethyl 2-oxypropionate, and propyl 2-oxypropionate (for example, methyl 2-methoxypropionate, ethyl 2-methoxypropionate, propyl 2-methoxypropionate, methyl 2-ethoxypropionate, and ethyl 2-ethoxypropionate)), methyl 2-oxy-2-methylpropionate and ethyl 2-oxy-2-methylpropionate (e.g., methyl 2-methoxy-2-methylpropionate and ethyl 2-ethoxy-2-methylpropionate), methyl pyruvate, ethyl pyruvate, propyl pyruvate, methyl acetoacetate, ethyl acetoacetate, methyl 2-oxobutanoate, and ethyl 2-oxobutanoate.

Examples of the ethers include diethylene glycol dimethyl ether, tetrahydrofuran, ethylene glycol monomethyl ether, ethylene glycol monoethyl ether, methyl cellosolve acetate, ethyl cellosolve acetate, diethylene glycol monomethyl ether, diethylene glycol monoethyl ether, diethylene glycol monobutyl ether, propylene glycol monomethyl ether, propylene glycol monomethyl ether acetate, propylene glycol monoethyl ether acetate, and propylene glycol monopropyl ether acetate.

Examples of the ketones include methyl ethyl ketone, cyclohexanone, cyclopentanone, 2-heptanone, and 3-heptanone.

Examples of the aromatic hydrocarbons include toluene and xylene.

These organic solvents may be used alone or in combination of two or more. When the organic solvents are used in combination of two or more, a mixed solution is particularly preferably used that contains two or more solvents selected from the group consisting of methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, ethyl carbitol acetate, butyl carbitol acetate, propylene glycol methyl ether, and propylene glycol methyl ether acetate.

The content of the solvent in the resin composition is preferably controlled so that the solid content is 10 to 90 mass %. The lower limit is preferably 15 mass % or more and more preferably 20 mass % or more. The upper limit is preferably 80 mass % or less and more preferably 70 mass % or less.

### Other Components

The resin composition may include a crosslinking compound, a photopolymerization initiator, a polymerization inhibitor, a surfactant, an ultraviolet absorber, and the like. The details of these components will be described in the infrared absorbing composition later. The resin composition may further include a dispersing agent, a sensitizing agent, a curing accelerator, a filler, a plasticizer, an adhesion accelerator, and other auxiliary agents (e.g., conductive particles, a filling material, an anti-foaming agent, a flame retardant, a leveling agent, a peeling accelerator, an antioxidant, a perfume, a surface tension adjuster, and a chain transfer agent). For these components, for example, the description in paragraphs 0183 to 0228 in JP2012-003225A (paragraphs 0237 to 0309 in corresponding US2013/0034812A), the description in paragraphs 0101 and 0102, 0103 and 0104, and 0107 to 0109 in JP2008-250074A, and the description in paragraphs 0159 to 0184 in JP2013-195480A can be taken into consideration, the contents of which are incorporated herein.

Preferably, the resin composition substantially does not include an infrared absorber. The infrared absorber will be described in the infrared absorbing layer later. The phrase “the resin composition substantially does not include an infrared absorber” means that, for example, the content of the infrared absorber in the resin composition is preferably 0.1 mass % or less and more preferably 0.01 mass % or less based on the total solid content of the resin composition, and further preferably the infrared absorber is not included.

### Method for Preparing Resin Composition

The resin composition can be prepared by mixing the above-described components. The resin composition may be prepared by mixing all the components at a time or by dissolving or dispersing each component in a solvent and then mixing the components one by one. The order of charging and the operational conditions in the mixing are not particularly limited.

In the preparation of the resin composition, filtration is preferably performed using a filter for the purpose of, for example, removing foreign matter and suppressing formation of defects. Any filter that has been used for filtration or the like can be used. The filter is formed of, for example, a fluorocarbon resin such as polytetrafluoroethylene (PTFE), a polyamide resin such as nylon (e.g., nylon-6 and nylon-6,6), or a polyolefin resin (including a high-density resin and an ultrahigh-molecular-weight resin) such as polyethylene or polypropylene (PP). In particular, polypropylene (including high-density polypropylene) and nylon are preferred.

The pore size of the filter is suitably about 0.01 to 7.0 μm, preferably about 0.01 to 3.0 μm, and more preferably about 0.05 to 0.5 μm. When the pore size is within the above range, fine foreign matter that inhibits the preparation of a homogeneous and smooth composition in a process performed later can be removed with certainty. Fibrous filter media are preferably used. Examples of the filter media include polypropylene fiber, nylon fiber, and glass fiber. Specifically, filter cartridges manufactured by ROKI TECHNO Co., Ltd., such as SBP series (e.g., SBP008), TPR series (e.g., TPR002 and TPR005), and SHPX series (e.g., SHPX003), can be used.

When the filter is used, different filters may be combined with each other. In this case, filtering with a first filter may be performed only once or may be performed twice or more.

Furthermore, first filters having pore sizes different from each other within the above range may be combined with each other. For the pore size herein, consult the nominal values provided by filter manufacturers. Commercially available filters can be selected from various filters provided by, for example, Pall Corporation (e.g., DFA4201NXEY), Advantec Toyo Kaisha, Ltd., Nihon Entegris K.K. (former Nihon Mykrolis), or KITZ MICROFILTER Corporation.

The second filter may be formed of the same material as the first filter.

### First Infrared Absorbing Layer 10 and Second Infrared Absorbing Layer 30

The near-infrared cut filter has a first infrared absorbing layer 10 and a second infrared absorbing layer 30. The first infrared absorbing layer 10 and a resin layer 20 are preferably in contact with each other. The resin layer 20 and the second infrared absorbing layer 30 are preferably in contact with each other. The first infrared absorbing layer 10 and the second infrared absorbing layer 30 each include an infrared absorber. An infrared absorber A included in the first infrared absorbing layer 10 and an infrared absorber C included in the second infrared absorbing layer 30 may be the same or different. Hereafter, the first infrared absorbing layer 10 and the second infrared absorbing layer 30 are also collectively referred to as an infrared absorbing layer.

In the present invention, the infrared absorber refers to a compound that absorbs light in the infrared wavelength range (preferably in the wavelength range of 700 to 1200 nm) and that transmits light in the visible wavelength range (preferably in the wavelength range of 400 to 650 nm). The infrared absorber is preferably a compound that has a maximum absorption wavelength in the range of 700 to 1200 nm and more preferably a compound that has a maximum absorption wavelength in the range of 650 to 1000 nm.

Examples of the infrared absorber include copper compounds, pyrrolopyrrole compounds, squarylium compounds, cyanine compounds, phthalocyanine compounds, naphthalocyanine compounds, diimmonium compounds, thiol complex compounds, transition metal oxide compounds, quaterrylene compounds, and croconium compounds. In particular, copper compounds, pyrrolopyrrole compounds, squarylium compounds, cyanine compounds, phthalocyanine compounds, and naphthalocyanine compounds are preferred because a film having both good near-infrared shielding properties and good visible-light transmitting properties is easily formed. Furthermore, the pyrrolopyrrole compounds, the squarylium compounds, the cyanine compounds, the phthalocyanine compounds, and the naphthalocyanine compounds are preferably dyes (i.e., pyrrolopyrrole dyes, squarylium dyes, cyanine dyes, phthalocyanine dyes, and naphthalocyanine dyes).

In the present invention, at least one of the infrared absorber A or the infrared absorber C is preferably a copper compound. In this case, the other infrared absorber may be a copper compound or an infrared absorber other than the copper compound. The infrared absorber other than the copper compound is preferably an organic dye. In the present invention, the organic dye refers to a dye formed of an organic compound having a colorant skeleton.

In the present invention, at least one of the infrared absorber A or the infrared absorber C is preferably one compound selected from the group consisting of pyrrolopyrrole compounds, squarylium compounds, cyanine compounds, phthalocyanine compounds, and naphthalocyanine compounds. In this case, the other infrared absorber may be any of the above compounds or may be an infrared absorber other than the above compounds (e.g., a copper compound or an organic dye other than a copper compound).

In the present invention, preferably, at least one of the infrared absorber A or the infrared absorber C is a copper compound and the other is at least one selected from the group consisting of pyrrolopyrrole compounds, squarylium compounds, cyanine compounds, phthalocyanine compounds, and naphthalocyanine compounds. With this combination, infrared radiation in a wide wavelength range can be shielded, which can provide a near-infrared cut filter having excellent infrared shielding properties. Furthermore, a near-infrared cut filter having lower haze is easily produced.

In the present invention, also preferably, at least one of the infrared absorber A or the infrared absorber C is a compound (infrared absorber) having a maximum absorption wavelength in the wavelength range of 650 to 850 nm and the other is a compound (infrared absorber) having a maximum absorption wavelength in the wavelength range of 700 to 1000 nm. The difference in maximum absorption wavelength between the infrared absorber A and the infrared absorber C is preferably 50 nm or more and more preferably 100 nm or more. The upper limit of the difference is preferably 300 nm or less and more preferably 200 nm or less. With this combination, infrared radiation in a wide wavelength range can be shielded, which can provide a near-infrared cut filter having excellent infrared shielding properties. The compound (infrared absorber) having a maximum absorption wavelength in the wavelength range of 700 to 1000 nm is preferably a copper compound. The compound (infrared absorber) having a maximum absorption wavelength in the wavelength range of 650 to 850 nm is preferably a pyrrolopyrrole compound, a squarylium compound, a cyanine compound, a phthalocyanine compound, or a naphthalocyanine compound.

Hereafter, the infrared absorber will be described in detail.

### Copper Compound

In the present invention, the copper compound used as the infrared absorber is preferably a copper complex. The copper complex is preferably a complex of copper and a compound (ligand) having a coordination site for copper. The coordination site for copper is a coordination site that undergoes coordination in the form of anion or a coordinating atom that coordinates through an unshared electron pair. The copper complex may have two or more ligands. When the copper complex has two or more ligands, the ligands may be the same or different. The coordination number of the copper complex is, for example, 4, 5, or 6, preferably 4 or 5, and more preferably 5. In the copper complex, a five-membered ring and/or a six-membered ring is preferably formed by copper and the ligand. Such a copper complex has a stable shape and thus has high complex stability.

In the present invention, the copper complex is also preferably a copper complex other than phthalocyanine copper complexes. Herein, the phthalocyanine copper complex refers to a copper complex including, as a ligand, a compound having a phthalocyanine skeleton. The compound having a phthalocyanine skeleton has a planar structure in which a π electron conjugated system expands throughout the molecule. The phthalocyanine copper complex absorbs light with π-π* transition. To absorb light in an infrared range with π-π* transition, a compound serving as a ligand needs to have a long conjugated structure. However, if the conjugated structure of a ligand is lengthened, visible-light transmitting properties tend to deteriorate. Therefore, the phthalocyanine copper complex sometimes has insufficient visible-light transmitting properties.

The copper complex is also preferably a copper complex including, as a ligand, a compound that does not have a maximum absorption wavelength in the wavelength range of 400 to 600 nm. Since the copper complex including, as a ligand, a compound having a maximum absorption wavelength in the wavelength range of 400 to 600 nm exhibits absorption in the visible wavelength range (e.g., in the wavelength range of 400 to 600 nm), the copper complex sometimes has insufficient visible-light transmitting properties. The compound having a maximum absorption wavelength in the wavelength range of 400 to 600 nm is, for example, a compound that has a long conjugated structure and absorbs a large amount of light with π-π* transition. A compound having a phthalocyanine skeleton is specifically given as an example.

The copper complex can be obtained by, for example, mixing/reacting a compound (ligand) having a coordination site for copper with a copper component (copper or copper-containing compound). The compound (ligand) having a coordination site for copper may be a low-molecular-weight compound or a polymer. Both of them may be used in combination.

The copper component is preferably a divalent-copper-containing compound. Only one copper component may be used or two or more copper components may be used. The copper component may be, for example, copper oxide or a copper salt. Preferred examples of the copper salt include copper carboxylates (e.g., copper acetate, copper ethylacetoacetate, copper formate, copper benzoate, copper stearate, copper naphthenate, copper citrate, and copper 2-ethylhexanoate), copper sulfonates (e.g., copper methanesulfonate), copper phosphate, copper organophosphate, copper phosphonate, copper organophosphonate, copper phosphinate, copper amide, copper sulfonamide, copper imide, copper acyl sulfonimide, copper bis(sulfonimide), copper methide, alkoxy copper, phenoxy copper, copper hydroxide, copper carbonate, copper sulfate, copper nitrate, copper perchlorate, copper fluoride, copper chloride, and copper bromide. More preferred examples of the copper salt include copper carboxylates, copper sulfonates, copper sulfonamide, copper imide, copper acyl sulfonimide, copper bis(sulfonimide), alkoxy copper, phenoxy copper, copper hydroxide, copper carbonate, copper fluoride, copper chloride, copper sulfate, and copper nitrate. Further preferred examples of the copper salt include copper carboxylates, copper acyl sulfonimide, phenoxy copper, copper chloride, copper sulfate, and copper nitrate. Particularly preferred examples of the copper salt include copper carboxylates, copper acyl sulfonimide, copper chloride, and copper sulfate.

In the present invention, the copper complex is preferably a compound having a maximum absorption wavelength in the wavelength range of 700 to 1200 nm. The maximum absorption wavelength of the copper complex is more preferably in the range of 720 to 1200 nm and further preferably in the range of 800 to 1100 nm. The maximum absorption wavelength can be measured by using, for example, Cary 5000 UV-Vis-NIR (spectrophotometer manufactured by Agilent Technologies Japan, Ltd.).

The molar extinction coefficient of the copper complex at a maximum absorption wavelength in the above wavelength range is preferably 120 (L/mol·cm) or more, more preferably 150 (L/mol·cm) or more, further preferably 200 (L/mol·cm) or more, still further preferably 300 (L/mol·cm) or more, and particularly preferably 400 (L/mol·cm) or more. The upper limit of the molar extinction coefficient is not particularly limited, but may be, for example, 30000 (L/mol·cm) or less. When the copper complex has a molar extinction coefficient of 100 (L/mol·cm) or more, a cured film having excellent infrared shielding properties can be formed even if the film is thin.

The gram extinction coefficient of the copper complex at 800 nm is preferably 0.11 (L/g·cm) or more, more preferably 0.15 (L/g·cm) or more, and further preferably 0.24 (L/g·cm) or more.

In the present invention, the molar extinction coefficient and the gram extinction coefficient of the copper complex can be determined by preparing a solution containing the copper complex dissolved in a solvent in a concentration of 1 g/L and measuring the absorption spectrum of the solution containing the copper complex dissolved therein. The measurement instrument is, for example, UV-1800 (wavelength range: 200 to 1100 nm) manufactured by SHIMADZU Corporation or Cary 5000 (wavelength range: 200 to 1300 nm) manufactured by Agilent Technologies Japan, Ltd. Examples of the solvent for measurement include water, N,N-dimethylformamide, propylene glycol monomethyl ether, 1,2,4-trichlorobenzene, and acetone. In the present invention, a solvent capable of dissolving the copper complex to be measured is selected from the above-described solvents for measurement. In particular, in the case of a copper complex that can be dissolved in propylene glycol monomethyl ether, the solvent for measurement is preferably propylene glycol monomethyl ether. The “dissolution” refers to a state in which the solubility of the copper complex in a solvent at 25° C. is more than 0.01 g/100 g solvent.

In the present invention, the molar extinction coefficient and the gram extinction coefficient of the copper complex are preferably measured using any one of the above-described solvents for measurement and more preferably measured using propylene glycol monomethyl ether.

### Low-Molecular-Weight Copper Compound

The copper compound may be, for example, a copper complex represented by formula (Cu-1) below. The copper complex is a copper compound in which a ligand L coordinates with copper serving as a central metal, the copper being normally a divalent copper. The copper compound can be obtained by, for example, mixing/reacting a compound serving as a ligand L or a salt thereof with a copper component.

Cu(L)ₙ₁.(X)ₙ₂ Formula (Cu-1)

In the formula, L represents a ligand that coordinates with copper, X represents a counterion, n1 represents an integer of 1 to 4, and n2 represents an integer of 0 to 4.

X represents a counterion. The copper compound may be, in addition to a neutral complex having no charges, a cationic complex or an anionic complex. In this case, when necessary, a counterion is present so as to neutralize the charge of the copper compound.

In the case of a negative counterion, the negative counterion may be, for example, an inorganic anion or an organic anion. Specific examples of the negative counterion include a hydroxide ion, halogen anions (e.g., a fluoride ion, a chloride ion, a bromide ion, and an iodide ion), substituted or unsubstituted alkylcarboxylate ions (e.g., an acetate ion and a trifluoroacetate ion), substituted or unsubstituted arylcarboxylate ions (e.g., a benzoate ion), substituted or unsubstituted alkylsulfonate ions (e.g., a methanesulfonate ion and a trifluoromethanesulfonate ion), substituted or unsubstituted arylsulfonate ions (e.g., a p-toluenesulfonate ion and a p-chlorobenzenesulfonate ion), aryldisulfonate ions (e.g., a 1,3-benzenedisulfonate ion, a 1,5-naphthalenedisulfonate ion, and a 2,6-naphthalenedisulfonate ion), alkylsulfate ions (e.g., a methylsulfate ion), a sulfate ion, a thiocyanate ion, a nitrate ion, a perchlorate ion, a tetrafluoroborate ion, tetraarylborate ions, a tetrakis(pentafluorophenyl)borate ion (B⁻(C₆F₅)₄), a hexafluorophosphate ion, a picrate ion, an amide ion (including an amide substituted with an acyl group or a sulfonyl group), and a methide ion (including a methide substituted with an acyl group or a sulfonyl group). Preferred examples of the negative counterion include halogen anions, substituted or unsubstituted alkylcarboxylate ions, a sulfate ion, a nitrate ion, a tetrafluoroborate ion, tetraarylborate ions, a hexafluorophosphate ion, an amide ion (including an amide substituted with an acyl group or a sulfonyl group) and a methide ion (including a methide substituted with an acyl group or a sulfonyl group).

In the case of a positive counterion, examples of the positive counterion include inorganic or organic ammonium ions (e.g., tetraalkylammonium ions such as a tetrabutylammonium ion, a triethylbenzylammonium ion, and a pyridinium ion), phosphonium ions (e.g., tetraalkylphosphonium ions such as a tetrabutylphosphonium ion, alkyltriphenylphosphonium ions, and a triethylphenylphosphonium ion), alkali metal ions, and a proton.

The counterion may be a metal complex ion. In particular, the counterion may be a copper complex, that is, a salt of a cationic copper complex and an anionic copper complex.

The ligand L is a compound having a coordination site for copper, which is a compound having one or more selected from the group consisting of a coordination site that coordinates with copper in the form of anion and a coordinating atom that coordinates with copper through an unshared electron pair. The coordination site that coordinates with copper in the form of anion may be dissociated or undissociated. The ligand L is preferably a compound (polydentate ligand) having two or more coordination sites for copper. In the ligand L, a plurality of π conjugated systems such as aromatic structures preferably do not bond to each other in a continuous manner to improve the transparency of visible light. For the ligand L, a compound (monodentate ligand) having one coordination site for copper and a compound (polydentate ligand) having two or more coordination sites for copper can be used in combination. The monodentate ligand is, for example, a monodentate ligand that undergoes coordination in the form of anion or through an unshared electron pair. Examples of the ligand that undergoes coordination in the form of anion include halide anions, a hydroxide anion, alkoxide anions, a phenoxide anion, an amide anion (including an amide substituted with an acyl group or a sulfonyl group), an imide anion (including an imide substituted with an acyl group or a sulfonyl group), an anilide anion (including an anilide substituted with an acyl group or a sulfonyl group), a thiolate anion, a hydrogencarbonate anion, a carboxylate anion, a thiocarboxylate anion, a dithiocarboxylate anion, a hydrogen sulfate anion, a sulfonate anion, a dihydrogen phosphate anion, a phosphodiester anion, a phosphonic acid monoester anion, a hydrogen phosphonate anion, a phosphinate anion, a nitrogen-containing heterocyclic anion, a nitrate anion, a hypochlorite anion, a cyanide anion, a cyanate anion, an isocyanate anion, a thiocyanate anion, an isothiocyanate anion, and an azide anion. Examples of the monodentate ligand that undergoes coordination through an unshared electron pair include water, alcohol, phenol, ether, amine, aniline, amide, imide, imine, nitrile, isonitrile, thiol, thioether, carbonyl compounds, thiocarbonyl compounds, sulfoxide, heterocycles; and carbonic acid, carboxylic acid, sulfuric acid, sulfonic acid, phosphoric acid, phosphonic acid, phosphinic acid, nitric acid, and the esters of the foregoing acids.

The anion of the ligand may be any anion capable of coordinating with a copper atom in the copper component and is preferably an oxygen anion, a nitrogen anion, or a sulfur anion. The coordination site that undergoes coordination in the form of anion is preferably at least one selected from the group consisting of the following group of monovalent functional groups (AN-1) and the following group of divalent functional groups (AN-2). Herein, the wavy line in the structural formulae below refers to a bonding position with an atomic group constituting the ligand.

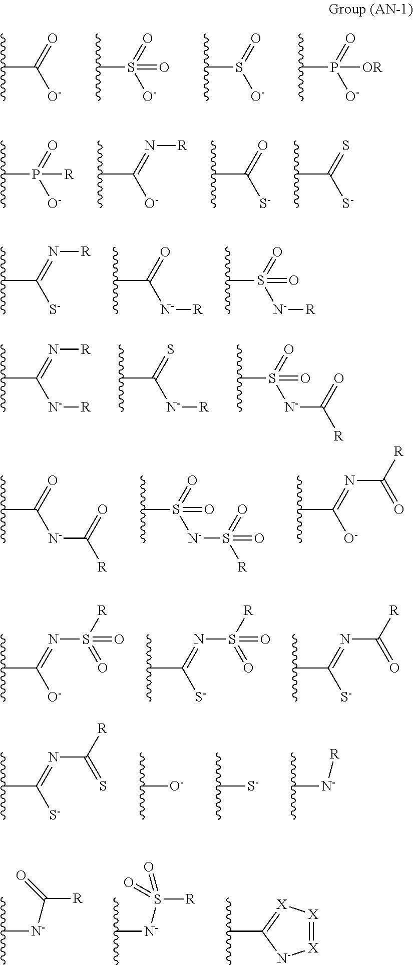

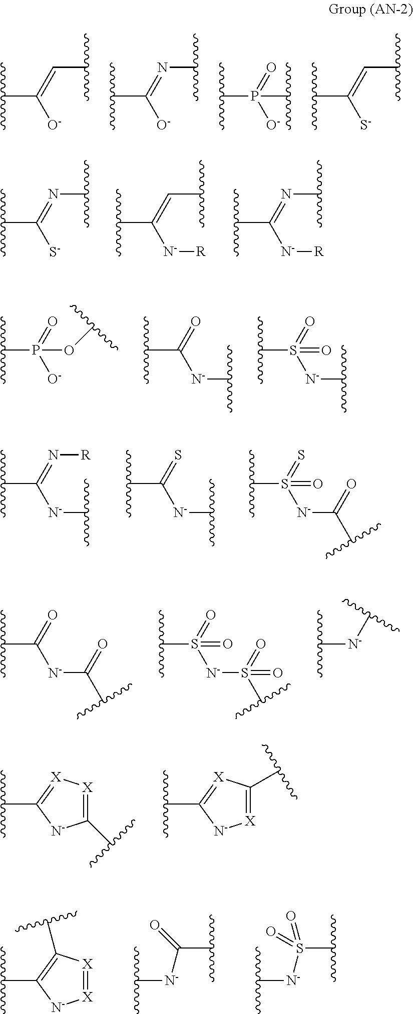

In the above formulae, X represents N or CR, and R each independently represent a hydrogen atom, an alkyl group, an alkenyl group, an alkynyl group, an aryl group, or a heteroaryl group.

The alkyl group represented by R is a linear, branched, or cyclic alkyl group and preferably a linear alkyl group. The number of carbon atoms in the alkyl group is preferably 1 to 10, more preferably 1 to 6, and further preferably 1 to 4. The alkyl group is, for example, a methyl group. The alkyl group may have a substituent, and examples of the substituent include halogen atoms, carboxy groups, and heterocyclic groups. The heterocyclic group serving as a substituent is a monocyclic or polycyclic group and is an aromatic or non-aromatic group. The number of hetero atoms constituting the heterocycle is preferably 1 to 3 and more preferably 1 or 2. The hetero atom constituting the heterocycle is preferably a nitrogen atom. When the alkyl group has a substituent, another substituent may be further included.

The alkenyl group represented by R is a linear, branched, or cyclic alkenyl group and preferably a linear alkenyl group. The number of carbon atoms in the alkenyl group is preferably 1 to 10 and more preferably 1 to 6. The alkenyl group may be unsubstituted or may have a substituent. Examples of the substituent include the above-described substituents.

The alkynyl group represented by R is a linear, branched, or cyclic alkynyl group and preferably a linear alkynyl group. The number of carbon atoms in the alkynyl group is preferably 1 to 10 and more preferably 1 to 6. The alkynyl group may be unsubstituted or may have a substituent. Examples of the substituent include the above-described substituents.

The aryl group represented by R has a monocyclic or polycyclic structure and preferably has a monocyclic structure. The number of carbon atoms in the aryl group is preferably 6 to 18, more preferably 6 to 12, and further preferably 6. The aryl group may be unsubstituted or may have a substituent. Examples of the substituent include the above-described substituents.

The heteroaryl group represented by R has a monocyclic or polycyclic structure. The number of hetero atoms constituting the heteroaryl group is preferably 1 to 3. The hetero atom constituting the heteroaryl group is preferably a nitrogen atom, a sulfur atom, or an oxygen atom. The number of carbon atoms in the heteroaryl group is preferably 6 to 18 and more preferably 6 to 12. The heteroaryl group may be unsubstituted or may have a substituent. Examples of the substituent include the above-described substituents.

Another example of the coordination site that undergoes coordination in the form of anion is a monoanionic coordination site. The monoanionic coordination site is a site that coordinates with a copper atom through a functional group having a single negative charge. An acid group having an acid dissociation constant (pKa) of 12 or less is exemplified. Specific examples of the acid group include phosphorus-containing acid groups (e.g., a phosphoric acid diester group, a phosphonic acid monoester group, and a phosphinate group), a sulfo group, a carboxy group, and an imidate group. A sulfo group and a carboxy group are preferred.

The coordinating atom that undergoes coordination through an unshared electron pair is preferably an oxygen atom, a nitrogen atom, a sulfur atom, or a phosphorus atom, more preferably an oxygen atom, a nitrogen atom, or a sulfur atom, further preferably an oxygen atom or a nitrogen atom, and particularly preferably a nitrogen atom. When the coordinating atom that undergoes coordination through an unshared electron pair is a nitrogen atom, the atom adjacent to the nitrogen atom is preferably a carbon atom or a nitrogen atom and more preferably a carbon atom.

The coordinating atom that undergoes coordination through an unshared electron pair is preferably included in a ring or is preferably included in at least one partial structure selected from the group consisting of the following group of monovalent functional groups (UE-1), the following group of divalent functional groups (UE-2), and the following group of trivalent functional groups (UE-3). Herein, the wavy line in the structural formulae below refers to a bonding position with an atomic group constituting the ligand.

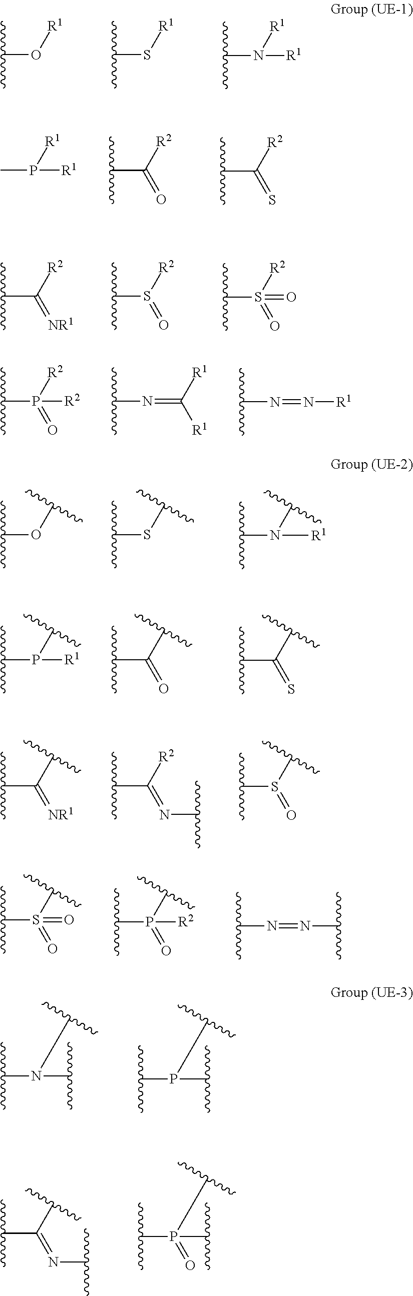

In the groups (UE-1) to (UE-3), R¹ represents a hydrogen atom, an alkyl group, an alkenyl group, an alkynyl group, an aryl group, or a heteroaryl group; and R² represents a hydrogen atom, an alkyl group, an alkenyl group, an alkynyl group, an aryl group, a heteroaryl group, an alkoxy group, an aryloxy group, a heteroaryloxy group, an alkylthio group, an arylthio group, a heteroarylthio group, an amino group, or an acyl group.

The coordinating atom that undergoes coordination through an unshared electron pair may be included in a ring. When the coordinating atom that undergoes coordination through an unshared electron pair is included in a ring, the ring including the coordinating atom that undergoes coordination through an unshared electron pair has a monocyclic or polycyclic structure and has an aromatic or non-aromatic structure. The ring including the coordinating atom that undergoes coordination through an unshared electron pair is preferably a five to twelve-membered ring and more preferably a five to seven-membered ring.

The ring including the coordinating atom that undergoes coordination through an unshared electron pair may have a substituent. Examples of the substituent include linear, branched, or cyclic alkyl groups having 1 to 10 carbon atoms, aryl groups having 6 to 12 carbon atoms, halogen atoms, a silicon atom, alkoxy groups having 1 to 12 carbon atoms, acyl groups having 2 to 12 carbon atoms, alkylthio groups having 1 to 12 carbon atoms, and a carboxy group.

When the ring including the coordinating atom that undergoes coordination through an unshared electron pair has a substituent, another substituent may be further included. Examples of the other substituent include groups constituted by a ring including the coordinating atom that undergoes coordination through an unshared electron pair, groups including at least one partial structure selected from the group consisting of the above-described groups (UE-1) to (UE-3), alkyl groups having 1 to 12 carbon atoms, acyl groups having 2 to 12 carbon atoms, and a hydroxy group.

When the coordinating atom that undergoes coordination through an unshared electron pair is included in the partial structure represented by any of the groups (UE-1) to (UE-3), R¹ represents a hydrogen atom, an alkyl group, an alkenyl group, an alkynyl group, an aryl group, or a heteroaryl group; and R² represents a hydrogen atom, an alkyl group, an alkenyl group, an alkynyl group, an aryl group, a heteroaryl group, an alkoxy group, an aryloxy group, a heteroaryloxy group, an alkylthio group, an arylthio group, a heteroarylthio group, an amino group, or an acyl group.

The alkyl group, the alkenyl group, the alkynyl group, the aryl group, and the heteroaryl group have the same meaning as the alkyl group, the alkenyl group, the alkynyl group, the aryl group, and the heteroaryl group described in the coordination site that undergoes coordination in the form of anion, and the preferred ranges thereof are also the same.

The number of carbon atoms in the alkoxy group is preferably 1 to 12 and more preferably 3 to 9.

The number of carbon atoms in the aryloxy group is preferably 6 to 18 and more preferably 6 to 12.

The heteroaryloxy group is a monocyclic or polycyclic group. The heteroaryl group constituting the heteroaryloxy group has the same meaning as the heteroaryl group described in the coordination site that undergoes coordination in the form of anion, and the preferred range is also the same.

The number of carbon atoms in the alkylthio group is preferably 1 to 12 and more preferably 1 to 9.

The number of carbon atoms in the arylthio group is preferably 6 to 18 and more preferably 6 to 12.

The heteroarylthio group is a monocyclic or polycyclic group. The heteroaryl group constituting the heteroarylthio group has the same meaning as the heteroaryl group described in the coordination site that undergoes coordination in the form of anion, and the preferred range thereof is also the same.

The number of carbon atoms in the acyl group is preferably 2 to 12 and more preferably 2 to 9.

When the ligand has, in a single molecule thereof, a coordination site that undergoes coordination in the form of anion and a coordinating atom that undergoes coordination through an unshared electron pair, the number of atoms that link the coordination site that undergoes coordination in the form of anion and the coordinating atom that undergoes coordination through an unshared electron pair is preferably 1 to 6 and more preferably 1 to 3. This configuration further distorts the structure of the copper complex, which can further improve the color value. Thus, the molar extinction coefficient is easily increased while the visible-light transmitting properties are improved. The coordination site that undergoes coordination in the form of anion and the coordinating atom that undergoes coordination through an unshared electron pair may be linked to each other through one atom or two or more atoms. A carbon atom or a nitrogen atom is preferred.

When the ligand has, in a single molecule thereof, two or more coordinating atoms that undergo coordination through an unshared electron pair, the ligand may have three or more coordinating atoms that undergo coordination through an unshared electron pair and preferably has 2 to 5 coordinating atoms and more preferably 4 coordinating atoms. The number of atoms that link the coordinating atoms that undergo coordination through an unshared electron pair is preferably 1 to 6, more preferably 1 to 3, further preferably 2 or 3, and particularly preferably 3. This configuration further distorts the structure of the copper complex, which can further improve the color value. The coordinating atoms that undergo coordination through an unshared electron pair may be linked to each other through one atom or two or more atoms. The atom that links the coordinating atoms that undergo coordination through an unshared electron pair is preferably a carbon atom.

The ligand is preferably a compound (also referred to as a polydentate ligand) having at least two coordination sites. The ligand more preferably has at least three coordination sites, further preferably 3 to 5 coordination sites, and particularly preferably 4 or 5 coordination sites. The polydentate ligand serves as a chelating ligand for the copper component. That is, it is believed that when at least two coordination sites of the polydentate ligand chelate with copper, the structure of the copper complex is distorted and good transmitting properties are achieved in a visible range, which can improve the infrared absorbance and also the color value.

The polydentate ligand is, for example, a compound including one or more coordination sites that undergo coordination in the form of anion and one or more coordinating atoms that undergo coordination through an unshared electron pair, a compound having two or more coordinating atoms that undergo coordination through an unshared electron pair, or a compound including two coordination sites that undergo coordination in the form of anion. These compounds may be each independently used alone or in combination of two or more. The compound serving as a ligand may be a compound having only one coordination site.

The polydentate ligand is preferably a compound represented by any of general formulae (IV-1) to (IV-14) below. For example, when the compound serves as a ligand having four coordination sites, compounds represented by formulae (IV-3), (IV-6), (IV-7), and (IV-12) are preferred, and a compound represented by formula (IV-12) is further preferred because the compound more strongly coordinates with a metal center and thus a stable five-coordinate complex having high heat resistance is easily formed. Furthermore, for example, when the compound serves as a ligand having five coordination sites, compounds represented by formulae (IV-4), (IV-8) to (IV-11), (IV-13), and (IV-14) are preferred, compounds represented by formulae (IV-9), (IV-10), (IV-13), and (IV-14) are further preferred because these compounds more strongly coordinate with a metal center and thus a stable five-coordinate complex having high heat resistance is easily formed, and a compound represented by formula (IV-13) is particularly preferred.

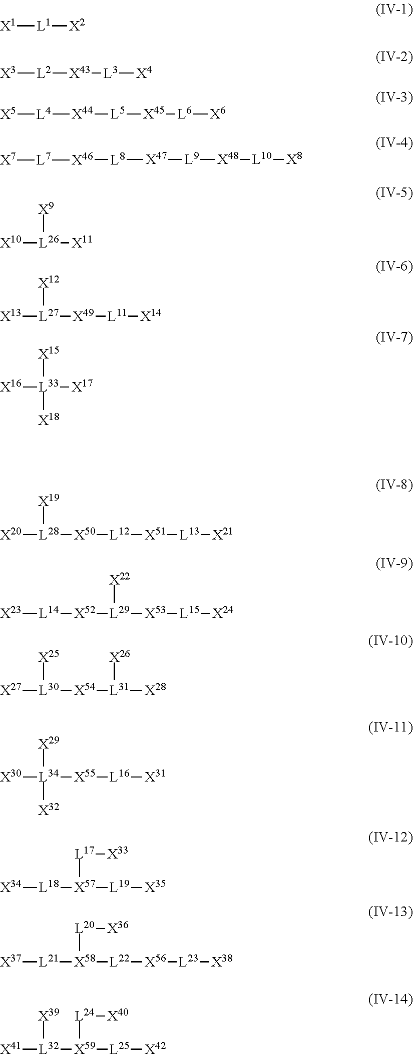

In the general formulae (IV-1) to (IV-14), X¹ to X⁵⁹ each independently represent a coordination site, L¹ to L²⁵ each independently represent a single bond or a divalent linking group, L²⁶ to L³² each independently represent a trivalent linking group, and L³³ and L³⁴ each independently represent a tetravalent linking group.

X¹ to X⁴² preferably each independently represent a group constituted by a ring including a coordinating atom that undergoes coordination through an unshared electron pair or at least one group selected from the group consisting of the group (AN-2) and the group (UE-2).

X⁴³ to X⁵⁶ preferably each independently represent a group constituted by a ring including a coordinating atom that undergoes coordination through an unshared electron pair or at least one group selected from the group consisting of the group (AN-2) and the group (UE-2).

X⁵⁷ to X⁵⁹ preferably each independently represent at least one group selected from the group consisting of the group (UE-3).

L¹ to L²⁵ each independently represent a single bond or a divalent linking group. The divalent linking group is preferably an alkylene group having 1 to 12 carbon atoms, an arylene group having 6 to 12 carbon atoms, —SO—, —O—, —SO₂—, or a group obtained by combining the foregoing groups and more preferably an alkylene group having 1 to 3 carbon atoms, a phenylene group, —SO₂—, or a group obtained by combining the foregoing groups.

L²⁶ to L³² each independently represent a trivalent linking group. An example of the trivalent linking group is a group obtained by removing one hydrogen atom from the above-described divalent linking group.

L³³ and L³⁴ each independently represent a tetravalent linking group. An example of the tetravalent linking group is a group obtained by removing two hydrogen atoms from the above-described divalent linking group.

For R in the groups (AN-1) and (AN-2) and R¹ in the groups (UE-1) to (UE-3), R may link to each other to form a ring, R¹ may link to each other to form a ring, or R and R¹ may link to each other to form a ring.

Specific examples of the compound serving as a ligand include the following compounds, compounds shown as preferred examples of the polydentate ligand below, and salts of these compounds. Examples of an atom or a molecule constituting the salt include metal atoms and tetrabutylammonium. The metal atoms are preferably alkali metal atoms or alkaline-earth metal atoms. Examples of the alkali metal atoms include sodium and potassium. Examples of the alkaline-earth metal atom include calcium and magnesium. Furthermore, the description in paragraphs 0022 to 0042 in JP2014-41318A and the description in paragraphs 0021 to 0039 in JP2015-43063A can be taken into consideration, the contents of which are incorporated herein.

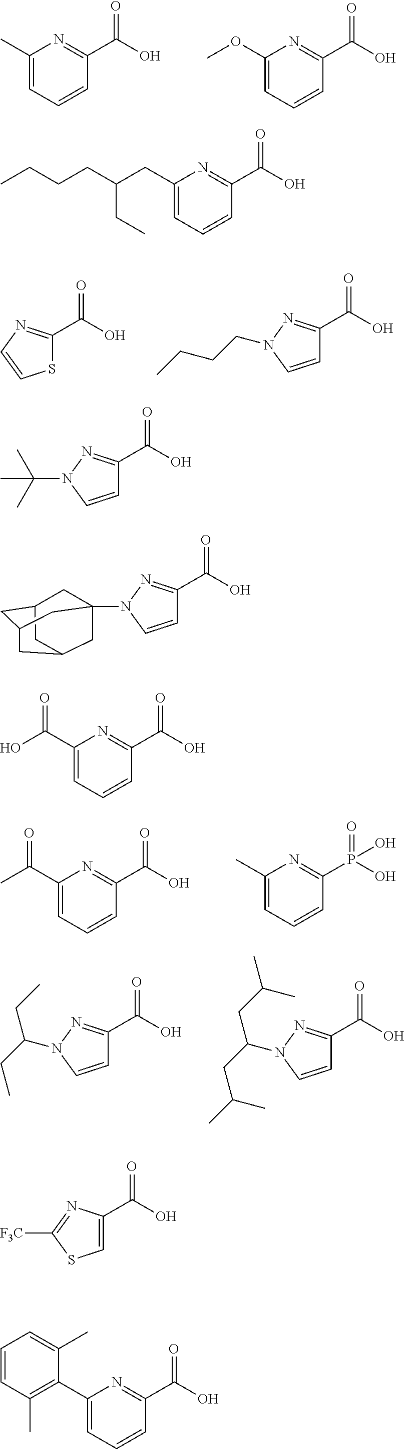

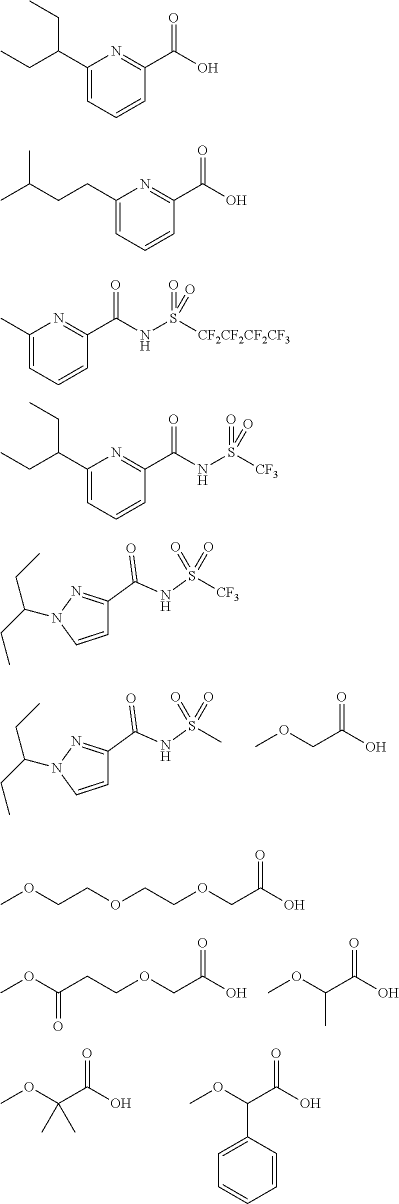

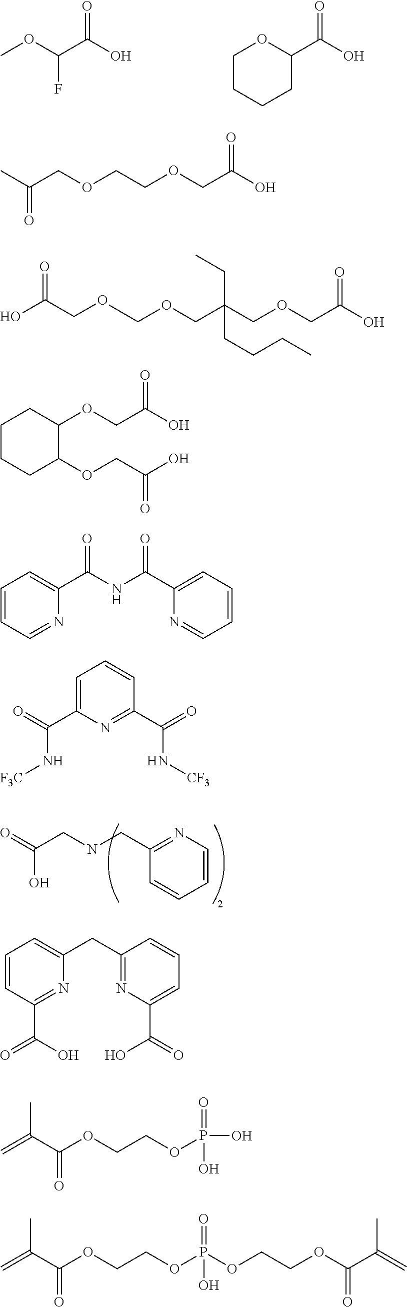

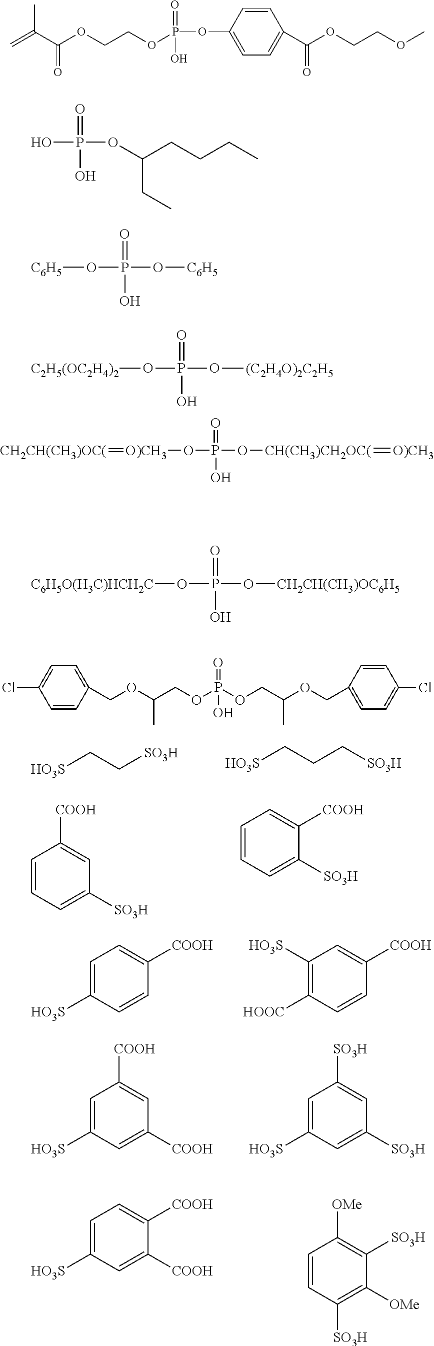

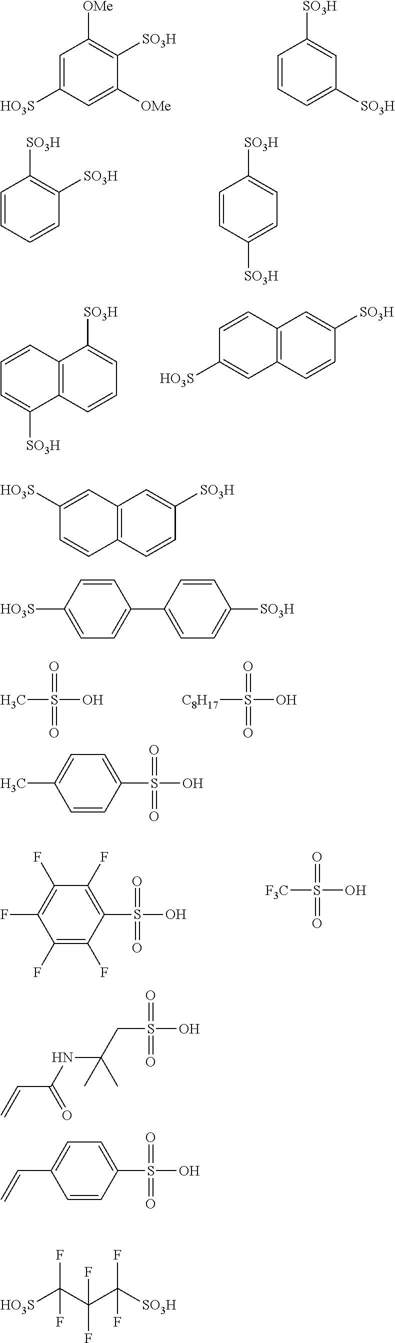

For example, the copper complex preferably has forms (1) to (5) below, more preferably has the forms (2) to (5), further preferably has the forms (3) to (5), and still further preferably has the form (4) or (5).

(1) a copper complex having, as ligands, one or two compounds having two coordination sites

(2) a copper complex having, as a ligand, a compound having three coordination sites

(3) a copper complex having, as ligands, a compound having three coordination sites and a compound having two coordination sites

(4) a copper complex having, as a ligand, a compound having four coordination sites (5) a copper complex having, as a ligand, a compound having five coordination sites

In the form (1), the compound having two coordination sites is preferably a compound having two coordinating atoms that undergo coordination through an unshared electron pair or a compound having a coordination site that undergoes coordination in the form of anion and a coordinating atom that undergoes coordination through an unshared electron pair. When two compounds having two coordination sites are included as ligands, the compounds serving as ligands may be the same or different.

In the form (1), the copper complex may further have a monodentate ligand. The number of monodentate ligands may be 0 or may be 1 to 3. The monodentate ligand is preferably a monodentate ligand that undergoes coordination in the form of anion or a monodentate ligand that undergoes coordination through an unshared electron pair. When the compound having two coordination sites is a compound having two coordinating atoms that undergo coordination through an unshared electron pair, the monodentate ligand that undergoes coordination in the form of anion is more preferably used in terms of high coordination strength. When the compound having two coordination sites is a compound having a coordination site that undergoes coordination in the form of anion and a coordinating atom that undergoes coordination through an unshared electron pair, the monodentate ligand that undergoes coordination through an unshared electron pair is more preferably used because the entire complex does not have a charge.

In the form (2), the compound having three coordination sites is preferably a compound having coordinating atoms that undergo coordination through an unshared electron pair and more preferably a compound having three coordinating atoms that undergo coordination through an unshared electron pair.

In the form (2), the copper complex may further have a monodentate ligand. The number of monodentate ligands may be 0 or may be 1 or more, and is more preferably 1 to 3, further preferably 1 or 2, and still further preferably 2. The monodentate ligand is preferably a monodentate ligand that undergoes coordination in the form of anion or a monodentate ligand that undergoes coordination through an unshared electron pair and more preferably a monodentate ligand that undergoes coordination in the form of anion for the above-described reason.

In the form (3), the compound having three coordination sites is preferably a compound having a coordination site that undergoes coordination in the form of anion and a coordinating atom that undergoes coordination through an unshared electron pair, and more preferably a compound having two coordination sites that undergo coordination in the form of anion and one coordinating atom that undergoes coordination through an unshared electron pair. Furthermore, the two coordination sites that undergo coordination in the form of anion are particularly preferably different from each other. The compound having two coordination sites is preferably a compound having a coordinating atom that undergoes coordination through an unshared electron pair and more preferably a compound having two coordinating atoms that undergo coordination through an unshared electron pair. In particular, the case where the compound having three coordination sites is a compound having two coordination sites that undergo coordination in the form of anion and one coordinating atom that undergoes coordination through an unshared electron pair and the case where the compound having two coordination sites is a compound having two coordinating atoms that undergo coordination through an unshared electron pair are particularly preferably combined with each other.

In the form (3), the copper complex may further have a monodentate ligand. The number of monodentate ligands may be 0 or may be 1 or more, and is preferably 0.

In the form (4), the compound having four coordination sites is preferably a compound having coordinating atoms that undergo coordination through an unshared electron pair, more preferably a compound having two or more coordinating atoms that undergo coordination through an unshared electron pair, and further preferably a compound having four coordinating atoms that undergo coordination through an unshared electron pair.

In the form (4), the copper complex may further have a monodentate ligand. The number of monodentate ligands may be 0, 1 or more, or 2 or more, and is preferably 1. The monodentate ligand is preferably a monodentate ligand that undergoes coordination in the form of anion or a monodentate ligand that undergoes coordination through an unshared electron pair.

In the form (5), the compound having five coordination sites is preferably a compound having coordinating atoms that undergo coordination through an unshared electron pair, more preferably a compound having two or more coordinating atoms that undergo coordination through an unshared electron pair, and further preferably a compound having five coordinating atoms that undergo coordination through an unshared electron pair.

In the form (5), the copper complex may further have a monodentate ligand. The number of monodentate ligands may be 0 or may be 1 or more, and is preferably 0.

Preferred examples of the polydentate ligand include the following compounds.

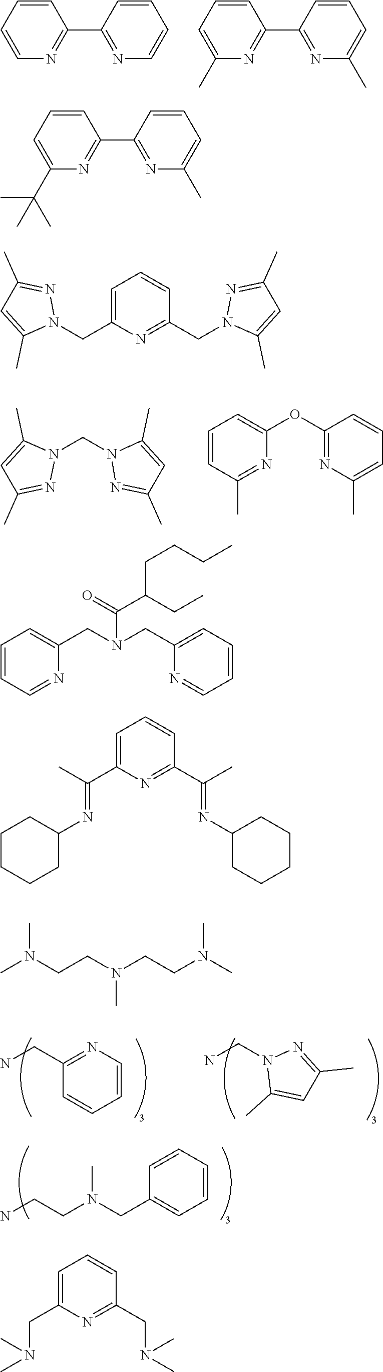

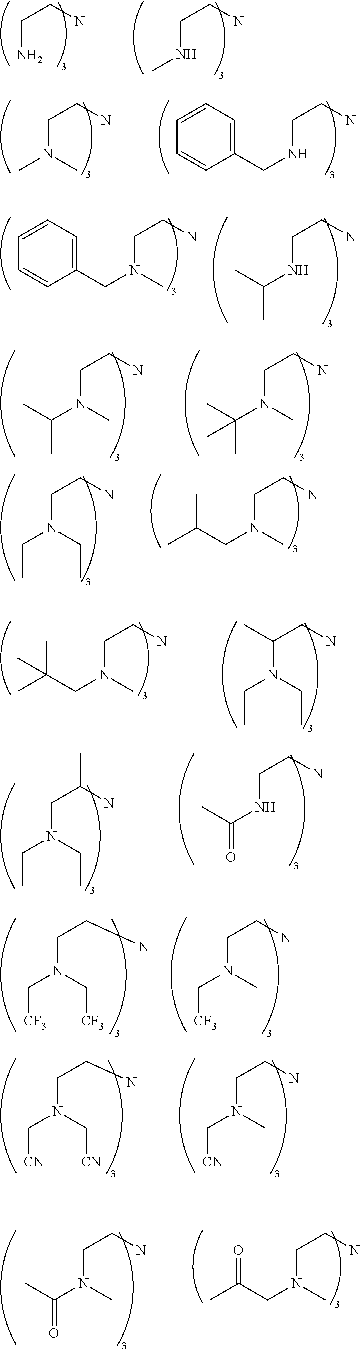

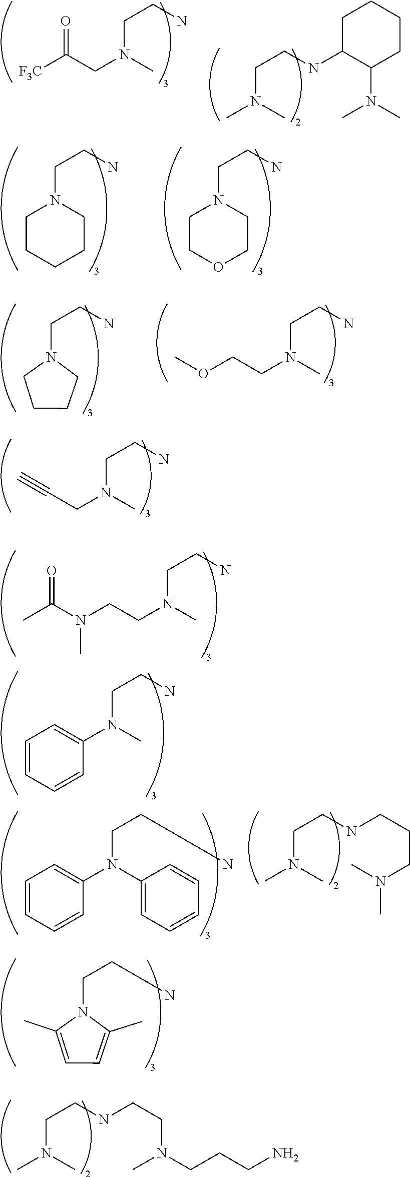

### Phosphate Copper Complex

In the present invention, the copper compound may be a phosphate copper complex. The phosphate copper complex includes copper as a central metal and a phosphate compound as a ligand. The phosphate compound serving as a ligand of the phosphate copper complex is preferably a compound represented by formula (L-100) below or a salt thereof.

(HO)ₙ—P(═O)—(OR¹)₃₋ₙ Formula (L-100)

In the formula, R¹ represents an alkyl group having 1 to 18 carbon atoms, an aryl group having 6 to 18 carbon atoms, an aralkyl group having 1 to 18 carbon atoms, or an alkenyl group having 1 to 18 carbon atoms, or —OR¹ represents a polyoxyalkyl group having 4 to 100 carbon atoms, a (meth)acryloyloxyalkyl group having 4 to 100 carbon atoms, or a (meth)acryloylpolyoxyalkyl group having 4 to 100 carbon atoms; n represents 1 or 2; and when n represents 1, R² may be the same or different.

In the formula, at least one of —OR¹ preferably represents a (meth)acryloyloxyalkyl group having 4 to 100 carbon atoms or a (meth)acryloylpolyoxyalkyl group having 4 to 100 carbon atoms, and more preferably represents a (meth)acryloyloxyalkyl group having 4 to 100 carbon atoms. The number of carbon atoms in each of the polyoxyalkyl group, the (meth)acryloyloxyalkyl group, and the (meth)acryloylpolyoxyalkyl group is preferably 4 to 20 and more preferably 4 to 10.

The molecular weight of the phosphate compound is preferably 300 to 1500 and more preferably 320 to 900.

Specific examples of the phosphate compound include the above-described ligands. The description in paragraphs 0022 to 0042 in JP2014-41318A can be taken into consideration, the contents of which are incorporated herein.

### Sulfonic Acid Copper Complex

In the present invention, the copper compound may be a sulfonic acid copper complex. The sulfonic acid copper complex includes copper as a central metal and a sulfonic acid compound as a ligand. The sulfonic acid compound serving as a ligand of the sulfonic acid copper complex is preferably a compound represented by formula (L-200) below or a salt thereof.

R²—SO₂—OH Formula (L-200)

In the formula, R² represents a monovalent organic group. Examples of the monovalent organic group include alkyl groups, aryl groups, and heteroaryl groups.

The alkyl group is a linear, branched, or cyclic alkyl group and is preferably a linear alkyl group. The number of carbon atoms in the alkyl group is preferably 1 to 30, more preferably 1 to 20, and further preferably 1 to 10.

The aryl group is a monocyclic or polycyclic group and is preferably a monocyclic group. The number of carbon atoms in the aryl group is preferably 6 to 25 and more preferably 6 to 10.

The heteroaryl group is a monocyclic or polycyclic group. The number of hetero atoms in the heteroaryl group is preferably 1 to 3. The hetero atom in the heteroaryl group is preferably a nitrogen atom, a sulfur atom, or an oxygen atom. The number of carbon atoms in the heteroaryl group is preferably 6 to 18 and more preferably 6 to 12.

The alkyl group, the aryl group, and the heteroaryl group may be unsubstituted or may have a substituent. Examples of the substituent include polymerizable groups (preferably groups having an ethylenically unsaturated bond, such as a vinyl group, a (meth)acryloyloxy group, and a (meth)acryloyl group), halogen atoms (fluorine atom, chlorine atom, bromine atom, and iodine atom), alkyl groups, carboxylate groups (e.g., —CO₂CH₃), halogenated alkyl groups, alkoxy groups, methacryloyloxy groups, acryloyloxy groups, ether groups, alkylsulfonyl groups, arylsulfonyl groups, a sulfide group, an amide group, acyl groups, a hydroxy group, a carboxy group, a sulfonate group, phosphorus-containing acid groups, an amino group, a carbamoyl group, and a carbamoyloxy group.

The halogenated alkyl group is preferably an alkyl group substituted with a fluorine atom. In particular, an alkyl group that has two or more fluorine atoms and 1 to 10 carbon atoms is preferred. The halogenated alkyl group is a linear, branched, or cyclic alkyl group and is preferably a linear or branched alkyl group. The number of carbon atoms in the halogenated alkyl group is more preferably 1 to 10, further preferably 1 to 5, and still further preferably 1 to 3. The alkyl group substituted with fluorine atoms preferably has a terminal structure of (—CF₃). In the alkyl group substituted with fluorine atoms, the substitution percentage with fluorine atoms is preferably 50% to 100% and more preferably 80% to 100%. Herein, the substitution percentage with fluorine atoms refers to a percentage (%) at which hydrogen atoms are replaced with fluorine atoms in the alkyl group substituted with fluorine atoms. In particular, the halogenated alkyl group is preferably a perfluoroalkyl group, more preferably a perfluoroalkyl group having 1 to 10 carbon atoms, and further preferably a trifluoroethyl group or a trifluoromethyl group.

The alkyl group, the aryl group, and the heteroaryl group may have a divalent linking group. The divalent linking group is preferably —(CH₂)ₘ— (m represents an integer of 1 to 10, preferably an integer of 1 to 6, and more preferably an integer of 1 to 4), a cyclic alkylene group having 5 to 10 carbon atoms, or a group obtained by combining the above groups with at least one of —O—, —COO—, —S—, —NH—, or —CO—.

In the formula (L-200), R² preferably represents an organic group having a formula weight of 300 or less, more preferably represents an organic group having a formula weight of 50 to 200, and further preferably represents an organic group having a formula weight of 60 to 100.

The molecular weight of the sulfonic acid compound represented by the formula (L-200) is preferably 80 to 750, more preferably 80 to 600, and further preferably 80 to 450.

The sulfonic acid copper complex preferably has a structure represented by formula (L-201) below.

R^{2A}—SO₂—O—* (L-201)

In the formula, R^{2A} has the same meaning as R² in the formula (L-200), and the preferred range thereof is also the same.

Specific examples of the sulfonic acid compound include the above-described ligands. The description in paragraphs 0021 to 0039 in JP2015-43063A can also be taken into consideration, the contents of which are incorporated herein.

### Polymer-Type Copper Compound

In the present invention, the copper compound may be a copper-containing polymer having a copper complex portion on a polymer side chain. Since the copper-containing polymer has a copper complex portion on a polymer side chain, a crosslinked structure is believed to be formed between the polymer side chains so as to extend from copper and thus a film having high heat resistance is believed to be obtained. The polymer-type copper compound (copper-containing polymer) is a component different from a resin described below.

The copper complex portion is constituted by copper and a site (coordination site) that coordinates with copper. The site that coordinates with copper is, for example, a site that undergoes coordination in the form of anion or through an unshared electron pair. The copper complex portion preferably has a tetradentate or pentadentate site that coordinates with copper. The details of the coordination site are the same as those described in the low-molecular-weight copper compound, and the preferred range is also the same.

The copper-containing polymer is, for example, a polymer obtained by reacting a polymer including a coordination site (also referred to as a polymer (B1)), a polymer obtained through reaction with a copper component or a polymer having a reactive site on a polymer side chain (hereafter also referred to as a polymer (B2)), and a copper complex having a functional group that is reactive with the reactive site of the polymer (B2). The weight-average molecular weight of the copper-containing polymer is preferably 2,000 or more, more preferably 2,000 to 2,000,000, and further preferably 6,000 to 200,000.

### Squarylium Compound

The squarylium compound is preferably a compound having a maximum absorption wavelength in the range of 650 to 850 nm and more preferably a compound having a maximum absorption wavelength in the range of 700 to 800 nm. The squarylium compound is preferably a compound represented by general formula 1 below.

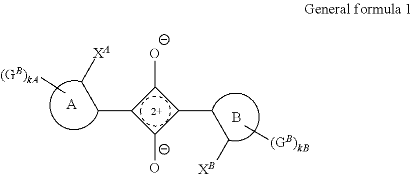

In the general formula 1, the ring A and the ring B each independently represent an aromatic ring;

X^{A} and X^{B} each independently represent a substituent;

G^{A} and G^{B} each independently represent a substituent;

kA represents an integer of 0 to nA and kB represents an integer of 0 to nB;

nA represents a maximum integer that is the number of substituents which can be introduced into the ring A and nB represents a maximum integer that is the number of substituents which can be introduced into the ring B; and

X^{A} and G^{A} may bond to each other to form a ring and X^{B} and G^{B} may bond to each other to form a ring. If a plurality of G^{A} are present, they may bond to each other to form a ring. If a plurality of G^{B} are present, they may bond to each other to form a ring.

In the general formula 1, G^{A} and G^{B} each independently represent a substituent.

Examples of the substituent include halogen atoms, a cyano group, a nitro group, alkyl groups, alkenyl groups, alkynyl groups, aralkyl groups, aryl groups, heteroaryl groups, —OR^{c1}, —COR^{c2}, —COOR^{c3}, —OCOR^{c4}, —NR^{c5}R^{c6}, —NHCOR^{c7}, —CONR^{c8}R^{c9}, —NHCONR^{c10}R^{c11}, NHCOOR^{c12}, —SR^{c13}, —SO₂R^{c14}, —SO₂OR^{c15}, —NHSO₂R^{c16}, and —SO₂NR^{c17}R¹⁸. R^{c1} to R^{c18} each independently represent a hydrogen atom, an alkyl group, an alkenyl group, an alkynyl group, an aryl group, or a heteroaryl group. When R³ in —COOR^{c3} represents a hydrogen atom (i.e., a carboxy group), the hydrogen atom may be dissociated (i.e., a carbonate group) or the group may be present in the form of a salt. When R^{c15} in —SO₂OR^{c15} is a hydrogen atom (i.e., a sulfo group), the hydrogen atom may be dissociated (i.e., a sulfonate group) or the group may be present in the form of a salt.

Examples of the halogen atoms include a fluorine atom, a chlorine atom, a bromine atom, and an iodine atom.

The number of carbon atoms in the alkyl group is preferably 1 to 20, more preferably 1 to 12, and particularly preferably 1 to 8. The alkyl group is a linear, branched, or cyclic alkyl group. The alkyl group may be unsubstituted or may have a substituent.

The number of carbon atoms in the alkenyl group is preferably 2 to 20, more preferably 2 to 12, and particularly preferably 2 to 8. The alkenyl group is a linear, branched, or cyclic alkenyl group.

The number of carbon atoms in the alkynyl group is preferably 2 to 20, more preferably 2 to 12, and particularly preferably 2 to 8. The alkynyl group is a linear, branched, or cyclic alkynyl group.

The number of carbon atoms in the aryl group is preferably 6 to 25, more preferably 6 to 15, and most preferably 6 to 10.

The alkyl portion in the aralkyl group is the same as the above alkyl group. The aryl portion in the aralkyl group is the same as the above aryl group. The number of carbon atoms in the aralkyl group is preferably 7 to 40, more preferably 7 to 30, and further preferably 7 to 25.

The heteroaryl group is preferably a monocyclic group or a group having fused rings, more preferably a monocyclic group or a group having 2 to 8 fused rings, and further preferably a monocyclic group or a group having 2 to 4 fused rings. The number of hetero atoms constituting the ring of the heteroaryl group is preferably 1 to 3. The hetero atom constituting the ring of the heteroaryl group is preferably a nitrogen atom, an oxygen atom, or a sulfur atom. The heteroaryl group is preferably a five-membered ring or a six-membered ring. The number of carbon atom constituting the ring of the heteroaryl group is preferably 3 to 30, more preferably 3 to 18, and further preferably 3 to 12.

The alkyl group, the alkenyl group, the alkynyl group, the aralkyl group, the aryl group, and the heteroaryl group may have a substituent or may be unsubstituted. Examples of the substituent include the substituents described in G^{A} and G^{B}, such as halogen atoms, a hydroxy group, a carboxy group, a sulfo group, an alkoxy group, and an amino group.

In the general formula 1, X^{A} and X^{B} each independently represent a substituent. The substituent is preferably a group having active hydrogen. The substituent is preferably —OH, —SH, —COOH, —SO₃H, —NHR^{x1}, —NR^{x1}R^{x2}, —NHCOR^{x1}, —CONR^{x1}R^{x2}, —NHCONR^{x1}R^{x2}, —NHCOOR^{x1}, —NHSO₂R^{x1}, —B(OH)₂, —PO(OH)₃, or —NHBR^{x1}R^{x2}; more preferably —OH, —NHCOR^{x1}, —NHCONR^{x1}R^{x2}, —NHCOOR^{x1}, —NHSO₂R^{x1}, or —NHBR^{x1}R^{x2}; further preferably —NHCOR^{x1}, —NHCONR^{x1}R^{x2}, —NHCOOR^{x1}, or —NHSO₂R^{x1}; and particularly preferably —NHCOR^{x1} or —NHSO₂R^{x1}.

R^{x1} and R^{x2} each independently represent a substituent. The substituent is, for example, an alkyl group or an aryl group and is preferably an alkyl group. The number of carbon atoms in the alkyl group is preferably 1 to 20, more preferably 1 to 15, further preferably 1 to 8, and particularly preferably 1 to 5. The alkyl group is a linear, branched, or cyclic alkyl group and is preferably a linear or branched alkyl group. The number of carbon atoms in the aryl group is preferably 6 to 30, more preferably 6 to 20, and further preferably 6 to 12. The alkyl group and the aryl group may have a substituent or may be unsubstituted, but preferably have a substituent. Examples of the substituent include substituents described in R_{Z} below, such as halogen atoms, aryl groups, and alkoxy groups. The substituent is preferably a halogen atom and more preferably a fluorine atom from the viewpoint of heat resistance and light resistance.

R^{x1} and R^{x2} preferably represent a group having a fluorine atom, more preferably represent an alkyl group having a fluorine atom or an aryl group having a fluorine atom, further preferably represent an alkyl group having a fluorine atom, and particularly preferably represent a perfluoroalkyl group having 1 to 5 carbon atoms.

In the general formula 1, the ring A and the ring B each independently represent an aromatic ring. The aromatic ring may be a monocyclic or a fused ring. The aromatic ring may be an aromatic hydrocarbon ring or an aromatic heterocyclic ring. Specific examples of the aromatic ring include a benzene ring, a naphthalene ring, a pentalene ring, an indene, an azulene ring, a heptalene ring, an indacene ring, a perylene ring, a pentacene ring, an acenaphthalene ring, a phenanthrene ring, an anthracene ring, a naphthacene ring, a chrysene ring, a triphenylene ring, a fluorene ring, a biphenyl ring, a pyrrole ring, a furan ring, a thiophene ring, an imidazole ring, an oxazole ring, a thiazole ring, a pyridine ring, a pyrazine ring, a pyrimidine ring, a pyridazine ring, an indolizine ring, an indole ring, a benzofuran ring, a benzothiophene ring, an isobenzofuran ring, a quinolizine ring, a quinoline ring, a phthalazine ring, a naphthyridine ring, a quinoxaline ring, a quinoxazoline ring, an isoquinoline ring, a carbazole ring, a phenanthridine ring, an acridine ring, a phenanthroline ring, a thianthrene ring, a chromene ring, a xanthene ring, a phenoxathiin ring, a phenothiazine ring, and a phenazine ring. The aromatic ring is preferably a benzene ring or a naphthalene ring and more preferably a naphthalene ring.

The aromatic ring may be unsubstituted or may have a substituent. Examples of the substituent include the substituents described in G^{A} and G^{B}.

In the general formula 1, X^{A} and G^{A} may bond to each other to form a ring and X^{B} and G^{B} may bond to each other to form a ring. If a plurality of G^{A} are present, they may bond to each other to form a ring. If a plurality of G^{B} are present, they may bond to each other to form a ring. The ring is preferably a five-membered ring or a six-membered ring. The ring may be a monocyclic ring or a heterocyclic ring. When X^{A} and G^{A}, X^{B} and G^{B}, a plurality of G^{A}, or a plurality of G^{B} bond to each other to form a ring, they may directly bond to each other to form a ring or they may bond to each other through a divalent linking group selected from the group consisting of alkylene groups, —CO—, —O—, —NH—, —BR—, and a combination of the foregoing to form a ring. X^{A} and G^{A}, X^{B} and G^{B}, a plurality of G^{A}, or a plurality of G^{B} preferably bond to each other through —BR— to form a ring. R represents a hydrogen atom or a substituent. The substituent is, for example, an alkyl group, an alkenyl group, an alkynyl group, an aryl group, or a heteroaryl group. The details of the alkyl group, the alkenyl group, the alkynyl group, the aryl group, and the heteroaryl group are the same as those described in G^{A} and G^{B}.

In the general formula 1, kA represents an integer of 0 to nA, kB represents an integer of 0 to nB, nA represents a maximum integer that is the number of substituents which can be introduced into the ring A, and nB represents a maximum integer that is the number of substituents which can be introduced into the ring B.

kA and kB preferably each independently represent 0 to 4, more preferably 0 to 2, and particularly preferably 0 or 1.

The compound represented by the general formula 1 is preferably a compound represented by general formula 1-1 below. This compound has high heat resistance.

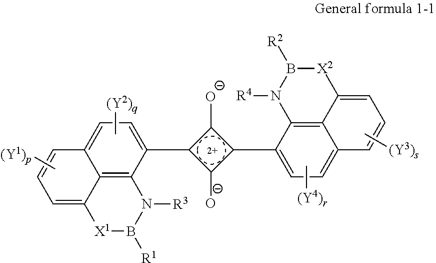

In the formula, R¹ and R² each independently represent an alkyl group, an alkenyl group, an aryl group, a heteroaryl group, or a group represented by formula (W) below;

R³ and R⁴ each independently represent a hydrogen atom or an alkyl group;

X¹ and X² each independently represent an oxygen atom or —N(R⁵)—;

R⁵ represents a hydrogen atom, an alkyl group, an aryl group, or a heteroaryl group;

Y¹ to Y⁴ each independently represent a substituent, Y¹ and Y² may bond to each other to form a ring, and Y³ and Y⁴ may bond to each other to form a ring;

if a plurality of Y¹, a plurality of Y², a plurality of Y³, and a plurality of Y⁴ are present, they may bond to each other to form a ring;

p and s each independently represent an integer of 0 to 3; and

q and r each independently represent an integer of 0 to 2.

—S¹-L¹-T¹ (W)

In the formula (W), S¹ represents a single bond, an arylene group, or a heteroarylene group;

L¹ represents an alkylene group, an alkenylene group, an alkynylene group, —O—, —S—, —NR^{L1}—, —CO—, —COO—, —OCO—, —CONR^{L1}—, —NR^{L1}CO—, —SO₂—, —OR^{L2}—, Or a group obtained by combining the foregoing groups, R^{L1} represents a hydrogen atom or an alkyl group, and R^{L2} represents an alkylene group; and

T¹ represents an alkyl group, a cyano group, a hydroxy group, a formyl group, a carboxy group, an amino group, a thiol group, a sulfo group, a phosphoryl group, a boryl group, a vinyl group, an ethynyl group, an aryl group, a heteroaryl group, a trialkylsilyl group, or a trialkoxysilyl group.

In the general formula 1-1, R¹ and R² each independently represent an alkyl group, an alkenyl group, an aryl group, a heteroaryl group, or a group represented by the formula (W). At least one of R¹ or R² preferably represents a group represented by the formula (W). In the general formula 1-1, R¹ and R² may be the same group or different groups. R¹ and R² are preferably the same group. In this specification, the aryl group refers to an aromatic hydrocarbon group and the heteroaryl group refers to an aromatic heterocyclic group.

The number of carbon atoms in the alkyl group represented by R¹ and R² is preferably 1 to 40. The lower limit of the number of carbon atoms is preferably 3 or more, more preferably 5 or more, further preferably 10 or more, and particularly preferably 13 or more. The upper limit of the number of carbon atoms is preferably 35 or less and more preferably 30 or less. The alkyl group is a linear, branched, or cyclic alkyl group, and is preferably a linear or branched alkyl group and particularly preferably a branched alkyl group. The number of branches in the branched alkyl group is, for example, preferably 2 to 10 and more preferably 2 to 8. When the number of branches is within the above range, the solubility in a solvent is good.

The number of carbon atoms in the alkenyl group represented by R¹ and R² is preferably 2 to 40. The lower limit of the number of carbon atoms is, for example, more preferably 3 or more, further preferably 5 or more, still further preferably 8 or more, and particularly preferably 10 or more. The upper limit of the number of carbon atoms is more preferably 35 or less and further preferably 30 or less. The alkenyl group is preferably a linear or branched alkenyl group and particularly preferably a branched alkenyl group. The number of branches in the branched alkenyl group is preferably 2 to 10 and more preferably 2 to 8. When the number of branches is within the above range, the solubility in a solvent is good.

The number of carbon atoms in the aryl group represented by R¹ and R² is preferably 6 to 30, more preferably 6 to 20, and further preferably 6 to 12.

The heteroaryl group represented by R¹ and R² may be a monocyclic group or a polycyclic group. The number of hetero atoms constituting the ring in the heteroaryl group is preferably 1 to 3. The hetero atom constituting the ring in the heteroaryl group is preferably a nitrogen atom, an oxygen atom, or a sulfur atom. The number of carbon atoms constituting the ring in the heteroaryl group is preferably 3 to 30, more preferably 3 to 18, and further preferably 3 to 12.

### Group Represented by Formula (W)

Subsequently, the group represented by the formula (W) will be described.

In the formula (W), S¹ represents a single bond, an arylene group, or a heteroarylene group. From the viewpoint of stability of a bond with a boron atom, S¹ preferably represents an arylene group or a heteroarylene group and more preferably represents an arylene group.

The arylene group may be a monocyclic group or a polycyclic group and is preferably monocyclic group. The number of carbon atoms in the arylene group is preferably 6 to 20 and more preferably 6 to 12.

The heteroaryl group may be a monocyclic group or a polycyclic group and is preferably a monocyclic group. The number of hetero atoms constituting the ring in the heteroaryl group is preferably 1 to 3. The hetero atom constituting the ring of the heteroaryl group is preferably a nitrogen atom, an oxygen atom, a sulfur atom, or a selenium atom. The number of carbon atoms constituting the ring of the heteroaryl group is preferably 3 to 30, more preferably 3 to 18, and further preferably 3 to 12.

The arylene group and heteroarylene group represented by S¹ specifically have the following structures.

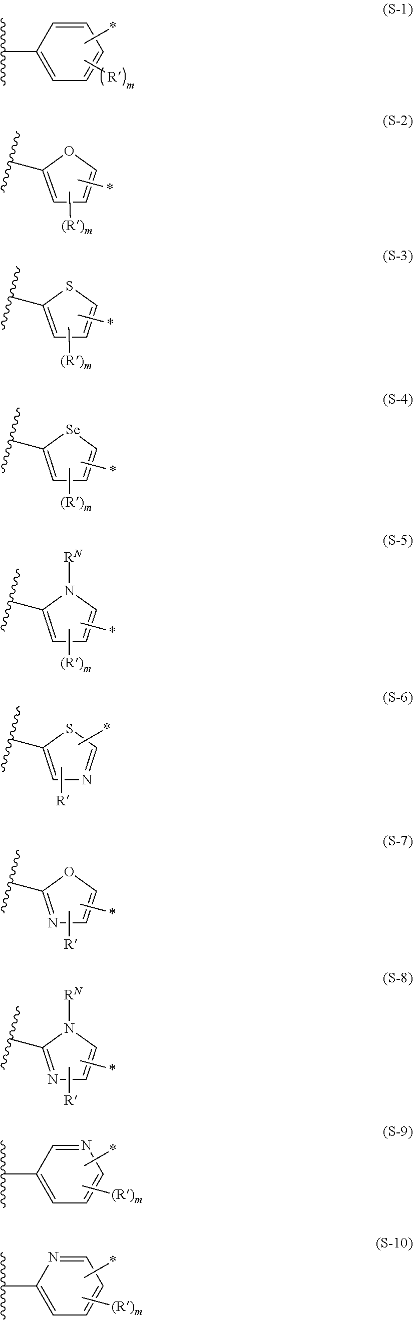

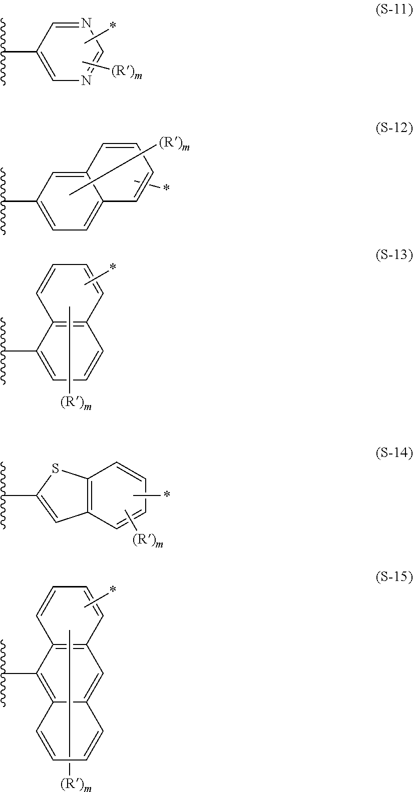

In the formulae, the wavy line represents a bonding position with a boron atom in the general formula 1-1, * represents a bonding position with L¹, R′ represents a substituent, R^{N} represents a hydrogen atom or an alkyl group, and m represents an integer of 0 or more.

Examples of the substituent represented by R′ include the substituents described in G^{A} and G^{B} in the general formula 1.

The number of carbon atoms in the alkyl group represented by R^{N} is preferably 1 to 20, more preferably 1 to 10, further preferably 1 to 4, and particularly preferably 1 or 2. The alkyl group is a linear or branched alkyl group.

Herein, m represents an integer of 0 or more, the upper limit of m is the maximum number of substituents that can be introduced, and m preferably represents 0.

In the formula (W), L¹ represents an alkenylene group, and alkenylene group, an alkynylene group, —O—, —S—, —NR^{L1}—, —CO—, —COO—, —OCO—, —CONR^{L1}—, —N^{L}CO—, —SO₂—, —OR^{L2}—, or a group obtained by combining the foregoing groups, R^{L1} represents a hydrogen atom or an alkyl group, and R^{L2} represents an alkylene group.

In the formula (W), L¹ preferably represents an alkylene group, an alkenylene group, an alkynylene group, —O—, —S—, —NR^{L1}—, —COO—, —OCO—, —CONR^{L1}—, —SO₂—, —OR^{L2}—, or a group obtained by combining the foregoing groups. From the viewpoint of flexibility and solubility in a solvent, L¹ more preferably represents an alkylene group, an alkenylene group, —O—, —OR^{L2}—, or a group obtained by combining the foregoing groups, further preferably represents an alkylene group, an alkenylene group, —O—, or —OR^{L2}—, and particularly preferably represents an alkylene group, —O—, or —OR^{L2}—.

The number of carbon atoms in the alkylene group represented by L¹ is preferably 1 to 40. The lower limit of the number of carbon atoms is more preferably 3 or more, further preferably 5 or more, still further preferably 10 or more, and particularly preferably 13 or more. The upper limit of the number of carbon atoms is more preferably 35 or less and further preferably 30 or less. The alkylene group is a linear, branched, or cyclic alkylene group, preferably a linear or branched alkylene group, and particularly preferably a branched alkylene group. The number of branches is, for example, preferably 2 to 10 and more preferably 2 to 8. When the number of branches is within the above range, the solubility in a solvent is good.

The number of carbon atoms in the alkenylene group and alkynylene group represented by L¹ is preferably 2 to 40. The lower limit of the number of carbon atoms is, for example, more preferably 3 or more, further preferably 5 or more, still further preferably 8 or more, and particularly preferably 10 or more. The upper limit of the number of carbon atoms is more preferably 35 or less and further preferably 30 or less. The alkenylene group and the alkynylene group are linear or branched, and preferably branched groups. The number of branches is preferably 2 to 10 and more preferably 2 to 8. When the number of branches is within the above range, the solubility in a solvent is good.

R^{L1} represents a hydrogen atom or an alkyl group and preferably represents a hydrogen atom. The number of carbon atoms in the alkyl group is preferably 1 to 20, more preferably 1 to 10, further preferably 1 to 4, and particularly preferably 1 or 2. The alkyl group is a linear or branched alkyl group.

R^{L2} represents an alkylene group. The alkylene group represented by R^{L2} has the same meaning as the alkylene group described in L¹, and the preferred range is also the same.

In the formula (W), T¹ represents an alkyl group, a cyano group, a hydroxy group, a formyl group, a carboxy group, an amino group, a thiol group, a sulfo group, a phosphoryl group, a boryl group, a vinyl group, an ethynyl group, an aryl group, a heteroaryl group, a trialkylsilyl group, or a trialkoxysilyl group.

The number of carbon atoms in the alkyl group, the alkyl group in the trialkylsilyl group, and the alkyl group in the trialkoxysilyl group is preferably 1 to 40. The lower limit of the number of carbon atoms is more preferably 3 or more, further preferably 5 or more, still further preferably 10 or more, and particularly preferably 13 or more. The upper limit of the number of carbon atoms is more preferably 35 or less and further preferably 30 or less. The alkyl group is a linear, branched, or cyclic alkyl group and is preferably a linear or branched alkyl group.

The aryl group and the heteroaryl group have the same meaning as those described in R¹ and R², and the preferred ranges thereof are also the same.

In the formula (W), when S¹ represents a single bond, L¹ represents an alkylene group, and T¹ represents an alkyl group, the total number of carbon atoms in L¹ and T¹ is preferably 13 or more and more preferably 21 or more from the viewpoint of solubility in a solvent. The upper limit of the total number of carbon atoms is, for example, 40 or less and more preferably 35 or less.

When S¹ represents an arylene group, the total number of carbon atoms in L¹ and T¹ is preferably 5 or more. From the viewpoint of solubility in a solvent, the total number of carbon atoms is preferably 9 or more and more preferably 10 or more. The upper limit of the total number of carbon atoms is, for example, preferably 40 or less and more preferably 35 or less.

The preferred form of the formula (W) is a combination of S¹ that represents an arylene group or a heteroarylene group, L¹ that represents an alkylene group, an alkenylene group, an alkynylene group, —O—, —S—, —NR^{L1}—, —COO—, —OCO—, —CONR^{L1}—, —SO₂—, —OR^{L2}—, or a group obtained by combining the foregoing groups, and T¹ that represents an alkyl group or a trialkylsilyl group. S¹ more preferably represents an arylene group. L¹ more preferably represents an alkylene group, an alkenylene group, —O—, —OR^{L2}—, or a group obtained by combining the foregoing groups, further preferably represents an alkylene group, an alkenylene group, —O—, or —OR^{L2}—, and particularly preferably represents an alkylene group, —O—, or —OR^{L2}—. T¹ more preferably represents an alkyl group.

In the formula (W), the -L¹-T¹ portion preferably includes a branched alkyl structure. Specifically, the -L¹-T¹ portion is particularly preferably a branched alkyl group or a branched alkoxy group. The number of branches in the -L¹-T¹ portion is preferably 2 to 10 and more preferably 2 to 8. The number of carbon atoms in the -L¹-T¹ portion is preferably 5 or more, more preferably 9 or more, and further preferably 10 or more. The upper limit of the number of carbon atoms is, for example, preferably 40 or less and more preferably 35 or less.

In the formula (W), the -L¹-T¹ portion preferably includes an asymmetric carbon atom. In this case, the compound represented by the general formula 1-1 can include a plurality of optical isomers, which can further improve the solubility of the compound in a solvent. The number of asymmetric carbon atoms is preferably one or more. The upper limit of the number of asymmetric carbon atoms is not particularly limited, but is, for example, preferably 4 or less.

In the general formula 1-1, R³ and R⁴ each independently represent a hydrogen atom or an alkyl group. R³ and R⁴ may be the same group or different groups. R³ and R⁴ are preferably the same group.

The number of carbon atoms in the alkyl group represented by R³ and R⁴ is preferably 1 to 20, more preferably 1 to 10, further preferably 1 to 4, and particularly preferably 1 or 2. The alkyl group is a linear or branched alkyl group. Specific examples of the alkyl group include a methyl group, an ethyl group, a propyl group, an isopropyl group, a butyl group, and an isobutyl group.

R³ and R⁴ preferably each independently represent a hydrogen atom, a methyl group, or an ethyl group, more preferably a hydrogen atom or a methyl group, and particularly preferably a hydrogen atom.

In the general formula 1-1, X¹ and X² each independently represent an oxygen atom (—O—) or —N(R⁵)—. X¹ and X² may be the same or different, but are preferably the same.

R⁵ represents a hydrogen atom, an alkyl group, an aryl group, or a heteroaryl group.

R⁵ preferably represents a hydrogen atom, an alkyl group, or an aryl group. The alkyl group, the aryl group, and the heteroaryl group represented by R⁵ may be unsubstituted or may have a substituent. Examples of the substituent include the substituents described in G^{A} and G^{B} in the general formula 1.

The number of carbon atoms in the alkyl group is preferably 1 to 20, more preferably 1 to 10, further preferably 1 to 4, and particularly preferably 1 or 2. The alkyl group is a linear or branched alkyl group.

The number of carbon atoms in the aryl group is preferably 6 to 20 and more preferably 6 to 12.

The heteroaryl group may be a monocyclic group or a polycyclic group. The number of hetero atoms constituting the ring of the heteroaryl group is preferably 1 to 3. The hetero atom constituting the ring of the heteroaryl group is preferably a nitrogen atom, an oxygen atom, or a sulfur atom. The number of carbon atoms constituting the ring of the heteroaryl group is preferably 3 to 30, more preferably 3 to 18, and further preferably 3 to 12.

X¹ and X² preferably each independently represent an oxygen atom or any of the following structures.

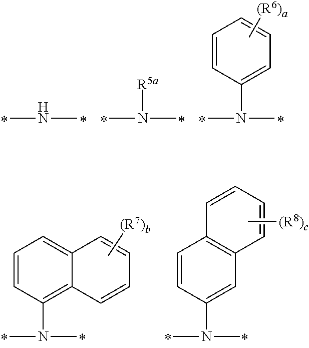

In the formulae, R^{5a} represents an alkyl group, R⁶ to R⁸ each independently represent a substituent, a represents an integer of 0 to 5, b and c each represent an integer of 0 to 7, and * represents a bonding arm.

Examples of the substituent represented by R⁶ to R⁸ include the substituents described in G^{A} and G^{B} in the general formula 1.

In the general formula 1-1, Y¹ to Y⁴ each independently represent a substituent.

Examples of the substituent include the substituents described in G^{A} and G^{B} in the general formula 1.

In the general formula 1-1, Y¹ and Y² may bond to each other to form a ring and Y³ and Y⁴ may bond to each other to form a ring. For example, Y¹ and Y² may bond to each other to form, for example, a three-ring structure such as an acenaphthene ring or an acenaphthylene ring together with a naphthalene ring to which Y¹ and Y² directly link.

When a plurality of Y¹, a plurality of Y², a plurality of Y³, or a plurality of Y⁴ are present, they may bond to each other to form a ring structure. For example, when a plurality of Y¹ are present, Y¹ may bond to each other to form a three-ring structure such as an anthracene ring or a phenanthrene ring together with a naphthalene ring to which Y¹ and Y² directly link. In the case where Y¹ bond to each other to form a ring structure, Y² to Y⁴ serving as substituents other than Y¹ are not necessarily present in plural. Alternatively, Y² to Y⁴ are not necessarily present. The same applies to the cases where Y² bond to each other to form a ring structure, Y³ bond to each other to form a ring structure, and Y⁴ bond to each other to form a ring structure.

In the formula, p and s each independently represent an integer of 0 to 3, preferably each independently represent 0 or 1, and particularly preferably each independently represent 0.

In the formula, q and r each independently represent an integer of 0 to 2, preferably each independently represent 0 or 1, and particularly preferably each independently represent 0.

In the general formula (1), the cation is delocalized as shown below.

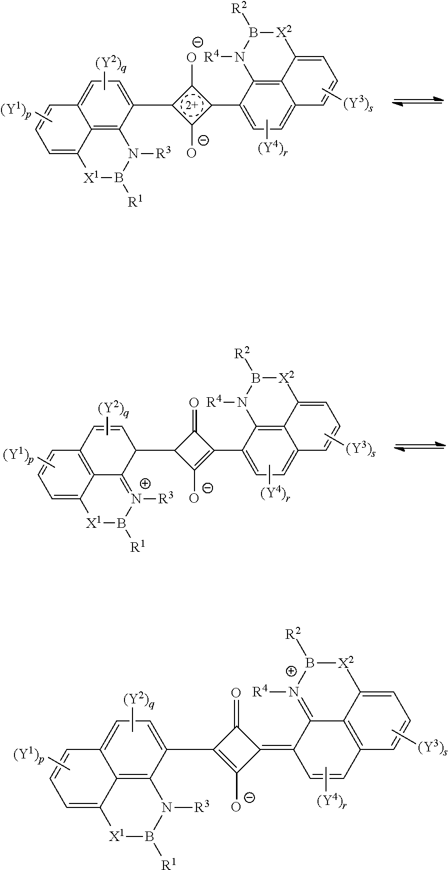

The squarylium compound represented by the general formula 1 is, for example, a compound below. Furthermore, a compound described in paragraphs 0044 to 0049 in JP2011-208101A is exemplified, the contents of which are incorporated herein.

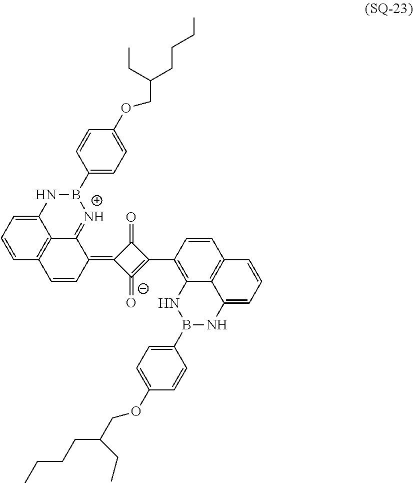

### Pyrrolopyrrole Compound

The pyrrolopyrrole compound is preferably a compound having a maximum absorption wavelength in the range of 650 to 850 nm and more preferably a compound having a maximum absorption wavelength in the range of 700 to 800 nm.

The pyrrolopyrrole compound is preferably a compound represented by general formula 2 below.

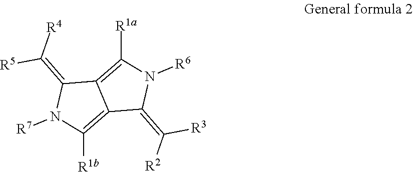

In the general formula 2, R^{1a} and R^{1b} each independently represent an alkyl group, an aryl group, or a heteroaryl group;

R² to R⁵ each independently represent a hydrogen atom or a substituent, where R² and R³ may bond to each other to form a ring and R⁴ and R⁵ may bond to each other to form a ring;

R⁶ and R⁷ each independently represent a hydrogen atom, an alkyl group, an aryl group, a heteroaryl group, —BR^{A}R^{B}, or a metal atom, where R^{A} and R^{B} each independently represent a hydrogen atom or a substituent; and

R⁶ may bond to R^{1a} or R³ through a covalent bond or a coordinate bond, and R⁷ may bond to R^{1b} or R⁵ through a covalent bond or a coordinate bond.

In the general formula 2, R^{1a} and R^{1b} each independently represent an alkyl group, an aryl group, or a heteroaryl group, preferably each independently represent an aryl group or a heteroaryl group, and more preferably each independently represent an aryl group.

The number of carbon atoms in the alkyl group represented by R^{1a} and R^{1b} is preferably 1 to 40, more preferably 1 to 30, and particularly preferably 1 to 25. The alkyl group is a linear, branched, or cyclic alkyl group, preferably a linear or branched alkyl group, and particularly preferably a branched alkyl group.

The number of carbon atoms in the aryl group represented by R^{1a} and R^{1b} is preferably 6 to 30, more preferably 6 to 20, and further preferably 6 to 12. The aryl group is preferably phenyl.

The heteroaryl group represented by R^{1a} and R^{1b} is preferably a monocyclic group or a group having fused rings, more preferably a monocyclic group or a group having 2 to 8 fused rings, and further preferably a monocyclic group or a group having 2 to 4 fused rings. The number of hetero atoms constituting the ring of the heteroaryl group is preferably 1 to 3. The hetero atom constituting the ring of the heteroaryl group is preferably a nitrogen atom, an oxygen atom, or a sulfur atom. The number of carbon atoms constituting the heteroaryl group is preferably 3 to 30, more preferably 3 to 18, further preferably 3 to 12, and particularly preferably 3 to 10. The heteroaryl group is preferably a five-membered ring or a six-membered ring.

The aryl group and the heteroaryl group may have a substituent or may be unsubstituted. From the viewpoint of improving the solubility in a solvent, they preferably have a substituent.

Examples of the substituent include hydrocarbon groups that may include an oxygen atom, an amino group, an acylamino group, a sulfonylamino group, a sulfamoyl group, a carbamoyl group, alkylthio groups, arylthio groups, alkylsulfonyl groups, arylsulfonyl groups, alkylsulfinyl groups, arylsulfinyl groups, a ureido group, a phosphoramide group, a mercapto group, a sulfo group, a carboxy group, a nitro group, a hydroxamic acid group, a sulfino group, a hydrazino group, an imino group, a silyl group, a hydroxy group, a halogen atom, and a cyano group.

Examples of the halogen atom include a fluorine atom, a chlorine atom, a bromine atom, and an iodine atom.

Examples of the hydrocarbon groups include alkyl groups, alkenyl groups, and aryl groups.

The number of carbon atoms in the alkyl group is preferably 1 to 40. The lower limit of the number of carbon atoms is more preferably 3 or more, further preferably 5 or more, still further preferably 8 or more, and particularly preferably 10 or more. The upper limit of the number of carbon atoms is more preferably 35 or less and further preferably 30 or less. The alkyl group is a linear, branched, or cyclic alkyl group, preferably a linear or branched alkyl group, and particularly preferably a branched alkyl group. The number of carbon atoms in the branched alkyl group is preferably 3 to 40. The lower limit of the number of carbon atoms is, for example, more preferably 5 or more, further preferably 8 or more, and still further preferably 10 or more. The upper limit of the number of carbon atoms is more preferably 35 or less and further preferably 30 or less. The number of branches in the branched alkyl group is, for example, preferably 2 to 10 and more preferably 2 to 8. When the number of branches is within the above range, the solubility in a solvent is good.

The number of carbon atoms in the alkenyl group is preferably 2 to 40. The lower limit of the number of carbon atoms is, for example, more preferably 3 or more, further preferably 5 or more, still further preferably 8 or more, and particularly preferably 10 or more. The upper limit of the number of carbon atoms is more preferably 35 or less and further preferably 30 or less. The alkenyl group is a linear, branched, or cyclic alkenyl group, preferably a linear or branched alkenyl group, and particularly preferably a branched alkenyl group. The number of carbon atoms in the branched alkenyl group is preferably 3 to 40. The lower limit of the number of carbon atoms is, for example, more preferably 5 or more, further preferably 8 or more, and still further preferably 10 or more. The upper limit of the number of carbon atoms is more preferably 35 or less and further preferably 30 or less. The number of branches in the branched alkenyl group is preferably 2 to 10 and more preferably 2 to 8. When the number of branches is within the above range, the solubility in a solvent is good.

The number of carbon atoms in the aryl group is preferably 6 to 30, more preferably 6 to 20, and further preferably 6 to 12.

The hydrocarbon group including an oxygen atom is, for example, a group represented by -L-R^{x1}.

L represents —O—, —CO—, —COO—, —OCO—, —(OR^{x2})ₘ—, or —(R^{x2}O)ₘ—; R^{x1} represents an alkyl group, an alkenyl group, or an aryl group; R^{x2} represents an alkylene group or an arylene group; and m represents an integer of 2 or more, where mR^{x2} may be the same or different.

L preferably represents —O—, —(OR²)ₘ—, or —(R^{x2}O)ₘ— and more preferably represents —O—.

The alkyl group, the alkenyl group, and the aryl group represented by R^{x1} have the same meaning as above, and the preferred ranges thereof are also the same. R^{x1} preferably represents an alkyl group or an alkenyl group and more preferably represents an alkyl group.

The number of carbon atoms in the alkylene group represented by R^{x2} is preferably 1 to 20, more preferably 1 to 10, and further preferably 1 to 5. The alkylene group is a linear, branched, or cyclic alkylene group and preferably a linear or branched alkylene group. The number of carbon atoms in the arylene group represented by R^{x2} is preferably 6 to 20 and more preferably 6 to 12. R^{x2} preferably represents an alkylene group.

Herein, m represents an integer of 2 or more, preferably represents 2 to 20, and more preferably represents 2 to 10.

The substituent is preferably a group having a branched alkyl structure. In this case, the solubility in a solvent is further improved. The substituent is preferably a hydrocarbon group that may include an oxygen atom and more preferably a hydrocarbon group that includes an oxygen atom. The hydrocarbon group including an oxygen atom is preferably a group represented by —O—R^{x1}. R^{x1} preferably represents an alkyl group or an alkenyl group, more preferably represents an alkyl group, and particularly preferably represents a branched alkyl group. That is, the substituent is more preferably an alkoxy group and particularly preferably a branched alkoxy group. When the substituent is an alkoxy group, an infrared absorber having high heat resistance and high light resistance can be provided. When the substituent is a branched alkoxy group, the solubility in a solvent is good.

The number of carbon atoms in the alkoxy group is preferably 1 to 40. The lower limit of the number of carbon atoms is, for example, more preferably 3 or more, further preferably 5 or more, still further preferably 8 or more, and particularly preferably 10 or more. The upper limit of the number of carbon atoms is more preferably 35 or less and further preferably 30 or less. The alkoxy group is a linear, branched, or cyclic alkoxy group, preferably a linear or branched alkoxy group, and particularly preferably a branched alkoxy group. The number of carbon atoms in the branched alkoxy group is preferably 3 to 40. The lower limit of the number of carbon atoms is, for example, more preferably 5 or more, further preferably 8 or more, and still further preferably 10 or more. The upper limit of the number of carbon atoms is more preferably 35 or less and further preferably 30 or less. The number of branches in the branched alkoxy group is preferably 2 to 10 and more preferably 2 to 8.

R² to R⁵ each independently represent a hydrogen atom or a substituent. Examples of the substituent include alkyl groups, alkenyl groups, alkynyl groups, aryl groups, heteroaryl groups, an amino group (including an alkylamino group, an arylamino group, and a heterocyclic amino group), alkoxy groups, aryloxy groups, heteroaryloxy groups, acyl groups, alkylcarbonyl groups, arylcarbonyl groups, alkoxycarbonyl groups, aryloxycarbonyl groups, acyloxy groups, acylamino groups, alkoxycarbonylamino groups, aryloxycarbonylamino groups, a sulfonylamino group, a sulfamoyl group, a carbamoyl group, alkylthio groups, arylthio groups, heteroarylthio groups, alkylsulfonyl groups, arylsulfonyl groups, alkylsulfinyl groups, arylsulfinyl groups, a ureido group, a phosphoramide group, a hydroxy group, a mercapto group, halogen atoms, a cyano group, a sulfo group, a carboxy group, a nitro group, a hydroxamic acid group, a sulfino group, a hydrazino group, an imino group, and a silyl group.

At least one of R² or R³ and at least one of R⁴ or R⁵ preferably represent an electron withdrawing group.

A substituent having a positive Hammett σp value (sigma para value) functions as an electron withdrawing group.

In the present invention, a substituent having a Hammett σp value of 0.2 or more can be exemplified as an electron withdrawing group. The σp value is preferably 0.25 or more, more preferably 0.3 or more, and particularly preferably 0.35 or more. The upper limit of the σp value is not particularly limited, but is preferably 0.80.

Specific examples of the electron withdrawing group include a cyano group (0.66), a carboxy group (—COOH: 0.45), an alkoxycarbonyl group (—COOMe: 0.45), an aryloxycarbonyl group (—COOPh: 0.44), a carbamoyl group (—CONH₂: 0.36), an alkylcarbonyl group (—COMe: 0.50), an arylcarbonyl group (—COPh: 0.43), an alkylsulfonyl group (—SO₂Me: 0.72), and an arylsulfonyl group (—SO₂Ph: 0.68). A cyano group is particularly preferred. Herein, Me represents a methyl group and Ph represents a phenyl group.

For the Hammett op value, for example, the description in paragraphs 0024 and 0025 in JP2009-263614A can be taken into consideration, the contents of which are incorporated herein.

At least one of R² or R³ and at least one of R⁴ or R⁵ preferably represent a heteroaryl group.

The heteroaryl group is preferably a monocyclic group or a group having fused rings, more preferably a monocyclic group or a group having 2 to 8 fused rings, and further preferably a monocyclic group or a group having 2 to 4 fused rings. The number of hetero atoms constituting the heteroaryl group is preferably 1 to 3. The hetero atom constituting the heteroaryl group is preferably a nitrogen atom, an oxygen atom, or a sulfur atom. The heteroaryl group preferably has one or more nitrogen atoms. The number of carbon atoms constituting the heteroaryl group is preferably 3 to 30, more preferably 3 to 18, further preferably 3 to 12, and particularly preferably 3 to 10. The heteroaryl group is preferably a five-membered ring or a six-membered ring. Specific examples of the heteroaryl group include an imidazolyl group, a pyridyl group, a pyrazyl group, a pyrimidyl group, a pyridazyl group, a triazyl group, a quinolyl group, a quinoxalyl group, an isoquinolyl group, an indolenyl group, a furyl group, a thienyl group, a benzoxazolyl group, a benzimidazolyl group, a benzothiazolyl group, a naphthothiazolyl group, a benzoxazolyl group, a m-carbazolyl group, an azepinyl group, and a benzannulated group or a naphthoannulated group of the foregoing groups.

The heteroaryl group may have a substituent or may be unsubstituted. Examples of the substituent include the above-described substituents represented by R² to R⁵. A halogen atom, an alkyl group, an alkoxy group, or an aryl group is preferred. The halogen atom is preferably a fluorine atom, a chlorine atom, a bromine atom, or an iodine atom and particularly preferably a chlorine atom. The number of carbon atoms in the alkyl group and the alkoxy group is preferably 1 to 40, more preferably 1 to 30, and particularly preferably 1 to 25. The alkyl group and the alkoxy group are preferably linear or branched groups and particularly preferably linear groups. The number of carbon atoms in the aryl group is preferably 6 to 30, more preferably 6 to 20, and further preferably 6 to 12.

In the general formula 2, R² and R³ may bond to each other to form a ring, and R⁴ and R⁵ may bond to each other to form a ring. When R² and R³ or R⁴ and R⁵ bond to each other to form a ring, a five-, six-, or seven-membered ring (preferably five- or six-membered ring) is preferably formed. The ring to be formed is preferably a ring used as an acidic nucleus in a merocyanine dye. Specifically, the structure is described in paragraph 0026 in JP2010-222557A, the contents of which are incorporated herein.

The ring formed by bonding R² and R³ or bonding R⁴ and R⁵ is preferably a 1,3-dicarbonyl nucleus, a pyrazolinone nucleus, a 2,4,6-triketohexahydropyrimidine nucleus (including thioketone body), a 2-thio-2,4-thiazolidinedione nucleus, a 2-thio-2,4-oxazolidinedione nucleus, a 2-thio-2,5-thiazolidinedione nucleus, a 2,4-thiazolidinedione nucleus, a 2,4-imidazolidinedione nucleus, a 2-thio-2,4-imidazolidinedione nucleus, a 2-imidazolin-5-one nucleus, a 3,5-pyrazolidinedione nucleus, a benzothiophen-3-one nucleus, or an indanone nucleus; and more preferably a 1,3-dicarbonyl nucleus, a 2,4,6-triketohexahydropyrimidine nucleus (including thioketone body), a 3,5-pyrazolidinedione nucleus, a benzothiophen-3-one nucleus, or an indanone nucleus.

R⁶ and R⁷ each independently represent a hydrogen atom, an alkyl group, an aryl group, a heteroaryl group, —BR^{A}R^{B}, or a metal atom and preferably each independently represent —BR^{A}R^{B}.

The number of carbon atoms in the alkyl group is preferably 1 to 40, more preferably 1 to 30, and particularly preferably 1 to 25. The alkyl group is a linear, branched, or cyclic alkyl group, preferably a linear or branched alkyl group, and particularly preferably a linear alkyl group. The alkyl group may be unsubstituted or may have a substituent. Examples of the substituent include the above-described substituents represented by R² to R⁵.

The number of carbon atoms in the aryl group is preferably 6 to 30, more preferably 6 to 20, and further preferably 6 to 12. The aryl group may be unsubstituted or may have a substituent. Examples of the substituent include the above-described substituents represented by R² to R⁵.

The heteroaryl group is preferably a monocyclic group or a group having fused rings and more preferably a monocyclic group. The number of hetero atoms constituting the ring of the heteroaryl group is preferably 1 to 3. The hetero atom constituting the ring of the heteroaryl group is preferably a nitrogen atom, an oxygen atom, or a sulfur atom. The number of carbon atoms constituting the heteroaryl group is preferably 3 to 30, more preferably 3 to 18, further preferably 3 to 12, and particularly preferably 3 to 5. The heteroaryl group is preferably a five-membered ring or a six-membered ring. The heteroaryl group may be unsubstituted or may have a substituent. Examples of the substituent include the above-described substituents represented by R² to R⁵.

The metal atom is preferably magnesium, aluminum, calcium, barium, zinc, tin, vanadium, iron, cobalt, nickel, copper, palladium, iridium, or platinum, and particularly preferably aluminum, zinc, vanadium, iron, copper, palladium, iridium, or platinum.

In the group represented by —BR^{A}R^{B}, R^{A} and R^{B} each independently represent a substituent. Examples of the substituent represented by R^{A} and R^{B} include the above-described substituents represented by R² to R⁵. The substituent is preferably a halogen atom, an alkyl group, an alkoxy group, an aryl group, or a heteroaryl group. The halogen atom is preferably a fluorine atom, a chlorine atom, a bromine atom, or an iodine atom and particularly preferably a fluorine atom. The number of carbon atoms in the alkyl group and the alkoxy group is preferably 1 to 40, more preferably 1 to 30, and particularly preferably 1 to 25. The alkyl group and the alkoxy group are preferably linear or branched groups and particularly preferably linear groups. The alkyl group and the alkoxy group may have a substituent or may be unsubstituted. Examples of the substituent include aryl groups, heteroaryl groups, and halogen atoms. The number of carbon atoms in the aryl group is preferably 6 to 20 and more preferably 6 to 12. The aryl group may have a substituent or may be unsubstituted. Examples of the substituent include alkyl groups, alkoxy groups, and halogen atoms. The heteroaryl group is a monocyclic group or a polycyclic group. The number of hetero atoms constituting the heteroaryl group is preferably 1 to 3. The hetero atom constituting the heteroaryl group is preferably a nitrogen atom, an oxygen atom, or a sulfur atom. The number of carbon atoms constituting the heteroaryl group is preferably 3 to 30, more preferably 3 to 18, further preferably 3 to 12, and particularly preferably 3 to 5. The heteroaryl group is preferably a five-membered ring or a six-membered ring. The heteroaryl group may have a substituent or may be unsubstituted. Examples of the substituent include alkyl groups, alkoxy groups, and halogen atoms.

In the general formula 2, R⁶ may bond to R^{1a} or R³ through a covalent bond or a coordinate bond. R⁷ may bond to R^{1b} or R⁵ through a covalent bond or a coordinate bond.

The following compound is exemplified as the pyrrolopyrrole compound represented by the general formula 2. Furthermore, compounds D-1 to D-162 described in paragraphs 0049 to 0062 in JP2010-222557A are also exemplified, the contents of which are incorporated herein. In the following formula, Ph represents a phenyl group.

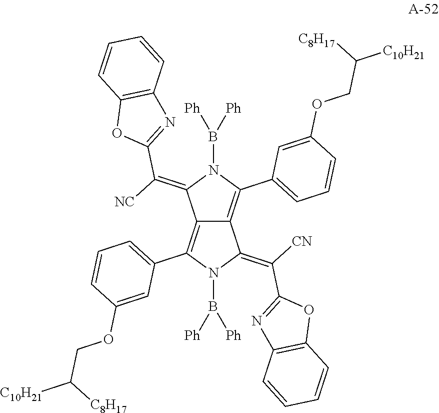

### Cyanine Compound

The cyanine compound is preferably a compound having a maximum absorption wavelength in the range of 650 to 850 nm and more preferably a compound having a maximum absorption wavelength in the range of 700 to 800 nm. The cyanine compound is preferably a compound represented by general formula 3 below.

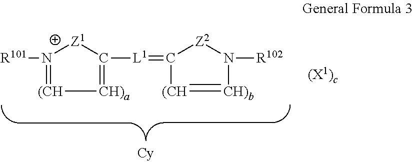

In the general formula 3, Z¹ and Z² each independently represent a nonmetal atom group for forming a five- or six-membered nitrogen-containing heterocycle that may undergo annulation;

R¹⁰¹ and R¹⁰² each independently represent an alkyl group, an alkenyl group, an alkynyl group, an aralkyl group, or an aryl group;

L¹ represents a methine chain having an odd number of methine groups;

a and b each independently represent 0 or 1; and

if a represents 0, the carbon atom and the nitrogen atom bond to each other through a double bond, and if b represents 0, the carbon atom and the nitrogen atom bond to each other through a single bond.

When a portion represented by Cy in the formula is a cationic portion, X¹ represents an anion and c represents the number of X¹ required to balance the charge. When a portion represented by Cy in the formula is an anionic portion, X¹ represents a cation and c represents the number of X¹ required to balance the charge. When the charge in a portion represented by Cy in the formula is intramolecularly neutralized, c represents 0.

In the general formula 3, Z¹ and Z² each independently represent a nonmetal atom group for forming a five- or six-membered nitrogen-containing heterocycle that may undergo annulation. The nitrogen-containing heterocycle may condense with other heterocycles, aromatic rings, or aliphatic rings. The nitrogen-containing heterocycle is preferably a five-membered ring. The five-membered nitrogen-containing heterocycle more preferably condenses with a benzene ring or a naphthalene ring. Specific examples of the nitrogen-containing heterocycle include an oxazole ring, an isoxazole ring, a benzoxazole ring, a naphthoxazole ring, an oxazolocarbazole ring, an oxazolodibenzofuran ring, a thiazole ring, a benzothiazole ring, a naphthothiazole ring, an indolenine ring, a benzindolenine ring, an imidazole ring, a benzimidazole ring, a naphthimidazole ring, a quinoline ring, a pyridine ring, a pyrrolopyridine ring, a furopyrrole ring, an indolizine ring, an imidazoquinoxaline ring, and a quinoxaline. A quinoline ring, an indolenine ring, a benzindolenine ring, a benzoxazole ring, a benzothiazole ring, and a benzimidazole ring are preferred. An indolenine ring, a benzothiazole ring, and a benzimidazole ring are particularly preferred. The nitrogen-containing heterocycle and a ring that condenses with the nitrogen-containing heterocycle may have a substituent. Examples of the substituent include the substituents described in G^{A} and G^{B} in the general formula 1.

In the general formula 3, R¹⁰¹ and R¹⁰² each independently represent an alkyl group, an alkenyl group, an alkynyl group, an aralkyl group, or an aryl group.

The number of carbon atoms in the alkyl group is preferably 1 to 20, more preferably 1 to 12, and particularly preferably 1 to 8. The alkyl group is a linear, branched, or cyclic alkyl group.

The number of carbon atoms in the alkenyl group is preferably 2 to 20, more preferably 2 to 12, and particularly preferably 2 to 8. The alkenyl group is a linear, branched, or cyclic alkenyl group.

The number of carbon atoms in the alkynyl group is preferably 2 to 20, more preferably 2 to 12, and particularly preferably 2 to 8. The alkynyl group is a linear, branched, or cyclic alkynyl group.

The number of carbon atoms in the aryl group is preferably 6 to 25, more preferably 6 to 15, and most preferably 6 to 10. The aryl group may be unsubstituted or may have a substituent.

The alkyl portion in the aralkyl group is the same as the above alkyl group. The aryl portion in the aralkyl group is the same as the above aryl group. The number of carbon atoms in the aralkyl group is preferably 7 to 40, more preferably 7 to 30, and further preferably 7 to 25.

The alkyl group, the alkenyl group, the alkynyl group, the aralkyl group, and the aryl group may have a substituent or may be unsubstituted. The substituent is, for example, a halogen atom, a hydroxy group, a carboxy group, a sulfo group, an alkoxy group, or an amino group; preferably a carboxy group or a sulfo group; and particularly preferably a sulfo group. For the carboxy group and the sulfo group, the hydrogen atom may be dissociated or the group may be present in the form of a salt.

In the formula 3, L¹ represents a methine chain having an odd number of methine groups. L¹ preferably represents a methine chain having 3, 5, or 7 methine groups.

The methine group may have a substituent. The methine group having a substituent is preferably a central (meso position) methine group. Specific examples of the substituent include the substituents that may be included in the nitrogen-containing heterocycle in Z¹ and Z² and a group represented by formula (a) below. Two substituents of the methine chain may bond to each other to form a five- or six-membered ring.

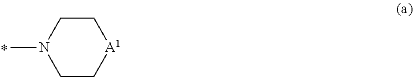

In the formula (a), * represents a linking portion with the methine chain, and A¹ represents an oxygen atom or a sulfur atom.

In the general formula 3, a and b each independently represent 0 or 1. When a represents 0, the carbon atom and the nitrogen atom bond to each other through a double bond. When b represents 0, the carbon atom and the nitrogen atom bond to each other through a single bond. Both a and b preferably represent 0. Note that when both a and b represent 0, the general formula 3 is expressed as follows.

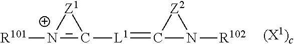

In the general formula 3, when the portion represented by Cy in the formula is a cationic portion, X¹ represents an anion and c represents the number of X¹ required to balance the charge. Examples of the anion include halide ions (Cl⁻, Br⁻, I⁻), a p-toluenesulfonate ion, an ethylsulfate ion, PF₆₋, BF₄⁻ or ClO₄⁻, tris(halogenoalkylsulfonyl)methide anions (e.g., (CF₃SO₂)₃C⁻), di(halogenoalkylsulfonyl)imide anions (e.g., (CF₃SO₂)₂N⁻), and a tetracyanoborate anion.

In the general formula 3, when the portion represented by Cy in the formula is an anionic portion, X¹ represents a cation and c represents the number of X¹ required to balance the charge. Examples of the cation include alkali metal ions (e.g., Li⁺, Na⁺, K⁺), alkaline-earth metal ions (e.g., Mg²⁺, Ca²⁺, Ba²⁺, Sr²⁺), transition metal ions (e.g., Ag⁺, Fe²⁺, Co²⁺, Ni²⁺, Cu²⁺, Zn²⁺), other metal ions (e.g., Al³⁺), an ammonium ion, a triethylammonium ion, a tributylammonium ion, a pyridinium ion, a tetrabutylammonium ion, a guanidinium ion, a tetramethylguanidinium ion, and a diazabicycloundecenium ion. The cation is preferably Na⁺, K⁺, Mg²⁺, Ca²⁺, Zn²⁺, or a diazabicycloundecenium ion.

In the general formula 3, when the charge in the portion represented by Cy in the formula is intramolecularly neutralized, X¹ is not present. That is, c represents 0.

The compound represented by the general formula 3 is also preferably a compound represented by formula (3-1) or (3-2) below. This compound has high heat resistance.

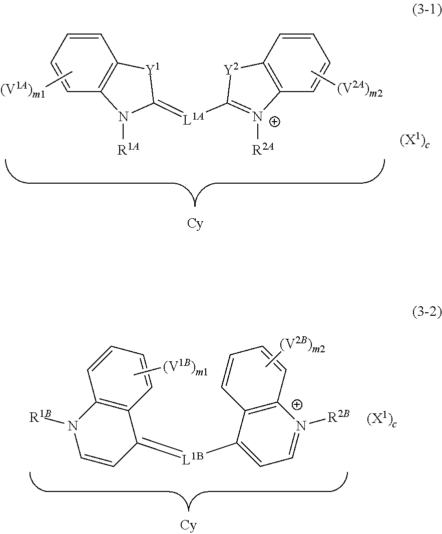

In the formulae (3-1) and (3-2), R^{1A}, R^{2A}, R^{1B}, and R^{2B} each independently represent an alkyl group, an alkenyl group, an alkynyl group, an aralkyl group, or an aryl group;

L^{1A} and L^{1B} each independently represent a methine chain having an odd number of methine groups;

Y¹ and Y² each independently represent —S—, —O—, —NR^{X1}—, or —CR^{X2}R^{X3}—;

R^{X1}, R^{X2}, and R^{X3} each independently represent a hydrogen atom or an alkyl group;

V^{1A}, V^{2A}, V^{1B}, and V^{2B} each independently represent a halogen atom, a cyano group, a nitro group, an alkyl group, an alkenyl group, an alkynyl group, an aralkyl group, an aryl group, a heteroaryl group, —OR^{c1}, —COR^{c2}, —COOR^{c3}, —OCOR^{c4}, —NR^{c5}R^{c6}, —NHCOR^{c7}, —CONR^{c8}CR^{c9}, —NHCONR^{c10}R^{c11}, —NHCOOR^{c12}, —SR^{c13}, —SO₂R^{c14}, —SO₂OR^{c15}, —NHSO₂R^{c16}, or —SO₂NR^{c17}R^{c18}, and V^{1A}, V^{2A}, V^{1B}, and V^{2B} may form a fused ring;

R^{c1} to R^{c18} each independently represent a hydrogen atom, an alkyl group, an alkenyl group, an alkynyl group, an aryl group, or a heteroaryl group;

when R^{c3} in —COOR^{c3} represents a hydrogen atom or when R^{c15} in —SO₂OR^{c15} represents a hydrogen atom, the hydrogen atom may be dissociated or the group may be present in the form of a salt; and

m1 and m2 each independently represent 0 to 4.

When the portion represented by Cy in the formula is a cationic portion, X¹ represents an anion and c represents the number of X¹ required to balance the charge. When the portion represented by Cy in the formula is an anionic portion, X¹ represents a cation and c represents the number of X¹ required to balance the charge. When the charge in the portion represented by Cy in the formula is intramolecularly neutralized, X¹ is not present.

The groups represented by R^{1A}, R^{2A}, R^{1B}, and R^{2B} have the same meaning as the alkyl group, alkenyl group, alkynyl group, aralkyl group, and aryl group described in R¹⁰¹ and R¹⁰² in the general formula 3, and the preferred ranges thereof are also the same. These groups may be unsubstituted or may have a substituent. The substituent is, for example, a halogen atom, a hydroxy group, a carboxy group, a sulfo group, an alkoxy group, or an amino group, preferably a carboxy group or a sulfo group, and particularly preferably a sulfo group. For the carboxy group and the sulfo group, the hydrogen atom may be dissociated or the group may be present in the form of a salt. When R^{1A}, R^{2A}, R^{1B}, and R^{2B} represent an alkyl group, the alkyl group is preferably a linear alkyl group.

Y¹ and Y² each independently represent —S—, —O—, —NR^{X1}—, or —CR^{X2}R^{X3}— and preferably each independently represent —NR^{X1}—. R^{X1}, R^{X2}, and R^{X3} each independently represent a hydrogen atom or an alkyl group and preferably each independently represent an alkyl group. The number of carbon atoms in the alkyl group is preferably 1 to 10, more preferably 1 to 5, and particularly preferably 1 to 3. The alkyl group is a linear, branched, or cyclic alkyl group, preferably a linear or branched alkyl group, and particularly preferably a linear alkyl group. The alkyl group is particularly preferably a methyl group or an ethyl group.

L^{1A} and L^{1B} have the same meaning as L¹ in the general formula 3, and the preferred ranges thereof are also the same.

The groups represented by V^{1A}, V^{2A}, V^{1B}, and V^{2B} have the same ranges as those described in G^{A} and G^{B} in the general formula 1, and the preferred ranges thereof are also the same.

m1 and m2 each independently represent 0 to 4 and preferably each independently represent 0 to 2.

The anion and cation represented by X¹ have the same ranges as those described in X¹ in the general formula 3, and the preferred ranges thereof are also the same.

The following compound is exemplified as the compound represented by the general formula 3. Furthermore, compounds described in paragraphs 0044 and 0045 in JP2009-108267A are exemplified, the contents of which are incorporated herein. In the following table, Et represents an ethyl group.

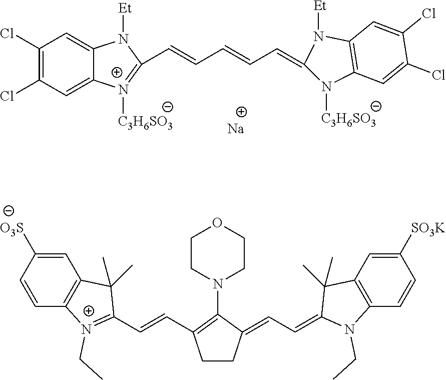

The compound represented by the general formula 3 can be easily synthesized with reference to F. M. Harmer “Heterocyclic Compounds—Cyanine Dyes and Related Compounds”, John Wiley & Sons: New York, London, 1964; D. M. Sturmer “Heterocyclic Compounds—Special Topics in Heterocyclic Chemistry”, Chapter 18, Section 14, pp. 482 to 515, John Wiley & Sons: New York, London, 1977; “Rodd's Chemistry of Carbon Compounds” 2nd Ed. vol. IV, part B, 1977, Chapter 15, pp. 369 to 422, Elsevier Science Publishing Company Inc.: New York; JP1994-313939A (JP-H6-313939A); and JP1993-88293A (JP-H5-88293A).

### Phthalocyanine Compound

The phthalocyanine compound is preferably a compound having a maximum absorption wavelength in the range of 650 to 850 nm and more preferably a compound having a maximum absorption wavelength in the range of 700 to 800 nm. The phthalocyanine compound is preferably a compound represented by formula (PC) below.

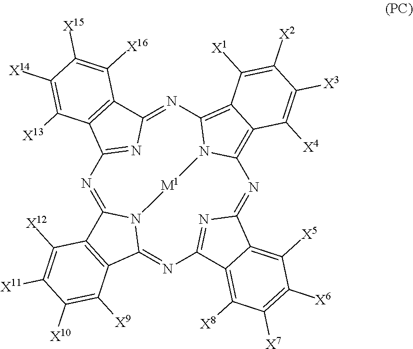

In the general formula (PC), X¹ to X¹⁶ each independently represent a hydrogen atom or a substituent, and M¹ represents Cu or V═O.

Examples of the substituent represented by X¹ to X¹⁶ include the above-described substituents T. An alkyl group, a halogen atom, an alkoxy group, a phenoxy group, an alkylthio group, a phenylthio group, an alkylamino group, and an anilino group are preferred.

For X¹ to X¹⁶, the number of substituents is preferably 0 to 16, more preferably 0 to 4, further preferably 0 or 1, and particularly preferably 0. M¹ preferably represents Ti═O.

Specific examples of the compound represented by the general formula (PC) include a compound described in paragraph 0093 in JP2012-77153A and oxytitanium phthalocyanine described in JP2006-343631A.

### Naphthalocyanine Compound

The naphthalocyanine compound is preferably a compound having a maximum absorption wavelength in the range of 650 to 850 nm and more preferably a compound having maximum absorption wavelength in the range of 700 to 800 nm. The naphthalocyanine compound is preferably a compound represented by formula (NPC) below.

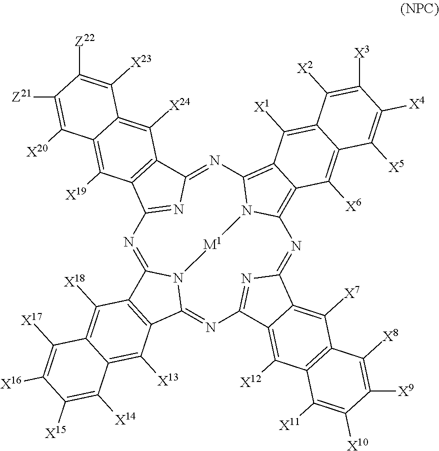

In the general formula (NPC), X¹ to X²⁴ each independently represent a hydrogen atom or a substituent, and M¹ represents Cu or V═O. Examples of the substituent represented by X¹ to X²⁴ include groups described in the substituents T. An alkyl group, a halogen atom, an alkoxy group, a phenoxy group, an alkylthio group, a phenylthio group, an alkylamino group, and an anilino group are preferred. M¹ preferably represents V═O.

A specific example of the compound represented by the general formula (NPC) is a compound described in paragraph 0093 in JP2012-77153A.

The content of the infrared absorber in the infrared absorbing layer is preferably 1 to 80 mass % based on the mass of the infrared absorbing layer. The lower limit of the content is preferably 5 mass % or more and more preferably 10 mass % or more. The upper limit of the content is preferably 70 mass % or less.

When the infrared absorbing layer is a layer including the copper compound as an infrared absorber, the content of the copper compound is preferably 30 to 70 mass % based on the mass of the infrared absorbing layer. The upper limit of the content is preferably 60 mass % or less and more preferably 55 mass % or less based on the mass of the infrared absorbing layer. The lower limit of the content is preferably 40 mass % or more and more preferably 45 mass % or more.

When the infrared absorbing layer is a layer including an organic dye (preferably at least one selected from the group consisting of a pyrrolopyrrole compound, a squarylium compound, a cyanine compound, a phthalocyanine compound, and a naphthalocyanine compound) other than the copper compound as an infrared absorber, the content of the organic dye is preferably 5 to 30 mass % based on the mass of the infrared absorbing layer. The upper limit of the content is preferably 20 mass % or less and more preferably 15 mass % or less based on the mass of the infrared absorbing layer. The lower limit of the content is preferably 5 mass % or more and more preferably 10 mass % or more.

The infrared absorbing layer preferably includes a resin. Examples of the resin include the resins described in the resin layer. The resin content is preferably 10 to 90 mass % based on the mass of the infrared absorbing layer. The lower limit of the content is preferably 30 mass % or more and more preferably 40 mass % or more. The upper limit of the content is preferably 70 mass % or less and more preferably 50 mass % or less. When the resin content is within the above range, it can be expected that good infrared absorbing properties (infrared shielding properties) are achieved and the elution of the infrared absorber into the adjacent layer can be suppressed.

When the infrared absorbing layer includes a resin, the absolute value of the difference between the solubility parameter (SP value) of the resin included in the infrared absorbing layer and the solubility parameter (SP value) of the resin included in the resin layer is preferably 0.5 to 5.0 (MPa)^{1/2}. The lower limit is preferably 0.5 (MPa)^{1/2} or more and more preferably 1.0 (MPa)^{1/2} or more. The upper limit is preferably 4.0 (MPa)^{1/2} or less and more preferably 3.0 (MPa)^{1/2} or less. When the absolute value is within the above range, the infrared absorber included in the infrared absorbing layer does not easily move to the resin layer, which can further reduce the haze. Furthermore, the adhesiveness between the resin layer and the infrared absorbing layer can be improved.

If the infrared absorbing layer includes two types of resins (e.g., a resin A1 and a resin A2), the SP value of the resins included in the infrared absorbing layer is determined by the following method.

SP value of resins included in infrared absorbing layer={(SP value of resin A1×content (mass %) of resin A1 in resins included in infrared absorbing layer)+(SP value of resin A2×content (mass %) of resin A2 in resins included in infrared absorbing layer)}/100

If the infrared absorbing layer includes three or more types of resins, the SP value of the resins included in the infrared absorbing layer is also determined by the same method described above.

If the resin layer includes two or more types of resins, the SP value of the resins included in the resin layer is also determined by the same method described above.

The infrared absorbing layer preferably has a thickness of 0.1 μm to 1.0 mm.

When the infrared absorbing layer is a layer including the copper compound as an infrared absorber, the thickness of the infrared absorbing layer is preferably 0.05 to 1.0 mm. The lower limit of the thickness is preferably 0.05 mm or more and more preferably 0.1 mm or more. The upper limit of the thickness is preferably 0.3 mm or less and more preferably 0.2 mm or less.

When the infrared absorbing layer is a layer including an organic dye (preferably at least one selected from the group consisting of a pyrrolopyrrole compound, a squarylium compound, a cyanine compound, a phthalocyanine compound, and a naphthalocyanine compound) other than the copper compound as an infrared absorber, the thickness of the infrared absorbing layer is preferably 0.1 to 500 μm. The upper limit of the thickness is more preferably 300 μm or less, further preferably 250 μm or less, and particularly preferably 200 μm or less. The lower limit of the thickness is more preferably 0.2 μm or more and further preferably 0.5 μm or more.

The infrared absorbing layer can be formed by using an infrared absorbing composition including the infrared absorber. For example, the infrared absorbing layer can be formed by applying the infrared absorbing composition onto a support or a resin layer 20 by a method such as coating. The infrared absorbing composition is applied by a method such as a dropping method (drop casting), coating with a spin coater, coating with a slit spin coater, coating with a slit coater, screen printing, or coating with an applicator. Hereafter, the infrared absorbing composition will be described.

### Infrared Absorbing Composition

### Infrared Absorber

The infrared absorber is, for example, the infrared absorber described in the infrared absorbing layer. The content of the infrared absorber in the infrared absorbing composition is preferably 1 to 80 mass % based on the total solid content of the infrared absorbing composition. The lower limit of the content is preferably 5 mass % or more and more preferably 10 mass % or more. The upper limit of the content is preferably 70 mass % or less. When the content of the infrared absorber is within the above range, a film having good infrared shielding properties is easily formed.

### Inorganic Fine Particles

The infrared absorbing composition may contain inorganic fine particles. The inorganic fine particles may be used alone or in combination of two or more.

The inorganic fine particles mainly act as particles that shield (absorb) infrared radiation. The inorganic fine particles are preferably metal oxide fine particles or metal fine particles from the viewpoint of achieving better infrared shielding properties.

Examples of the metal oxide fine particles include indium tin oxide (ITO) particles, antimony tin oxide (ATO) particles, zinc oxide (ZnO) particles, Al-doped zinc oxide (Al-doped ZnO) particles, fluorine-doped tin dioxide (F-doped SnO₂) particles, and niobium-doped titanium dioxide (Nb-doped TiO₂) particles.

Examples of the metal fine particles include silver (Ag) particles, gold (Au) particles, copper (Cu) particles, and nickel (Ni) particles. To achieve both good infrared shielding properties and high photolithographic performance, the transmittance of exposure light (wavelength: 365 to 405 nm) is desirably high and indium tin oxide (ITO) particles or antimony tin oxide (ATO) particles are preferred.

The inorganic fine particles may have any shape regardless of being spherical or nonspherical, such as a sheet-like shape, a wire-like shape, or a tubular shape.

The inorganic fine particles may be a tungsten oxide-based compound. Specifically, a tungsten oxide-based compound represented by general formula (composition formula) (I) below is preferably used.

MₓW_{y}O_{z} (I)

M represents a metal, W represents tungsten, and O represents oxygen.

0.001≤x/y≤1.1

2.2≤z/y≤3.0

Examples of the metal represented by M include alkali metals, alkaline-earth metals, Mg, Zr, Cr, Mn, Fe, Ru, Co, Rh, Ir, Ni, Pd, Pt, Cu, Ag, Au, Zn, Cd, Al, Ga, In, Tl, Sn, Pb, Ti, Nb, V, Mo, Ta, Re, Be, Hf, Os, and Bi. The metal is preferably an alkali metal, more preferably Rb or Cs, and particularly preferably Cs. The metals represented by M may be used alone or in combination of two or more.

When x/y is 0.001 or more, infrared radiation can be sufficiently shielded. When x/y is 1.1 or less, the generation of an impurity phase in the tungsten oxide-based compound can be avoided with more certainty.

When z/y is 2.2 or more, the chemical stability as a material can be further improved. When z/y is 3.0 or less, infrared radiation can be sufficiently shielded.

The tungsten oxide-based compound represented by the general formula (I) is specifically Cs_{0.33}WO₃, Rb_{0.33}WO₃, K_{0.33}WO₃, or Ba_{0.33}WO₃, preferably Cs_{0.33}WO₃ or Rb_{0.33}WO₃, and further preferably Cs_{0.33}WO₃.

For example, the tungsten oxide-based compound is available as a dispersion of tungsten fine particles such as YMF-02 manufactured by Sumitomo Metal Mining Co., Ltd.

The average particle size of the inorganic fine particles is preferably 800 nm or less, more preferably 400 nm or less, and further preferably 200 nm or less. When the average particle size of the inorganic fine particles is within the above range, better visible-light transmitting properties can be achieved. From the viewpoint of avoiding light scattering, the average particle size is preferably as small as possible. However, the average particle size of the inorganic fine particles is normally 1 nm or more from the viewpoint of, for example, ease of handling during production.

The content of the inorganic fine particles is preferably 0.01 to 30 mass % based on the total solid content of the infrared absorbing composition. The lower limit of the content is preferably 0.1 mass % or more and more preferably 1 mass % or more. The upper limit of the content is preferably 20 mass % or less and more preferably 10 mass % or less.

### Resin

The infrared absorbing composition may contain a resin. The resin is, for example, the resin described in the resin layer. The resin may be the above-described resin having a crosslinking group or may be a resin not having a crosslinking group. When the resin having a crosslinking group is used, an infrared absorbing layer having high heat resistance and high solvent resistance can be formed without using a crosslinking compound described later. Only one resin may be used or two or more resins may be used in combination. When two or more resins are used in combination, two or more resins not having a crosslinking group may be used in combination. Two or more resins having a crosslinking group may be used in combination. Alternatively, one or more resins not having a crosslinking group and one or more resins having a crosslinking group may be used in combination. In the present invention, the resin having a crosslinking group is also a component that corresponds to a crosslinking compound described later. That is, in the present invention, the resin having a crosslinking group corresponds to not only the resin, but also a crosslinking compound described later.

The content of the resin (i.e., the total content of the resin having a crosslinking group and the resin not having a crosslinking group) is preferably 1 to 80 mass % based on the total solid content of the infrared absorbing composition. The lower limit of the content is preferably 5 mass % or more and more preferably 10 mass % or more. The upper limit of the content is preferably 70 mass % or less. The resin may be constituted by only the resin having a crosslinking group. The resin may be constituted by only the resin not having a crosslinking group. The resin having a crosslinking group and the resin not having a crosslinking group may be used in combination.

The content of the resin not having a crosslinking group is preferably 1 to 80 mass % based on the total solid content of the infrared absorbing composition. The lower limit of the content is preferably 5 mass % or more and more preferably 10 mass % or more. The upper limit of the content is preferably 70 mass % or less.

The content of the resin having g crosslinking group is preferably 1 to 80 mass % based on the total solid content of the infrared absorbing composition. The lower limit of the content is preferably 5 mass % or more and more preferably 10 mass % or more. The upper limit of the content is preferably 70 mass % or less.

When the resin having a crosslinking group and the resin not having a crosslinking group are used in combination, the content of the resin having a crosslinking group is preferably 30 to 99 mass % based on the total mass of the resins. The lower limit of the content may be 50 mass % or more or 40 mass % or more. The upper limit of the content may be 90 mass % or less or 70 mass % or less.

The resin preferably includes at least the resin having a crosslinking group and more preferably includes substantially only the resin having a crosslinking group. In the present invention, when the resin includes substantially only the resin having a crosslinking group, the content of the resin having a crosslinking group is preferably 99 mass % or more based on the total mass of the resins and more preferably 99.9 mass % or more, or the resin further preferably includes only the resin having a crosslinking group.

The resins may be used alone or in combination of two or more. When the resins are used in combination of two or more, the total content of the resins is preferably within the above range.

### Compound Having Crosslinking Group (Crosslinking Compound)

The infrared absorbing composition may contain a compound having a crosslinking group. When the infrared absorbing composition contains a crosslinking compound, an infrared absorbing layer having high heat resistance and high solvent resistance can be formed. The crosslinking compound is, for example, a publicly known compound that enables crosslinking by using radicals, acids, or heat. Examples of the crosslinking compound include compounds having a group having an ethylenically unsaturated bond, compounds having a cyclic ether group, compounds having a methylol group, and compounds having a partial structure represented by M-X described later. The group having an ethylenically unsaturated bond is, for example, a vinyl group, a styryl group, a (meth)allyl group, or a (meth)acryloyl group and preferably a (meth)allyl group or a (meth)acryloyl group. The cyclic ether group is, for example, an epoxy group or an oxetanyl group and preferably an epoxy group.

The crosslinking compound may be in the form of monomer or polymer. Examples of the polymer-type crosslinking compound include the epoxy resin described in the resin above and resins including a structural unit having a crosslinking group. The molecular weight of the monomer-type crosslinking compound is preferably less than 2000, more preferably 100 or more and less than 2000, and further preferably 200 or more and less than 2000. The upper limit of the molecular weight is, for example, preferably 1500 or less. The weight-average molecular weight (Mw) of the polymer-type crosslinking compound is preferably 2,000 to 2,000,000. The upper limit of the weight-average molecular weight is preferably 1,000,000 or less and more preferably 500,000 or less. The lower limit of the weight-average molecular weight is preferably 3,000 or more and more preferably 5,000 or more. In the case of the compound having a cyclic ether group, the weight-average molecular weight (Mw) is preferably 100 or more and more preferably 200 to 2,000,000. The upper limit of the weight-average molecular weight is preferably 1,000,000 or less and more preferably 500,000 or less.

### Compound Having Group Having Ethylenically Unsaturated Bond

The compound having a group having an ethylenically unsaturated bond is preferably a trifunctional to pentadecafunctional (meth)acrylate compound and more preferably a trifunctional to hexafunctional (meth)acrylate compound. For the compound having a group having an ethylenically unsaturated bond, the description in paragraphs 0033 and 0034 in JP2013-253224A can be taken into consideration, the contents of which are incorporated herein. Specifically, preferred examples of the compound include ethyleneoxy-modified pentaerythritol tetraacrylate (commercially available as NK Ester ATM-35E, manufactured by Shin Nakamura Chemical Co., Ltd.), dipentaerythritol triacrylate (commercially available as KAYARAD D-330, manufactured by Nippon Kayaku Co., Ltd.), dipentaerythritol tetraacrylate (commercially available as KAYARAD D-320, manufactured by Nippon Kayaku Co., Ltd.), dipentaerythritol penta(meth)acrylate (commercially available as KAYARAD D-310, manufactured by Nippon Kayaku Co., Ltd.), dipentaerythritol hexa(meth)acrylate (commercially available as KAYARAD DPHA, manufactured by Nippon Kayaku Co., Ltd. and A-DPH-12E, manufactured by Shin Nakamura Chemical Co., Ltd.), and compounds having a structure in which these (meth)acryloyl groups link to each other through an ethylene glycol or propylene glycol residue. Oligomers corresponding to these examples can also be used. Furthermore, the description of a polymerizable compound in paragraphs 0034 to 0038 in JP2013-253224A can be taken into consideration, the contents of which are incorporated herein. A polymerizable monomer described in paragraph 0477 in JP2012-208494A (paragraph 0585 in corresponding US2012/0235099A) is exemplified, the contents of which are incorporated herein. Another preferred example is diglycerin EO (ethylene oxide)-modified (meth)acrylate (commercially available as M-460, manufactured by TOAGOSEI Co., Ltd.). Other preferred examples include pentaerythritol tetraacrylate (A-TMMT, manufactured by Shin Nakamura Chemical Co., Ltd.) and 1,6-hexanediol diacrylate (KAYARAD HDDA, manufactured by Nippon Kayaku Co., Ltd.). Oligomers corresponding to these examples can also be used. For example, RP-1040 (manufactured by Nippon Kayaku Co., Ltd.) can be used.

The compound including a group having an ethylenically unsaturated bond may further have an acid group such as a carboxy group, a sulfonate group, or a phosphate group. An example of the compound having an acid group is an ester of an aliphatic polyhydroxy compound and an unsaturated carboxylic acid. A polyfunctional monomer prepared by causing unreacted hydroxy groups of the aliphatic polyhydroxy compound to react with a non-aromatic carboxylic anhydride so as to introduce acid groups is preferred. In particular, the aliphatic polyhydroxy compound is preferably pentaerythritol and/or dipentaerythritol. Examples of commercially available products include, as polybasic acid-modified acrylic oligomers, ARONIX series M-305, M-510, and M-520 manufactured by TOAGOSEI Co., Ltd. The compound having an acid group preferably has an acid value of 0.1 to 40 mgKOH/g. The lower limit of the acid value is preferably 5 mgKOH/g or more. The upper limit of the acid value is preferably 30 mgKOH/g or less.

The compound including a group having an ethylenically unsaturated bond is also preferably a compound having a caprolactone structure. For the compound having a caprolactone structure, the description in paragraphs 0042 to 0045 in JP2013-253224A can be taken into consideration, the contents of which are incorporated herein. Examples of commercially available products include SR-494, which is a tetrafunctional acrylate having four ethyleneoxy chains and is manufactured by Sartomer; DPCA-60, which is a hexafunctional acrylate having six pentyleneoxy chains and is manufactured by Nippon Kayaku Co., Ltd.; and TPA-330, which is a trifunctional acrylate having three isobutyleneoxy chains and is manufactured by Nippon Kayaku Co., Ltd.

In the present invention, the compound having a group having an ethylenically unsaturated bond may be a polymer that has, on its side chain, a group having an ethylenically unsaturated bond described in the resin above.

### Compound Having Cyclic Ether Group

Examples of the compound having a cyclic ether group include monofunctional or polyfunctional glycidyl ether compounds and polyfunctional aliphatic glycidyl ether compounds. Other examples include compounds having a glycidyl group as an epoxy group, such as glycidyl (meth)acrylate and allyl glycidyl ether, and compounds having an alicyclic epoxy group. For these compounds, the description in paragraph 0045 and the like in JP2009-265518A can be taken into consideration, the contents of which are incorporated herein. The epoxy resin described in the resin above is also exemplified.

### Compound Having Partial Structure Represented by M-X

In the present invention, the crosslinking compound may also be a compound having a partial structure represented by M-X. In particular, when the copper compound is used as an infrared absorber, the compound having a partial structure represented by M-X is preferably used as a crosslinking compound. In this case, a near-infrared cut filter having high heat resistance and high solvent resistance is easily produced.

In the compound having a partial structure represented by M-X, M represents an atom selected from the group consisting of Si, Ti, Zr, and Al, preferably represents Si, Ti, or Zr, and more preferably represents Si.

In the compound having a partial structure represented by M-X, X represents one group selected from the group consisting of a hydroxy group, an alkoxy group, an acyloxy group, a phosphoryloxy group, a sulfonyloxy group, an amino group, an oxime group, and O═C(R^{a})(R^{b}), preferably represents an alkoxy group, an acyloxy group, or an oxime group, and more preferably represents an alkoxy group. When X represents O═C(R^{a})(R^{b}), X bonds to M through an unshared electron pair of an oxygen atom in the carbonyl group (—CO—). R^{a} and R^{b} each independently represent a monovalent organic group.

The partial structure represented by M-X preferably has a combination of M representing Si and X representing an alkoxy group. In this combination, the structure has moderate reactivity and thus the composition has good preservation stability. Furthermore, a near-infrared cut filter having higher heat resistance is easily produced.

The number of carbon atoms in the alkoxy group represented by X is preferably 1 to 20, more preferably 1 to 10, further preferably 1 to 5, and particularly preferably 1 or 2. The alkoxy group is a linear, branched, or cyclic alkoxy group, preferably a linear or branched alkoxy group, and more preferably a linear alkoxy group. The alkoxy group may be unsubstituted or may have a substituent, but is preferably unsubstituted. Examples of the substituent include halogen atoms (preferably a fluorine atom), a vinyl group, a (meth)acryloyl group, a styryl group, an epoxy group, an oxetanyl group, an amino group, an isocyanate group, an isocyanurate group, a ureido group, a mercapto group, a sulfide group, a sulfo group, a carboxy group, and a hydroxy group.

The acyloxy group represented by X is, for example, a substituted or unsubstituted alkylcarbonyloxy group having 2 to 30 carbon atoms or a substituted or unsubstituted arylcarbonyloxy group having 6 to 30 carbon atoms. Examples of the acyloxy group include a formyloxy group, an acetyloxy group, a pivaloyloxy group, stearoyloxy, a benzoyloxy group, and a p-methoxyphenylcarbonyloxy group. Examples of the substituent include the above-described substituents.

The number of carbon atoms in the oxime group represented by X is preferably 1 to 20, more preferably 1 to 10, and further preferably 1 to 5. For example, an ethyl methyl ketoxime group is used.

The amino group represented by X is, for example, an amino group, a substituted or unsubstituted alkylamino group having 1 to 30 carbon atoms, a substituted or unsubstituted arylamino group having 6 to 30 carbon atoms, or a heterocyclic amino group having 0 to 30 carbon atoms. For example, amino, methylamino, dimethylamino, anilino, N-methylanilino, diphenylamino, and N-1,3,5-triazin-2-ylamino are used. Examples of the substituent include the above-described substituents.

The monovalent organic group represented by R^{a} and R^{b} is, for example, an alkyl group, an aryl group, or a group represented by —R¹⁰¹—COR¹⁰². The number of carbon atoms in the alkyl group is preferably 1 to 20 and more preferably 1 to 10. The alkyl group is a linear, branched, or cyclic alkyl group. The alkyl group may be unsubstituted or may have the above-described substituent. The number of carbon atoms in the aryl group is preferably 6 to 20 and more preferably 6 to 12. The aryl group may be unsubstituted or may have the above-described substituent. In the group represented by —R¹⁰¹—COR¹⁰², R¹⁰¹ represents an arylene group and R¹⁰² represents an alkyl group or an aryl group. The number of carbon atoms in the arylene group represented by R¹⁰¹ is preferably 1 to 20 and more preferably 1 to 10. The arylene group is a linear, branched, or cyclic arylene group. The arylene group may be unsubstituted or may have the above-described substituent. The alkyl group and the aryl group represented by R¹⁰² are the same as those described in R^{a} and R^{b}, and the preferred ranges thereof are also the same.

The compound having a partial structure represented by M-X may be a low-molecular-weight compound or a polymer-type compound, but a polymer-type compound is preferred because a film having higher heat resistance is easily formed. For the compound having a partial structure represented by M-X, the molecular weight of the low-molecular-weight compound is preferably 100 to 1000. The upper limit of the molecular weight is preferably 800 or less and more preferably 700 or less. The molecular weight is a theoretical value determined from the structural formula. For the compound having a partial structure represented by M-X, the weight-average molecular weight of the polymer-type compound is preferably 500 to 300000. The lower limit of the weight-average molecular weight is preferably 1000 or more and more preferably 2000 or more. The upper limit of the weight-average molecular weight is preferably 250000 or less and more preferably 200000 or less.

For the compound having a partial structure represented by M-X, the low-molecular-weight compound is, for example, a compound represented by formula (MX1) below.

M-(X¹)ₘ (MX1)

M represents an atom selected from the group consisting of Si, Ti, Zr, and Al; X¹ represents a substituent or a ligand; at least one of mX¹ represents one group selected from the group consisting of a hydroxy group, an alkoxy group, an acyloxy group, a phosphoryloxy group, a sulfonyloxy group, an amino group, an oxime group, and O═C(R^{a})(R^{b}); X¹ may bond to each other to form a ring; and m represents the number of bonding arms of M with X¹. R^{a} and R^{b} each independently represent a monovalent organic group. When X¹ represents O═C(R^{a})(R^{b}), X¹ bonds to M through an unshared electron pair of an oxygen atom in the carbonyl group (—CO—).

M represents an atom selected from the group consisting of Si, Ti, Zr, and Al, preferably represents Si, Ti, or Zr, and more preferably represents Si. X¹ represents a substituent or a ligand; at least one of mX¹ represents one group selected from the group consisting of a hydroxy group, an alkoxy group, an acyloxy group, a phosphoryloxy group, a sulfonyloxy group, an amino group, an oxime group, and O═C(R^{a})(R^{b}); at least one of mX¹ preferably represents one group selected from the group consisting of an alkoxy group, an acyloxy group, and an oxime group; at least one of mX¹ more preferably represents an alkoxy group; and further preferably all X¹ represent an alkoxy group.

For the substituent and ligand, the hydroxy group, the alkoxy group, the acyloxy group, the phosphoryloxy group, the sulfonyloxy group, the amino group, the oxime group, and O═C(R^{a})(R^{b}) have the same meaning as those described above, and the preferred ranges are also the same.

The substituent other than the hydroxy group, the alkoxy group, the acyloxy group, the phosphoryloxy group, the sulfonyloxy group, the amino group, and the oxime group is preferably a hydrocarbon group. The hydrocarbon group is, for example, an alkyl group, an alkenyl group, or an aryl group. The hydrocarbon group may have a substituent or may be unsubstituted. Examples of the substituent include alkyl groups, halogen atoms (preferably a fluorine atom), a vinyl group, a (meth)acryloyl group, a styryl group, an epoxy group, an oxetanyl group, an amino group, an isocyanate group, an isocyanurate group, a ureido group, a mercapto group, a sulfide group, a sulfo group, a carboxy group, a hydroxy group, and an alkoxy group.

The alkyl group is a linear, branched, or cyclic alkyl group. The number of carbon atoms in the linear alkyl group is preferably 1 to 20, more preferably 1 to 12, and further preferably 1 to 8. The number of carbon atoms in the branched alkyl group is preferably 3 to 20, more preferably 3 to 12, and further preferably 3 to 8. The cyclic alkyl group is a monocyclic or polycyclic alkyl group. The number of carbon atoms in the cyclic alkyl group is preferably 3 to 20, more preferably 4 to 10, and further preferably 6 to 10.

The number of carbon atoms in the alkenyl group is preferably 2 to 10, more preferably 2 to 8, and further preferably 2 to 4.

The number of carbon atoms in the aryl group is preferably 6 to 18, more preferably 6 to 14, and further preferably 6 to 10.

Examples of the compound with M representing Si include methyltrimethoxysilane, dimethyldimethoxysilane, phenyltrimethoxysilane, methyltriethoxysilane, dimethyldiethoxysilane, phenyltriethoxysilane, n-propyltrimethoxysilane, n-propyltriethoxysilane, hexyltrimethoxysilane, hexyltriethoxysilane, octyltriethoxysilane, decyltrimethoxysilane, 1,6-bis(trimethoxysilyl)hexane, trifluoropropyltrimethoxysilane, hexamethyldisilazane, vinyltrimethoxysilane, vinyltriethoxysilane, 2-(3,4-epoxycyclohexyl)ethyltrimethoxysilane, 3-glycidoxypropylmethyldimethoxysilane, 3-glycidoxypropyltrimethoxysilane, 3-glycidoxypropylmethyldiethoxysilane, 3-glycidoxypropyltriethoxysilane, p-styryltrimethoxysilane, 3-methacryloxypropylmethyldimethoxysilane, 3-methacryloxypropyltrimethoxysilane, 3-methacryloxypropylmethyldiethoxysilane, 3-methacryloxypropyltriethoxysilane, 3-acryloxypropyltrimethoxysilane, N-2-(aminoethyl)-3-aminopropylmethyldimethoxysilane, N-2-(aminoethyl)-3-aminopropyltrimethoxysilane, 3-aminopropyltrimethoxysilane, 3-aminopropyltriethoxysilane, 3-triethoxysilyl-N-(1,3-dimethyl-butylidene)propylamine, N-phenyl-3-aminopropyltrimethoxysilane, N-(vinylbenzyl)-2-aminoethyl-3-aminopropyltrimethoxysilane hydrochloride, tris-(trimethoxysilylpropyl)isocyanurate, 3-ureidopropyltriethoxysilane, 3-mercaptopropylmethyldimethoxysilane, 3-mercaptopropyltrimethoxysilane, bis(triethoxysilylpropyl)tetrasulfide, and 3-isocyanatopropyltriethoxysilane.

Examples of the commercially available product include KBM-13, KBM-22, KBM-103, KBE-13, KBE-22, KBE-103, KBM-3033, KBE-3033, KBM-3063, KBE-3063, KBE-3083, KBM-3103, KBM-3066, KBM-7103, SZ-31, KPN-3504, KBM-1003, KBE-1003, KBM-303, KBM-402, KBM-403, KBE-402, KBE-403, KBM-1403, KBM-502, KBM-503, KBE-502, KBE-503, KBM-5103, KBM-602, KBM-603, KBM-903, KBE-903, KBE-9103, KBM-573, KBM-575, KBM-9659, KBE-585, KBM-802, KBM-803, KBE-846, and KBE-9007 manufactured by Shin-Etsu Chemical Co., Ltd.

Examples of the compound with M representing Ti include tetraisopropyl titanate, tetra-n-butyl titanate, butyl titanate dimer, tetraoctyl titanate, titanium diisopropoxide bis(acetylacetonate), titanium tetraacetylacetonate, titanium diisopropoxide bis(ethylacetoacetate), titanium phosphate compounds, titanium di-2-ethylhexoxide bis(2-ethyl-3-hydroxyhexoxide), titanium diisopropoxide bis(ethylacetoacetate), titanium lactate ammonium salts, titanium lactate, titanium diisopropoxide bis(triethanolaminate), tert-amyl titanate, tetra-tert-butyl titanate, tetrastearyl titanate, titanium 1,3-propanedioxide bis(ethylacetoacetate), titanium dodecylbenzenesulfonate compounds, titanium isostearate, titanium diethanolaminate, and titanium aminoethylaminoethanolate. Examples of the commercially available product include ORGATIX series manufactured by Matsumoto Fine Chemical Co., Ltd. (e.g., TA-10, TA-21, TA-23, TA-30, TC-100, TC-401, TC-710, TC-1040, TC-201, TC-750, TC-300, TC-310, TC-315, TC-400, TA-60, TA-80, TA-90, TC-120, TC-220, TC-730, TC-810, TC-800, TC-500, and TC-510) and PLENACT series manufactured by Ajinomoto Fine-Techno Co., Inc. (e.g., TTS, 46B, 55, 41B, 38S, 138S, 238S, 338X, 44, 9SA, and ET).

Examples of the compound with M representing Zr include zirconium tetra-n-propoxide, zirconium tetra-n-butoxide, zirconium tetraacetylacetonate, zirconium tributoxide monoacetylacetonate, and zirconium dibutoxide bis(ethylacetoacetate). Examples of the commercially available product include ORGATIX series manufactured by Matsumoto Fine Chemical Co., Ltd. (e.g., ZA-45, ZA-65, ZC-150, ZC-540, ZC-700, ZC-580, ZC-200, ZC-320, ZC-126, and ZC-300).

An example of the compound with M representing A1 is aluminum alkylacetoacetate diisopropylate. An example of the commercially available product is PLENACT AL-M manufactured by Ajinomoto Fine-Techno Co., Inc.

For the compound having a partial structure represented by M-X, examples of the polymer-type compound include acrylic resin, acrylamide resin, styrene resin, and polysiloxane. In particular, acrylic resin, acrylamide resin, or styrene resin is preferred from the viewpoint of improving film properties and easily controlling the viscosity of a coating liquid.

Specifically, the polymer-type compound is, for example, a polymer having one structural unit selected from the group consisting of a structural unit represented by (MX2-1) below, a repeating unit represented by (MX2-2) below, and a structural unit represented by (MX2-3) below.

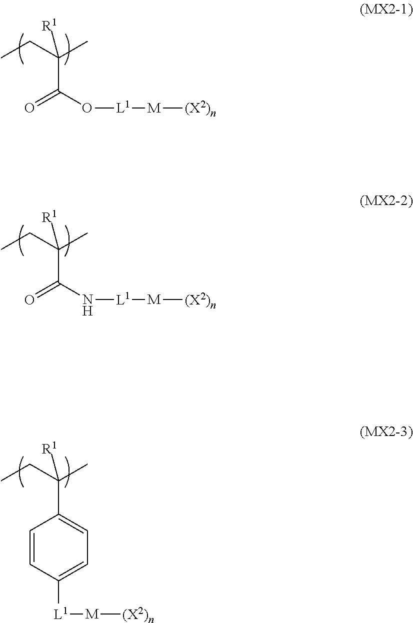

M represents an atom selected from the group consisting of Si, Ti, Zr, and Al; X² represents a substituent or a ligand; at least one of nX² represents at least one group selected from the group consisting of a hydroxy group, an alkoxy group, an acyloxy group, a phosphoryloxy group, a sulfonyloxy group, an amino group, an oxime group, and O═C(R^{a})(R^{b}); X² may bond to each other to form a ring; R¹ represents a hydrogen atom or an alkyl group; L¹ represents a single bond or a divalent linking group; and n represents the number of bonding arms of M with X². R^{a} and R^{b} each independently represent a monovalent organic group. When X² represents O═C(R^{a})(R^{b}), X² bonds to M through an unshared electron pair of an oxygen atom in the carbonyl group (—CO—).

M and X² have the same meaning as M and X¹ in the formula (MX1), and the preferred ranges thereof are also the same.

R¹ represents a hydrogen atom or an alkyl group. The number of carbon atoms in the alkyl group is preferably 1 to 5, more preferably 1 to 3, and particularly preferably 1. The alkyl group is preferably a linear or branched alkyl group and more preferably a linear alkyl group. Some or all hydrogen atoms in the alkyl group may be substituted with halogen atoms (preferably fluorine atoms).

L¹ represents a single bond or a divalent linking group. The divalent linking group is, for example, an alkylene group, an arylene group, —O—, —S—, —CO—, —COO—, —OCO—, —SO₂—, —NR¹⁰— (R¹⁰ represents a hydrogen atom or an alkyl group and preferably represents a hydrogen atom), or a group obtained by combining the foregoing groups and preferably a group obtained by combining at least one of an alkylene group, an arylene group, or an alkylene group with —O—.

The number of carbon atoms in the alkylene group is preferably 1 to 30, more preferably 1 to 15, and further preferably 1 to 10. The alkylene group may have a substituent, but is preferably unsubstituted. The alkylene group is a linear, branched, or cyclic alkylene group. The cyclic alkylene group is a monocyclic or polycyclic alkylene group.

The number of carbon atoms in the arylene group is preferably 6 to 18, more preferably 6 to 14, further preferably 6 to 10, and particularly preferably a phenylene group.

The polymer-type compound may include other structural units in addition to the structural units represented by the formulae (MX2-1), (MX2-2), and (MX2-3). For components constituting the other structural units, the description of copolymerization components in paragraphs 0068 to 0075 in JP2010-106268A (paragraphs 0112 to 0118 in corresponding US2011/0124824A can be taken into consideration, the contents of which are incorporated herein.

The polymer-type compound may also have the structural units represented by (A3-1) to (A3-6) described in the resin above.

When the polymer-type compound includes other structural units (preferably the structural units represented by the formulae (A3-1) to (A3-6)), the molar ratio of the total content of the structural units represented by the formulae (MX2-1) to (MX2-3) and the total content of the other structural units is preferably 95:5 to 20:80 and more preferably 90:10 to 40:60. By increasing the content of the structural units represented by the formulae (MX2-1) to (MX2-3) within the above range, the moisture resistance and the solvent resistance tend to further improve. By decreasing the content of the structural units represented by the formulae (MX2-1) to (MX2-3) within the above range, the heat resistance tends to further improve.

The content of the crosslinking compound (including a resin (polymer-type crosslinking compound) having a crosslinking group) is preferably 15 mass % or more, more preferably 20 mass % or more, and further preferably 25 mass % or more based on the total solid content of the infrared absorbing composition. The upper limit of the content is preferably 80 mass % or less, more preferably 70 mass % or less, and further preferably 65 mass % or less.

The crosslinking compound may be constituted by only the monomer-type compound. The crosslinking compound may be constituted by only the resin having a crosslinking group (polymer-type crosslinking compound). The monomer-type compound and the resin having a crosslinking group (polymer-type crosslinking compound) may be used in combination. When the monomer-type compound and the resin having a crosslinking group (polymer-type crosslinking compound) are used in combination, the content of the resin having a crosslinking group (polymer-type crosslinking compound) is preferably 30 to 90 mass % based on the total mass of the crosslinking compounds. The lower limit of the content may be 50 mass % or more or 40 mass % or more. The upper limit of the content may be 70 mass % or less or 50 mass % or less.

The total content of the resin and the crosslinking compound is preferably 15 to 99 mass % based on the total solid content of the infrared absorbing composition. The lower limit of the total content is preferably 20 mass % or more and more preferably 25 mass % or more. The upper limit of the total content is preferably 95 mass % or less and more preferably 90 mass % or less.

The crosslinking compound may be used alone or two or more crosslinking compounds may be used. If two or more crosslinking compounds are used, the total content is preferably within the above range.

### Gelatin

The infrared absorbing composition preferably contains a gelatin. When the infrared absorbing composition contains a gelatin, an infrared absorbing layer having high heat resistance is easily formed. The specific mechanism is unclear, but this may be because the infrared absorber and the gelatin tend to form an associate. In particular, when the cyanine compound is used as an infrared absorber, an infrared absorbing layer having high heat resistance is easily formed.

In the present invention, the gelatin is classified into an acid-treated gelatin and an alkali-treated gelatin (e.g., liming) in accordance with the synthesis method, and both of them can be preferably used. The molecular weight of the gelatin is preferably 10,000 to 1,000,000. A modified gelatin that is modified by using an amino group or a carboxy group of the gelatin can also be used (e.g., phthalated gelatin). Examples of the gelatin include an inert gelatin (e.g., Nitta gelatin 750) and a phthalated gelatin (e.g., Nitta gelatin 801).

To improve the water resistance and mechanical strength of the infrared absorbing layer, the gelatin is preferably hardened by using various compounds. A publicly known hardener can be used. Examples of the hardener include aldehyde compounds such as formaldehyde and glutaraldehyde, compounds having reactive halogens and described in U.S. Pat. No. 3,288,775A and the like, compounds having a reactive ethylenically unsaturated bond and described in U.S. Pat. No. 3,642,486A, JP1974-13563B (JP-S49-13563B), and the like, aziridine compounds described in U.S. Pat. No. 3,017,280A and the like, epoxy compounds described in U.S. Pat. No. 3,091,537A and the like, halogen carboxaldehydes such as mucochloric acid, dioxanes such as dihydroxydioxane and dichlorodioxane, and inorganic hardeners such as chromium alum and zirconium sulfate. Specifically, 1,3-divinylsulfonyl-2-propanol is used.

The content of the gelatin is preferably 1 to 99 mass % based on the total solid content of the infrared absorbing composition. The lower limit of the content is preferably 10 mass % or more and more preferably 20 mass % or more. The upper limit of the content is preferably 95 mass % or less and more preferably 90 mass % or less.

### Photopolymerization Initiator

The infrared absorbing composition may contain a photopolymerization initiator. The content of the photopolymerization initiator is preferably 0.01 to 30 mass % based on the total solid content of the infrared absorbing composition. The lower limit of the content is preferably 0.1 mass % or more and more preferably 0.5 mass % or more. The upper limit of the content is preferably 20 mass % or less and more preferably 15 mass % or less. The photopolymerization initiator may be used alone or two or more photopolymerization initiators may be used. When two or more photopolymerization initiators are used, the total content is preferably within the above range.

Any photopolymerization initiator can be appropriately selected in accordance with the purpose as long as it is capable of initiating the polymerization of a curable compound by applying light. When polymerization is initiated by applying light, a photopolymerization initiator having photosensitivity to light in an ultraviolet to visible range is preferably used.

The photopolymerization initiator is preferably a compound having at least an aromatic group. Examples of the compound include acylphosphine compounds, acetophenone compounds, ca-aminoketone compounds, benzophenone compounds, benzoin ether compounds, ketal derivative compounds, thioxanthone compounds, oxime compounds, hexaarylbiimidazole compounds, trihalomethyl compounds, azo compounds, organic peroxides, diazonium compounds, iodonium compounds, sulfonium compounds, azinium compounds, benzoin ether compounds, ketal derivative compounds, onium salt compounds such as metallocene compounds, organic boron salt compounds, disulfone compounds, and thiol compounds.

For the photopolymerization initiator, the description in paragraphs 0217 to 0228 in JP2013-253224A can be taken into consideration, the contents of which are incorporated herein.

Examples of the oxime compound include IRGACURE-OXE01 (manufactured by BASF), IRGACURE-OXE02 (manufactured by BASF), TR-PBG-304 (manufactured by Changzhou Tronly New Electronic Materials Co., Ltd.), ADEKA ARKLS NCI-831 (manufactured by ADEKA), and ADEKA ARKLS NCI-930 (manufactured by ADEKA), which are commercially available products.

Examples of the acetophenone compound include IRGACURE-907, IRGACURE-369, and IRGACURE-379 (trade name: all manufactured by BASF), which are commercially available products. Examples of the acylphosphine compound include IRGACURE-819 and DAROCUR-TPO (trade name: all manufactured by BASF), which are commercially available products.

In the present invention, an oxime compound having a fluorine atom may also be used as a photopolymerization initiator. Specific examples of the oxime compound having a fluorine atom include compounds described in JP2010-262028A, compounds 24 and 36 to 40 described in JP2014-500852A, and a compound (C-3) described in JP2013-164471A, the contents of which are incorporated herein.

An oxime compound having a nitro group may also be used as a photopolymerization initiator. Specific examples of the oxime compound having a nitro group include compounds described in paragraphs 0031 to 0047 in JP2013-114249A and paragraphs 0008 to 0012 and 0070 to 0079 in JP2014-137466A, and ADEKAARKLS NCI-831 (manufactured by ADEKA).

### Heat Stabilizer

The infrared absorbing composition may also contain an oxime compound as a heat stabilizer. In particular, when the copper compound is used as an infrared absorber, the heat resistance of the infrared absorbing layer can be further improved by adding a heat stabilizer such as an oxime compound. Examples of the oxime compound include IRGACURE-OXE01 (manufactured by BASF), IRGACURE-OXE02 (manufactured by BASF), TR-PBG-304 (manufactured by Changzhou Tronly New Electronic Materials Co., Ltd.), ADEKA ARKLS NCI-831 (manufactured by ADEKA), and ADEKA ARKLS NCI-930 (manufactured by ADEKA), which are commercially available products. The above-described oxime compound having a fluorine atom and the above-described oxime compound having a nitro group can also be used.

The content of the heat stabilizer is preferably 0.01 to 30 mass % based on the total solid content of the infrared absorbing composition. The lower limit of the content is preferably 0.1 mass % or more. The upper limit of the content is preferably 20 mass % or less and more preferably 10 mass % or less.

### Catalyst

The infrared absorbing composition preferably contains a catalyst. When the infrared absorbing composition contains a catalyst, a near-infrared cut filter having high solvent resistance and high heat resistance is easily provided. The catalyst is, for example, an organometallic catalyst, an acid-based catalyst, or an amine-based catalyst and preferably an organometallic catalyst. An example of the organometallic catalyst is tris(2,4-pentanedionato)aluminum(III).

The content of the catalyst is preferably 0.01 to 5 mass % based on the total solid content of the infrared absorbing composition. The lower limit of the content is preferably 0.05 mass % or more. The upper limit of the content is preferably 3 mass % or less and more preferably 1 mass % or less.

### Surfactant

The infrared absorbing composition may contain a surfactant. The surfactant may be used alone or two or more surfactants may be used in combination. The content of the surfactant is preferably 0.0001 to 5 mass % based on the total solid content of the infrared absorbing composition. The lower limit of the content is preferably 0.005 mass % or more and more preferably 0.01 mass % or more. The upper limit of the content is preferably 2 mass % or less and more preferably 1 mass % or less.

Various surfactants such as fluorine-based surfactants, nonionic surfactants, cationic surfactants, anionic surfactants, and silicone surfactants can be used. The infrared absorbing composition preferably contains at least one of the fluorine-based surfactant or the silicone surfactant. The surfactant decreases the interfacial tension between a surface to be coated and a coating liquid, which improves the wettability on the surface to be coated. This improves the liquid properties (in particular, fluidity) of the composition and enables further improvements in the uniformity of the coating thickness and in saving of the liquid. As a result, even when a thin film having a thickness of about several micrometers is formed using a small amount of liquid, the film is formed as a uniform-thickness film having less unevenness in thickness.

The fluorine content in the fluorine-based surfactant is preferably 3 to 40 mass %. The lower limit of the fluorine content is preferably 5 mass % or more and more preferably 7 mass % or more. The upper limit of the fluorine content is preferably 30 mass % or less and more preferably 25 mass % or less. When the fluorine content is within the above range, the uniformity of the coating thickness and saving of the liquid are effectively achieved and the solubility is also good.

Specific examples of the fluorine-based surfactant include surfactants described in paragraphs 0060 to 0064 in JP2014-41318A (paragraphs 0060 to 0064 in corresponding WO2014/17669A), the contents of which are incorporated herein. Examples of commercially available fluorine-based surfactants include MEGAFACE F-171, F-172, F-173, F-176, F-177, F-141, F-142, F-143, F-144, R30, F-437, F-475, F-479, F-482, F-554, and F-780 (all manufactured by DIC Corporation); Fluorad FC430, FC431, and FC171 (all manufactured by Sumitomo 3M Limited); and Surflon S-382, SC-101, SC-103, SC-104, SC-105, SC1068, SC-381, SC-383, S393, and KH-40 (all manufactured by Asahi Glass Co., Ltd.).

A block polymer can also be used as the fluorine-based surfactant. Specifically, the block polymer is, for example, a compound described in JP2011-89090A. The following compound is also exemplified as the fluorine-based surfactant used in the present invention.

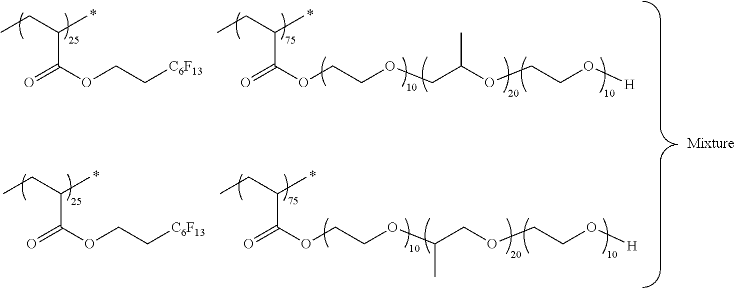

The weight-average molecular weight of the above compound is preferably 3,000 to 50,000, such as 14,000.

A fluorine-containing polymer having an ethylenically unsaturated group on its side chain can also be used as the fluorine-based surfactant. Specific examples of the fluorine-containing polymer include compounds described in paragraphs 0050 to 0090 and 0289 to 0295 in JP2010-164965A and MEGAFACE RS-101, RS-102, RS-718K, and RS-72-K manufactured by DIC Corporation. The fluorine-containing polymer having an ethylenically unsaturated group on its side chain corresponds to a surfactant and is a component different from the above-described resin having a crosslinking group and the above-described crosslinking compound.

Compounds described in paragraphs 0015 to 0158 in JP2015-117327A can also be used as the fluorine-based surfactant.

Specific examples of the nonionic surfactant include nonionic surfactants described in paragraph 0553 in JP2012-208494A (paragraph 0679 in corresponding US2012/0235099A), the contents of which are incorporated herein.

Specific examples of the cationic surfactant include cationic surfactants described in paragraph 0554 in JP2012-208494A (paragraph 0680 in corresponding US2012/0235099A), the contents of which are incorporated herein.

Specific examples of the anionic surfactant include W004, W005, and W017 (manufactured by Yusho Co., Ltd.).

Specific examples of the silicone surfactant include silicone surfactants described in paragraph 0556 in JP2012-208494A (paragraph 0682 in corresponding US2012/0235099A), the contents of which are incorporated herein.

### Polymerization Inhibitor

The infrared absorbing composition may contain a polymerization inhibitor. The polymerization inhibitor is, for example, hydroquinone, p-methoxyphenol, di-tert-butyl-p-cresol, pyrogallol, tert-butylcatechol, benzoquinone, 4,4′-thiobis(3-methyl-6-tert-butylphenol), 2,2′-methylenebis(4-methyl-6-tert-butylphenol), or an N-nitrosophenylhydroxyamine cerium(III) salt and preferably p-methoxyphenol. The content of the polymerization inhibitor is preferably 0.01 to 5 mass % based on the total solid content of the infrared absorbing composition.

### Ultraviolet Absorber

The infrared absorbing composition may contain an ultraviolet absorber. The ultraviolet absorber may be a publicly known compound. An example of the commercially available product is UV503 (DAITO CHEMICAL Co., Ltd.). The content of the ultraviolet absorber is preferably 0.01 to 10 mass % and more preferably 0.01 to 5 mass % based on the total solid content of the infrared absorbing composition.

### Solvent

The infrared absorbing composition preferably contains a solvent. Examples of the solvent include water and organic solvents. The water and the organic solvent may be used in combination. The details of the organic solvent are the same as those described in the resin composition.

The content of the solvent is preferably 5 to 80 mass % and more preferably 10 to 60 mass % based on the total solid content of the infrared absorbing composition.

### Antioxidant

The infrared absorbing composition may contain an antioxidant. Examples of the antioxidant include phenolic compounds, phosphite compounds, and thioether compounds. A phenolic compound having a molecular weight of 500 or more, a phosphite compound having a molecular weight of 500 or more, or a thioether compound having a molecular weight of 500 or more is further preferred. These compounds may be used as a mixture of two or more. The phenolic compound may be any phenolic compound known as a phenolic antioxidant. The phenolic compound is preferably a hindered phenolic compound. In particular, a compound having a substituent at a site (ortho position) adjacent to a phenolic hydroxy group is preferred. The substituent is preferably a substituted or unsubstituted alkyl group having 1 to 22 carbon atoms. The substituent is more preferably a methyl group, an ethyl group, a propionyl group, an isopropionyl group, a butyl group, an isobutyl group, a t-butyl group, a pentyl group, an isopentyl group, a t-pentyl group, a hexyl group, an octyl group, an isooctyl group, or a 2-ethylhexyl group. A compound (antioxidant) having a phenolic group and a phosphite group in the same molecule is also preferred.

A phosphorus-based antioxidant can also be suitably used as the antioxidant. The phosphorus-based antioxidant is, for example, at least one compound selected from the group consisting of tris[2-[[2,4,8,10-tetrakis(1,1-dimethylethyl)dibenzo[d,f][1,3,2]dioxaphosphepin-6-yl]oxy]ethyl]amine, tris[2-[(4,6,9,11-tetra-tert-butyldibenzo[d,f][1,3,2]dioxaphosphepin-2-yl)oxy]ethyl]amine, and ethyl bis(2,4-di-tert-butyl-6-methylphenyl) phosphite.

These compounds are easily acquired as commercially available products.

Examples of the compounds include ADK STAB AO-20, ADK STAB AO-30, ADK STAB AO-40, ADK STAB AO-50, ADK STAB AO-50F, ADK STAB AO-60, ADK STAB AO-60G, ADK STAB AO-80, and ADK STAB AO-330 (ADEKA).

The content of the antioxidant is preferably 0.01 to 20 mass % and more preferably 0.3 to 15 mass % based on the total solid content of the infrared absorbing composition. These antioxidants may be used alone or in combination of two or more. When two or more antioxidants are used, the total content is preferably within the above range.

### Other Components

The infrared absorbing composition may further contain, for example, a dispersing agent, a sensitizing agent, a curing accelerator, a filler, a plasticizer, an adhesion accelerator, and other auxiliary agents (e.g., conductive particles, a filling material, an anti-foaming agent, a flame retardant, a leveling agent, a peeling accelerator, a perfume, a surface tension adjuster, and a chain transfer agent). For these components, for example, the description in paragraphs 0183 to 0228 in JP2012-003225A (paragraphs 0237 to 0309 in corresponding US2013/0034812A), the description in paragraphs 0101 to 0102, 0103 to 0104, and 0107 to 0109 in JP2008-250074A, and the description in paragraphs 0159 to 0184 in JP2013-195480A can be taken into consideration, the contents of which are incorporated herein.

### Method for Preparing Infrared Absorbing Composition

The infrared absorbing composition can be prepared by mixing the above components. The details of the method for preparing an infrared absorbing composition are the same as those described in the method for preparing a resin composition.

For example, when the infrared absorbing layer is formed by performing coating, the infrared absorbing composition preferably has a viscosity of 1 to 3000 mPa·s. The lower limit of the viscosity is preferably 10 mPa·s or more and more preferably 100 mPa·s or more. The upper limit of the viscosity is preferably 2000 mPa·s or less and more preferably 1500 mPa·s or less. The viscosity is measured at 25° C.

### Method for Producing Near-Infrared Cut Filter

Next, a method for producing a near-infrared cut filter according to the present invention will be described. The method for producing a near-infrared cut filter according to the present invention includes a step of forming a first infrared absorbing layer on a support using an infrared absorbing composition A including an infrared absorber A, a step of forming a resin layer on the first infrared absorbing layer using a resin composition B including a resin B, and a step of forming a second infrared absorbing layer on the resin layer using an infrared absorbing composition C including an infrared absorber C.

The support is not particularly limited. The support is formed of a material that transmits at least light in a visible wavelength range. Examples of the material include glass, crystal, and resin. Examples of the glass include soda-lime glass, borosilicate glass, alkali-free glass, and quartz glass. Examples of the crystal include rock crystal, lithium niobate, and sapphire. Examples of the resin include polyester resins such as polyethylene terephthalate and polybutylene terephthalate; polyolefin resins such as polyethylene, polypropylene, and ethylene-vinyl acetate copolymers; norbornene resin; acrylic resins such as polyacrylate and poly(methyl methacrylate); and urethane resin, vinyl chloride resin, fluorocarbon resin, polycarbonate resin, polyvinyl butyral resin, and polyvinyl alcohol resin.

A substrate for solid-state imaging elements on which a solid-state imaging element (light-receiving element) such as CCD or CMOS is disposed on a substrate (e.g., a silicon substrate) may be used as a support.

Each composition can be applied by a method such as a dropping method (drop casting), coating with a spin coater, coating with a slit spin coater, coating with a slit coater, screen printing, coating with an applicator, or an inkjet method.

Each layer may be pre-baked (preheated) after each composition has been applied. The heating temperature is preferably 80° C. to 200° C. and more preferably 90° C. to 150° C. The heating time is preferably 30 to 240 seconds and more preferably 60 to 180 seconds.

In the method for forming each layer, a curing treatment may be performed after each composition has been applied. The curing treatment may be performed after the pre-baking or may be performed without the pre-baking.

The curing treatment is not particularly limited and can be suitably selected in accordance with the purpose. Preferred examples of the curing treatment include a whole-surface exposure treatment and a whole-surface heating treatment.

In the present invention, the term “exposure” is intended to cover irradiation processes using light beams having various wavelengths and irradiation processes using radiations such as electron beams and X-rays. The exposure is preferably performed by irradiation using radiation and, in particular, preferred examples of the radiation usable for exposure include electron beams, ultraviolet rays such as KrF, ArF, g-line, h-line, and i-line, and visible light. Examples of the mode of performing exposure include stepper exposure and exposure with a high-pressure mercury lamp. The exposure dose is preferably 5 to 3000 mJ/cm², more preferably 10 to 2000 mJ/cm², and particularly preferably 50 to 1000 mJ/cm². The method for performing the whole-surface exposure treatment is carried out by, for example, exposing the whose surface of the formed film. The whose-surface exposure promotes curing of crosslinking components in the film, so that the curing of the film further proceeds, which improves the solvent resistance and heat resistance of the infrared absorbing layer. An apparatus for performing the whole-surface exposure is not particularly limited and can be suitably selected in accordance with the purpose. The apparatus is, for example, suitably an ultraviolet exposure apparatus using an ultra-high-pressure mercury lamp or the like. The method for performing the whole-surface heating treatment is carried out by, for example, heating the whole surface of the formed film. The whose-surface heating improves the solvent resistance and heat resistance of the infrared absorbing layer.

The heating temperature in the whose-surface heating is preferably 120° C. to 250° C. and more preferably 160° C. to 220° C. When the heating temperature is 120° C. or higher, the heating treatment improves the film hardness. When the heating temperature is 250° C. or lower, the decomposition of components in the film can be suppressed. The heating time in the whose-surface heating is preferably 3 minutes to 180 minutes and more preferably 5 minutes to 120 minutes. An apparatus for performing the whose-surface heating is not particularly limited and can be suitably selected from publicly known apparatuses in accordance with the purpose. Examples of the apparatus include dry ovens, hot plates, and infrared (IR) heaters.

In the method for forming each layer, the curing treatment is performed and then post-baking (post-heating) may be performed. The post-heating is a heating treatment for completely curing the film that has been subjected to the curing treatment. The heating temperature is preferably 100° C. to 240° C. The heating temperature is more preferably 200° C. to 230° C. from the viewpoint of curing the film. The heating time is preferably 30 to 1000 seconds and more preferably 60 to 500 seconds.

In the present invention, the combination of the infrared absorbing composition A and the resin composition B preferably satisfies the following conditions (1).

(1) The infrared absorbing composition A includes an infrared absorber A and a resin A, and the absolute value of the difference between the solubility parameter (SP value) of the resin A included in the infrared absorbing composition A and the solubility parameter (SP value) of the resin B included in the resin composition B is 0.5 to 5.0 (MPa)^{1/2} (preferably 1.0 to 4.0 (MPa)^{1/2} and more preferably 1.0 to 3.0 (MPa)^{1/2}).

In the present invention, the combination of the infrared absorbing composition C and the resin composition B preferably satisfies the following conditions (2).

(2) The infrared absorbing composition C includes an infrared absorber C and a resin C, and the absolute value of the difference between the solubility parameter (SP value) of the resin C included in the infrared absorbing composition C and the solubility parameter (SP value) of the resin B included in the resin composition B is 0.5 to 5.0 (MPa)^{1/2} (preferably 1.0 to 4.0 (MPa)^{1/2} and more preferably 1.0 to 3.0 (MPa)^{1/2}).

In the present invention, the infrared absorbing composition A, the infrared absorbing composition C, and the resin composition B are particularly preferably combined with each other so that the above conditions (1) and (2) are satisfied. In this case, a near-infrared cut filter with lower haze is easily produced.

When the infrared absorbing composition A includes two resins (resin A1 and resin A2), that is, when the resin A is constituted by the resin A1 and the resin A2, the SP value of the resin A is determined by the following method.

SP value of resin A={(SP value of resin A1×content (mass %) of resin A1 in resin A)+(SP value of resin A2×content (mass %) of resin A2 in resin A)}/100

When the resin A is constituted by three or more resins, the SP value of the resin A is determined by the same method as above.

When the resin composition B includes two or more resins, that is, when the resin B is constituted by two or more resins, the SP value of the resin B is determined by the same method as above.

When the infrared absorbing composition C includes two or more resins, that is, when the resin C is constituted by two or more resins, the SP value of the resin C is determined by the same method as above.

### Application of Near-Infrared Cut Filter

The near-infrared cut filter according to the present invention is used for lenses capable of absorbing and cutting off infrared radiation (lenses for cameras such as digital cameras, cellular phones, and car-mounted cameras and optical lenses such as f-θ lenses and pickup lenses) and optical filters for semiconductor light-receiving elements. The near-infrared cut filter is also useful for noise cut filters for CCD cameras and filters for CMOS image sensors. The near-infrared cut filter can also be preferably used for organic electroluminescence (organic EL) elements and solar cell elements.

### Solid-State Imaging Element

The solid-state imaging element according to the present invention includes the near-infrared cut filter according to the present invention. The solid-state imaging element according to the present invention may have any configuration in which the solid-state imaging element includes the near-infrared cut filter according to the present invention and functions as a solid-state imaging element. For example, the following configuration is provided.

A plurality of photodiodes that constitute a light-receiving area of a solid-state imaging element (e.g., CCD image sensor and CMOS image sensor) and transfer electrodes formed of polysilicon or the like are provided on a support; a light shielding film having openings in light receiving sections of the photodiodes is provided on the photodiodes and the transfer electrodes; a device protecting film formed of silicon nitride or the like is provided on the light shielding film so as to cover the entire light shielding film and the photodiode light receiving sections; and a color filter is provided on the device protecting film. Furthermore, condensing means (e.g., microlens, the same applies hereafter) may be provided on the device protecting film and below the color filter (the side close to the support), or condensing means may be provided on the color filter. For the details of the solid-state imaging element included in the near-infrared cut filter, the description in paragraphs 0106 and 0107 in JP2015-044188A and the description in paragraphs 0010 to 0012 in JP2014-132333A can be taken into consideration, the contents of which are incorporated herein.

### Image Display Device

The image display device according to the present invention has the near-infrared cut filter according to the present invention. The near-infrared cut filter according to the present invention can be used for image display devices, such as liquid crystal display devices and organic electroluminescence (organic EL) display devices. For example, a near-infrared cut filter used together with each color pixel (e.g., red, green, and blue) cuts off infrared light included in backlight (e.g., white-light-emitting diode (white LED)) of the display device to prevent malfunctioning of peripheral devices. Alternatively, the near-infrared cut filter can be used to form an infrared pixel in addition to each color pixel.

The definition and details of the display devices are described in, for example, “Electronic Display Device (Akio Sasaki, Kogyo Chosakai Publishing Co., Ltd., published in 1990)” and “Display Device (Sumiaki Ibuki, Sangyo Tosho Publishing Co., Ltd., published in 1989)”. The definition and details of the liquid crystal display devices are described in, for example, “Next-generation Liquid Crystal Display Technology (edited by Tatsuo Uchida, Kogyo Chosakai Publishing Co., Ltd., published in 1994)”. The liquid crystal display devices to which the present invention can be applied are not particularly limited. For example, the present invention can be applied to liquid crystal display devices with various modes described in the “Next-generation Liquid Crystal Display Technology”.

The image display device may have a white organic EL element. The white organic EL element preferably has a tandem structure. The tandem structure of the organic EL element is described in, for example, JP2003-45676A and “Leading Edge of Development of Organic EL Technique—High-brightness, High-precision, and Life-extending Know-hows”, under the supervision of Akiyoshi Mikami, Technical Information Institute Co., Ltd., pp. 326-328, 2008. The spectrum of white light emitted by the organic EL element preferably has large maximum emission peaks in a blue-light region (430 nm to 485 nm), a green-light region (530 nm to 580 nm), and a yellow-light region (580 nm to 620 nm). The spectrum more preferably has a maximum emission peak in a red-light region (650 nm to 700 nm) in addition to the above emission peaks.

### Examples

Hereafter, the present invention will be more specifically described based on Examples. The materials, amounts of use, ratios, details of treatments, and sequence of treatments, and the like in Examples below can be appropriately changed without departing from the spirit of the present invention. Accordingly, the scope of the present invention is not limited to the following specific examples. Note that “%” and “part” are on a mass basis unless otherwise specified. In the following description, propylene glycol monomethyl ether acetate is abbreviated as PGMEA.

### Measurement of Weight-Average Molecular Weight (Mw)

The weight-average molecular weight (Mw) was measured by the following method.

Type of column: TSKgel Super AWM-H (manufactured by Tosoh Corporation, 6.0 mm (inside diameter)×15.0 cm)
Developing solvent: 10 mmol/L lithium bromide NMP (N-methylpyrrolidinone) solution
Column temperature: 40° C.
Flow rate (amount of sample injected): 10 μL
Name of instrument: HLC-8220 (manufactured by Tosoh Corporation)
Base resin for calibration curve: polystyrene

### Measurement of Glass Transition Temperature

The glass transition temperature of a resin layer was measured by differential scanning calorimetry (DSC).

### Production of Near-Infrared Cut Filter

### Formation of Infrared Absorbing Layer

### Infrared Absorbing Layer 1

Forty-five parts by mass of a copper complex 1 below, 49.95 parts by mass of a resin 1 below, 5 parts by mass of IRGACURE-OXE02 (manufactured by BASF), 0.05 parts by mass of tris(2,4-pentanedionato)aluminum(III) (manufactured by Tokyo Chemical Industry Co., Ltd.), and 100 parts by mass of cyclohexanone were mixed with each other to prepare an infrared absorbing composition 1. The prepared infrared absorbing composition 1 was applied onto a glass wafer or a resin layer using a spin coater so as to have a dry thickness of 100 μm. Then, heating treatment was performed using a hot plate at 160° C. for 1.5 hours to form an infrared absorbing layer 1 having a thickness of 100 μm.

Copper complex 1: structure below

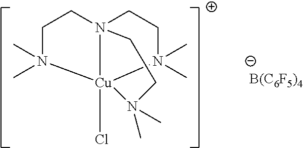

Resin 1: structure below (Mw=15,000, SP value=20.5, the value added to the main chain was the molar ratio of each structural unit)

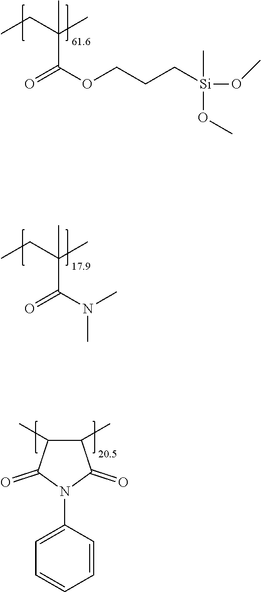

### Infrared Absorbing Layer 2

An infrared absorbing composition 2 was prepared in the same manner as the infrared absorbing composition 1, except that a copper complex 2 was used in the same amount instead of the copper complex 1. An infrared absorbing layer 2 having a thickness of 100 m was formed by the same formation method as the infrared absorbing layer 1 using the prepared infrared absorbing composition 2.

Copper complex 2: structure below

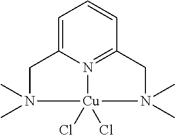

### Infrared Absorbing Layer 3

An infrared absorbing composition 3 was prepared in the same manner as the infrared absorbing composition 1, except that a copper complex 3 was used in the same amount instead of the copper complex 1. An infrared absorbing layer 3 having a thickness of 100 m was formed by the same formation method as the infrared absorbing layer 1 using the prepared infrared absorbing composition 3.

Copper complex 3: structure below

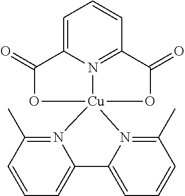

### Infrared Absorbing Layer 4

An infrared absorbing composition 4 was prepared in the same manner as the infrared absorbing composition 1, except that a copper complex 4 was used in the same amount instead of the copper complex 1. An infrared absorbing layer 4 having a thickness of 100 m was formed by the same formation method as the infrared absorbing layer 1 using the prepared infrared absorbing composition 4.

Copper complex 4: copper complex having the following compound as a ligand

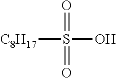

### Infrared Absorbing Layer 5

An infrared absorbing composition 5 was prepared in the same manner as the infrared absorbing composition 1, except that a copper complex 5 was used in the same amount instead of the copper complex 1. An infrared absorbing layer 5 having a thickness of 100 μm was formed by the same formation method as the infrared absorbing layer 1 using the prepared infrared absorbing composition 5.

Copper complex 5: copper complex having the following compound as a ligand

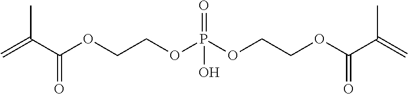 [SMILES: C=C(C)C(=O)OCCOP(=O)(O)OCCOC(=O)C(=C)C]

### Infrared Absorbing Layer 6

To a recovery flask, 7.00 g (35.06 mmol) of copper acetate monohydrate and 140 g of methanol were added, and stirring was performed at 20° C. for 1 hour to prepare a solution (A solution). In a different container, 1.75 g of PLYSURF A219B (manufactured by DKS Co., Ltd.) and 4.82 g of n-butylphosphonic acid were dissolved in 100 g of methanol to prepare a solution (B solution). The B solution was added dropwise to the A solution over 3 hours to prepare a reaction liquid. The resulting reaction liquid was stirred at 20° C. for 10 hours. Then, the solvent was distilled off from the reaction liquid using an evaporator (water bath, 60° C.). One hundred grams of toluene was added to the solid obtained by distilling off the solvent, and distillation was performed using an evaporator until a constant weight was achieved and the acetate odor was removed. Thus, a bluish green solid was obtained at a yield of 8.75 g (yield 100%). To the obtained solid, 211 g of toluene was added, and ultrasonic irradiation was performed for 6 hours to obtain a toluene dispersion liquid (1) of copper n-butylphosphonate.

Subsequently, 1.90 g of triethylene glycol bis(2-ethylhexanoate), 250 ml of toluene, and 5.00 g of polyvinyl butyral (PVB) were added to the flask. A solution prepared by dissolving 4.8 mg of meso-erythritol in 1 ml of methanol was added thereto. Furthermore, 3.65 g (including 0.583 mmol of the copper salt) of the toluene dispersion liquid (1) of copper n-butylphosphonate was added thereto and stirring was performed at 20° C. for 10 hours. After that, ultrasonic irradiation was performed for 1.5 hours to uniformly dissolve the PVB. Thus, an infrared absorbing composition 6 was obtained.

The obtained infrared absorbing composition 6 was applied onto a glass wafer or a resin layer using a spin coater so as to have a dry thickness of 100 μm. Then, heating treatment was performed using a hot plate at 160° C. for 1.5 hours to form an infrared absorbing layer 6 having a thickness of 100 μm.

### Infrared Absorbing Layer 7

After mixing 8.04 parts by mass of a resin 2 below, 0.1 parts by mass of a compound SQ-23 below, 0.07 parts by mass of KAYARAD DPHA (Nippon Kayaku Co., Ltd.) serving as a crosslinking compound, 0.265 parts by mass of MEGAFACE RS-72K (DIC Corporation), 0.38 parts by mass of a photopolymerization initiator below, and 82.51 parts by mass of PGMEA serving as a solvent, stirring was performed. The resulting solution after the stirring was filtrated with a 0.5 μm nylon filter (manufactured by Pall Corporation) to prepare an infrared absorbing composition 7. The prepared infrared absorbing composition 7 was applied onto a glass wafer or a resin layer using a spin coater (manufactured by Mikasa Co., Ltd.) to form a coating film. Subsequently, preheating (pre-baking) was performed at 100° C. for 120 seconds and then whose-surface exposure was performed at 1000 mJ/cm² using an i-line stepper. Next, post-heating (post-baking) was performed at 220° C. for 300 seconds to form an infrared absorbing layer 7 having a thickness of 0.8 μm.

Resin 2: compound below (Mw: 41000, SP value=19.2, the value added to the main chain was the molar ratio of each structural unit)

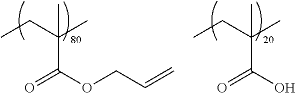

Compound SQ-23: structure below

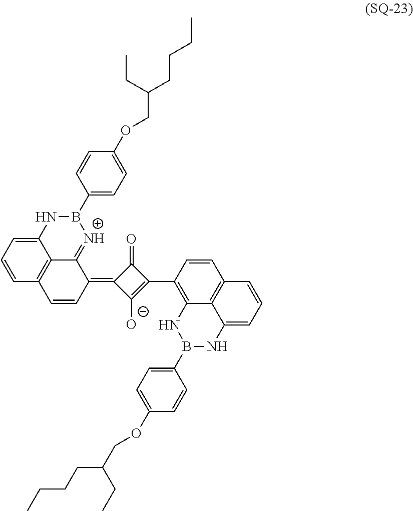 [SMILES: CCCCC(CC)COc1ccc(B2Nc3cccc4ccc(C5=C([O-])/C(=c6\ccc7cccc8c7c6=[NH+]B(c6ccc(OCC(CC)CCCC)cc6)N8)C5=O)c(c34)N2)cc1]

Photopolymerization initiator: structure below

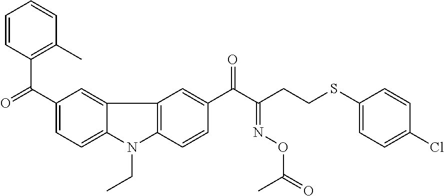 [SMILES: CCn1c2ccc(C(=O)/C(CCSc3ccc(Cl)cc3)=N/OC(C)=O)cc2c2cc(C(=O)c3ccccc3C)ccc21]

### Infrared Absorbing Layer 8

An infrared absorbing composition 8 was prepared in the same manner as the infrared absorbing composition 7, except that a compound A-52 below was used in the same amount instead of the compound SQ-23. An infrared absorbing layer 8 having a thickness of 0.8 μm was formed by the same formation method as the infrared absorbing layer 7 using the prepared infrared absorbing composition 8.

Compound A-52: structure below

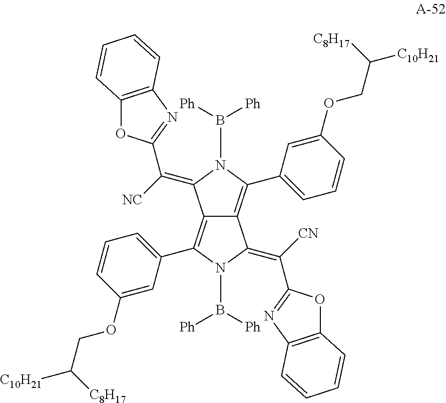

### Infrared Absorbing Layer 9

A solution was prepared by dissolving 0.5 parts by mass of a compound C-15 below in 69.5 parts by mass of ion-exchanged water. To the solution, 30.0 parts by mass of a 10 mass % aqueous gelatin solution was added and furthermore 0.3 parts by mass of 1,3-divinylsulfonyl-2-propanol serving as a hardener was added, and stirring was performed to prepare an infrared absorbing composition 9. An infrared absorbing layer 9 having a thickness of 0.8 μm was formed by the same formation method as the infrared absorbing layer 7 using the prepared infrared absorbing composition 9.

Compound C-15: structure below

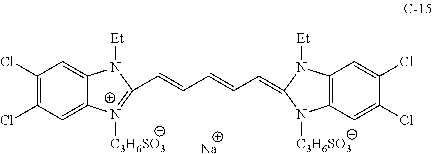

### Infrared Absorbing Layer 10

An infrared absorbing composition 10 was prepared in the same manner as the infrared absorbing composition 9, except that a compound 31 below was used in the same amount instead of the compound C-15. An infrared absorbing layer 10 having a thickness of 0.8 μm was formed by the same formation method as the infrared absorbing layer 7 using the prepared infrared absorbing composition 10.

Compound 31: structure below

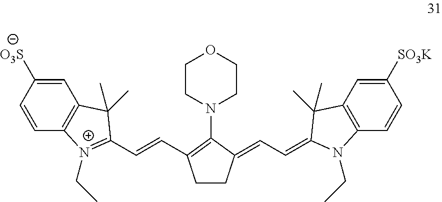

### Infrared Absorbing Layer 11

An infrared absorbing composition 11 was prepared in the same manner as the infrared absorbing composition 7, except that Acrycure-RD-F8 (manufactured by Nippon Shokubai Co., Ltd.) was used in the same amount instead of the resin 2. An infrared absorbing layer 11 having a thickness of 0.8 μm was formed by the same formation method as the infrared absorbing layer 7 using the prepared infrared absorbing composition 11.

### Infrared Absorbing Layer 12

An infrared absorbing composition 12 was prepared in the same manner as the infrared absorbing composition 5, except that Acrycure-RD-F8 (Nippon Shokubai Co., Ltd.) was used in the same amount instead of the resin 1. An infrared absorbing layer 12 having a thickness of 100 μm was formed by the same formation method as the infrared absorbing layer 1 using the prepared infrared absorbing composition 12.

### Infrared Absorbing Layer 13

An infrared absorbing composition 13 was prepared in the same manner as the infrared absorbing composition 5, except that a resin 3 was used in the same amount instead of the resin 1. An infrared absorbing layer 13 having a thickness of 100 μm was formed by the same formation method as the infrared absorbing layer 1 using the prepared infrared absorbing composition 13.

Resin 3: structure below (Mw=15,000, SP value=19.2, the value added to the main chain was the molar ratio of each structural unit)

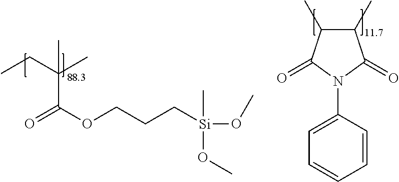

### Formation of Resin Layer (Interlayer)

### Resin Layer 1

Thirty parts by mass of a resin B1 (Cyclomer P (ACA230AA) manufactured by Daicel Corporation, acrylic resin) and 70 parts by mass of cyclohexanone were mixed with each other to prepare a resin composition 1. The prepared resin composition 1 was applied using a spin coater so as to have a thickness of 10 μm and heated using a hot plate at 100° C. for 2 minutes. Then, heating treatment was performed using a hot plate at 200° C. for 5 minutes to form a resin layer 1 (glass transition temperature=31° C.) having a thickness of 10 m.

### Resin Layer 2

Thirty parts by mass of a resin B2 (Cyclomer P (ACA2103) manufactured by Daicel Corporation, acrylic resin) and 70 parts by mass of cyclohexanone were mixed with each other to prepare a resin composition 2. A resin layer 2 (glass transition temperature=12° C.) having a thickness of 10 μm was formed by the same formation method as the resin layer 1 using the prepared resin composition 2.

### Resin Layer 3

Thirty parts by mass of a resin B3 (BGM-601 manufactured by Osaka Organic Chemical Industry Ltd.) and 70 parts by mass of cyclohexanone were mixed with each other to prepare a resin composition 3. A resin layer 3 (glass transition temperature=47° C.) having a thickness of 10 μm was formed by the same formation method as the resin layer 1 using the prepared resin composition 3.

### Resin Layer 4

Thirty parts by mass of a resin B4 (Ripoxy SPCF-9λ manufactured by Showa Denko K.K.) and 70 parts by mass of cyclohexanone were mixed with each other to prepare a resin composition 4. A resin layer 4 having a thickness of 10 m was formed by the same formation method as the resin layer 1 using the prepared resin composition 4.

### Resin Layer 5

Thirty parts by mass of a resin B5 (Acrycure-RD-F8 manufactured by Nippon Shokubai Co., Ltd., acrylic resin) and 70 parts by mass of cyclohexanone were mixed with each other to prepare a resin composition 5. A resin layer 5 (glass transition temperature=46° C.) having a thickness of 10 μm was formed by the same formation method as the resin layer 1 using the prepared resin composition 5.

### Resin Layer 6

Fifteen parts by mass of a resin B1 (Cyclomer P (ACA230AA) manufactured by Daicel Corporation, acrylic resin), 15 parts by mass of a resin B2 (Cyclomer P (ACA21013) manufactured by Daicel Corporation, acrylic resin), and 70 parts by mass of cyclohexanone were mixed with each other to prepare a resin composition 6. A resin layer 6 (glass transition temperature=31° C.) having a thickness of 10 μm was formed by the same formation method as the resin layer 1 using the prepared resin composition 6.

### Resin Layer 7

Thirty parts by mass of a resin 3 and 70 parts by mass of cyclohexanone were mixed with each other to prepare a resin composition 7. A resin layer 7 having a thickness of 10 μm was formed by the same formation method as the resin layer 1 using the prepared resin composition 7.

Resin 3: structure below (Mw=15,000, SP value=19.2, the value added to the main chain was the molar ratio of each structural unit)

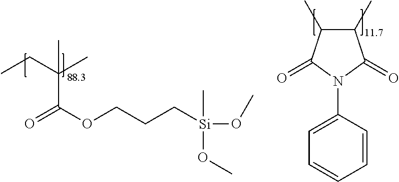

### Resin Layer 8

Thirty parts by mass of a resin 4 and 70 parts by mass of cyclohexanone were mixed with each other to prepare a resin composition 8. A resin layer 8 having a thickness of 10 m was formed by the same formation method as the resin layer 1 using the prepared resin composition 8.

Resin 4: structure below (Mw=15,000, SP value=20.0, the value added to the main chain was the molar ratio of each structural unit)

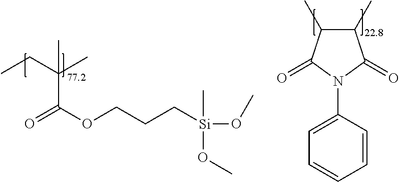

### Resin Layer 9

Thirty parts by mass of a resin 5 and 70 parts by mass of cyclohexanone were mixed with each other to prepare a resin composition 9. A resin layer 9 having a thickness of 10 μm was formed by the same formation method as the resin layer 1 using the prepared resin composition 9.

Resin 5: structure below (Mw=15,000, SP value=20.9, the value added to the main chain was the molar ratio of each structural unit)

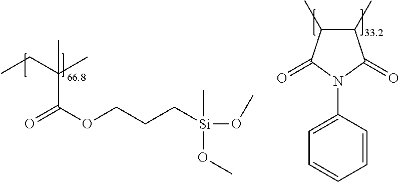

### Resin Layer 10

Thirty parts by mass of a resin 6 and 70 parts by mass of cyclohexanone were mixed with each other to prepare a resin composition 10. A resin layer 10 having a thickness of 10 μm was formed by the same formation method as the resin layer 1 using the resin composition 10.

Resin 6: structure below (Mw=15,000, SP value=24.5, the value added to the main chain was the molar ratio of each structural unit)

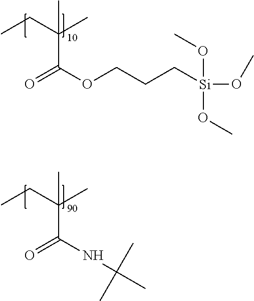

### Measurement of Haze

The haze of the near-infrared cut filter was measured with a haze meter NDH-5000 manufactured by NIPPON DENSHOKU INDUSTRIES Co., Ltd. Since clouding is visually recognized at a haze of more than 1%, the haze should be 1% or less from the viewpoint of practical use.

TABLE 1

| | | Resin layer | Second infrared absorbing | |
|---|---|---|---|---|
| | First infrared absorbing layer | (interlayer) | layer | Haze |
| Example 1 | Infrared absorbing layer 1 | Resin layer 1 | Infrared absorbing layer 7 | <0.1% |
| Example 2 | Infrared absorbing layer 2 | Resin layer 1 | Infrared absorbing layer 7 | <0.1% |
| Example 3 | Infrared absorbing layer 3 | Resin layer 1 | Infrared absorbing layer 7 | <0.1% |
| Example 4 | Infrared absorbing layer 4 | Resin layer 1 | Infrared absorbing layer 7 | <0.1% |
| Example 5 | Infrared absorbing layer 5 | Resin layer 1 | Infrared absorbing layer 7 | <0.1% |
| Example 6 | Infrared absorbing layer 6 | Resin layer 1 | Infrared absorbing layer 7 | <0.1% |
| Example 7 | Infrared absorbing layer 12 | Resin layer 1 | Infrared absorbing layer 7 | <0.1% |
| Example 8 | Infrared absorbing layer 1 | Resin layer 2 | Infrared absorbing layer 7 | <0.1% |
| Example 9 | Infrared absorbing layer 1 | Resin layer 3 | Infrared absorbing layer 7 | <0.1% |
| Example 10 | Infrared absorbing layer 1 | Resin layer 4 | Infrared absorbing layer 7 | <0.1% |
| Example 11 | Infrared absorbing layer 1 | Resin layer 5 | Infrared absorbing layer 7 | <0.1% |
| Example 12 | Infrared absorbing layer 1 | Resin layer 6 | Infrared absorbing layer 7 | <0.1% |
| Example 13 | Infrared absorbing layer 1 | Resin layer 6 | Infrared absorbing layer 8 | <0.1% |
| Example 14 | Infrared absorbing layer 1 | Resin layer 6 | Infrared absorbing layer 9 | <0.1% |
| Example 15 | Infrared absorbing layer 1 | Resin layer 6 | Infrared absorbing layer 10 | <0.1% |
| Example 16 | Infrared absorbing layer 1 | Resin layer 6 | Infrared absorbing layer 11 | <0.1% |
| Example 17 | Infrared absorbing layer 12 | Resin layer 5 | Infrared absorbing layer 11 | 0.8% |
| Example 18 | Infrared absorbing layer 13 | Resin layer 7 | Infrared absorbing layer 7 | 0.8% |
| | (SP value: 19.2) | (SP value: 19.2) | (SP value: 19.2) | |
| Example 19 | Infrared absorbing layer 13 | Resin layer 8 | Infrared absorbing layer 7 | 0.2% |
| | (SP value: 19.2) | (SP value: 20) | (SP value: 19.2) | |
| Example 20 | Infrared absorbing layer 13 | Resin layer 9 | Infrared absorbing layer 7 | <0.1% |
| | (SP value: 19.2) | (SP value: 20.9) | (SP value: 19.2) | |
| Example 21 | Infrared absorbing layer 13 | Resin layer 10 | Infrared absorbing layer 7 | <0.1% |
| | (SP value: 19.2) | (SP value: 24.5) | (SP value: 19.2) | |
| Comparative | Infrared absorbing layer 12 | No | Infrared absorbing layer 11 | 3% |
| Example 1 | | | | |

As is clear from the above results, the near-infrared cut filters in Examples in which a resin layer was disposed between the first infrared absorbing layer and the second infrared absorbing layer had a low haze of 1% or less, and thus clouding was substantially not visually observed. Furthermore, the near-infrared cut filters in Examples 18 to 20 in which the absolute value of the difference between the SP value of the resin layer and the SP value of the first infrared absorbing layer and the absolute value of the difference between the SP value of the resin layer and the SP value of the second infrared absorbing layer were 5.0 (MPa)^{1/2} or less had better adhesiveness between the resin layer and the first infrared absorbing layer and better adhesiveness between the resin layer and the second infrared absorbing layer than the near-infrared cut filter in Example 21 in which the absolute values of the differences between the SP values were more than 5.0 (MPa)^{1/2}.

In contrast, the near-infrared cut filter in Comparative Example 1 that did not have a resin layer had a high haze and was highly clouded.

### REFERENCE SIGNS LIST

10 first infrared absorbing layer
20 resin layer
30 second infrared absorbing layer

What is claimed is:

1. A near-infrared cut filter comprising:
a first infrared absorbing layer including an infrared absorber A;
a second infrared absorbing layer including an infrared absorber C; and
a resin layer disposed between the first infrared absorbing layer and the second infrared absorbing layer.

2. The near-infrared cut filter according to claim 1, wherein at least one of the infrared absorber A or the infrared absorber C includes a copper compound.

3. The near-infrared cut filter according to claim 1, wherein at least one of the infrared absorber A or the infrared absorber C includes at least one compound selected from the group consisting of a pyrrolopyrrole compound, a squarylium compound, a cyanine compound, a phthalocyanine compound, and a naphthalocyanine compound.

4. The near-infrared cut filter according to claim 1, wherein one of the infrared absorber A and the infrared absorber C includes a copper compound and the other includes at least one compound selected from the group consisting of a pyrrolopyrrole compound, a squarylium compound, a cyanine compound, a phthalocyanine compound, and a naphthalocyanine compound.

5. The near-infrared cut filter according to claim 1, wherein at least one of the first infrared absorbing layer or the second infrared absorbing layer is a layer obtained by curing an infrared absorbing composition that contains a compound having a crosslinking group and an infrared absorber.

6. The near-infrared cut filter according to claim 1,
wherein at least one of the first infrared absorbing layer or the second infrared absorbing layer is a layer obtained by curing an infrared absorbing composition that contains a compound having a crosslinking group and a copper compound, and
the compound having a crosslinking group is a compound having a partial structure represented by M-X,
where M represents an atom selected from the group consisting of Si, Ti, Zr, and Al; X represents one group selected from the group consisting of a hydroxy group, an alkoxy group, an acyloxy group, a phosphoryloxy group, a sulfonyloxy group, an amino group, an oxime group, and O═C(R^{a})(R^{b}); R^{a} and R^{b} each independently represent a monovalent organic group; and when X represents O═C(R^{a})(R^{b}), X bonds to M through an unshared electron pair of an oxygen atom in a carbonyl group.

7. The near-infrared cut filter according to claim 5, wherein a content of the compound having a crosslinking group is 15 mass % or more based on a total solid content of the infrared absorbing composition.

8. The near-infrared cut filter according to claim 1, wherein the resin layer has a glass transition temperature of 0° C. to 200° C.

9. The near-infrared cut filter according to claim 1, wherein the resin layer has a thickness of 0.005 mm or more.

10. The near-infrared cut filter according to claim 1,
wherein at least one of the first infrared absorbing layer or the second infrared absorbing layer includes a resin, and
an absolute value of a difference between an SP value that is a solubility parameter of the resin included in the at least one of the first infrared absorbing layer or the second infrared absorbing layer and an SP value that is a solubility parameter of a resin included in the resin layer is 0.5 to 5.0 (MPa)^{1/2}.

11. The near-infrared cut filter according to claim 1,
wherein the first infrared absorbing layer is in contact with the resin layer, and
the second infrared absorbing layer is in contact with the resin layer.

12. A method for producing a near-infrared cut filter, comprising:
forming a first infrared absorbing layer on a support using an infrared absorbing composition A including an infrared absorber A;
forming a resin layer on the first infrared absorbing layer using a resin composition B including a resin B; and
forming a second infrared absorbing layer on the resin layer using an infrared absorbing composition C including an infrared absorber C.

13. The method for producing a near-infrared cut filter according to claim 12,
wherein the infrared absorbing composition A includes the infrared absorber A and a resin A, and
an absolute value of a difference between an SP value that is a solubility parameter of the resin A and an SP value that is a solubility parameter of the resin B is 0.5 to 5.0 (MPa)^{1/2}.

14. The method for producing a near-infrared cut filter according to claim 12,
wherein the infrared absorbing composition C includes the infrared absorber C and a resin C, and
an absolute value of a difference between an SP value that is a solubility parameter of the resin C and an SP value that is a solubility parameter of the resin B is 0.5 to 5.0 (MPa)^{1/2}.

15. A solid-state imaging element comprising the near-infrared cut filter according to claim 1.
